(19) United States
(12) Patent Application Publication
(10) Pub. No.: US 2021/0198406 A1
(43) Pub. Date: Jul. 1, 2021

(54) TRANSFER FILM, MANUFACTURING METHOD OF CURED FILM, MANUFACTURING METHOD OF LAMINATE, AND MANUFACTURING METHOD OF TOUCH PANEL

(71) Applicant: FUJIFILM Corporation, Tokyo (JP)

(72) Inventors: Kentaro TOYOOKA, Fujinomiya-shi (JP); Tatsuya SHIMOYAMA, Fujinomiya-shi (JP)

(73) Assignee: FUJIFILM Corporation, Tokyo (JP)

(21) Appl. No.: 17/205,128

(22) Filed: Mar. 18, 2021

Related U.S. Application Data
(63) Continuation of application No. PCT/JP2019/035454, filed on Sep. 10, 2019.

(30) Foreign Application Priority Data
Oct. 18, 2018 (JP) 2018-196602
Feb. 7, 2019 (JP) 2019-020457
Apr. 24, 2019 (JP) 2019-083007

(51) Int. Cl. C08F 265/06; C08K 3/22; C09D 151/00; B32B 7/06; B32B 27/20; B32B 27/30; B32B 37/00; B32B 37/18; G03F 7/004; G03F 7/00; G03F 7/031; G03F 7/033; G03F 7/11; G06F 3/044

(52) U.S. Cl. CPC C08F 265/06; G06F 2203/04103; C09D 151/003; B32B 7/06; B32B 27/20; B32B 27/302; B32B 27/308; B32B 37/025; B32B 37/182; G03F 7/0044; G03F 7/0007; G03F 7/031; G03F 7/033; G03F 7/11; G06F 3/044; C08K 2003/2231; C08K 2003/2241; C08K 2003/2244; B32B 2305/72; B32B 2264/1022; B32B 2264/102; B32B 2325/00; B32B 2333/08; B32B 2457/208; C08K 3/22

(57) ABSTRACT

A transfer film satisfies at least one of the following (1) or (2). (1) The transfer film comprises a temporary support, and a first transparent layer including a polymerizable compound, a polymerization initiator, and a resin, and the first transparent layer further contains a metal oxide particle containing titanium oxide and tin oxide. (2) The transfer film comprises a temporary support, and a first transparent layer including a polymerizable compound, a polymerization initiator, and a resin, and a second transparent layer, and the second transparent layer contains a metal oxide particle containing titanium oxide and tin oxide.

### CROSS-REFERENCE TO RELATED APPLICATIONS

This application is a Continuation of PCT International Application No. PCT/JP2019/035454 filed on Sep. 10, 2019, which claims priority under 35 U.S.C § 119(a) to Japanese Patent Application No. 2018-196602 filed on Oct. 18, 2018, Japanese Patent Application No. 2019-020457 filed on Feb. 7, 2019, and Japanese Patent Application No. 2019-083007 filed on Apr. 24, 2019. Each of the above application(s) is hereby expressly incorporated by reference, in its entirety, into the present application.

### BACKGROUND OF THE INVENTION

### 1. Field of the Invention

The present disclosure relates to a transfer film, a manufacturing method of a cured film, a manufacturing method of a laminate, and a manufacturing method of a touch panel.

### 2. Description of the Related Art

In recent years, in electronic devices such as a mobile phone, a car navigator, a personal computer, a ticket vending machine, or a terminal of the bank, a tablet type input device is disposed on a surface of a liquid crystal device or the like. There is provided a device to which information corresponding to an instruction image is input, by touching a portion, where the instruction image is displayed, with fingers or a touch pen, while referring to the instruction image displayed in an image display region of a liquid crystal device.

The input device described above (hereinafter, may be referred to as a touch panel) may include a resistance film type input device, a capacitive input device, and the like. The capacitive input device is advantageous in that a transmittance conductive film may be simply formed on one sheet of substrate. In such a capacitive input device, there is provided a device in which electrode patterns are extended in directions intersecting each other, and which detects an input position by detecting a change of electrostatic capacity between electrodes, in a case where a finger or the like is touched.

In order to protect electrode patterns or leading wirings (for example, metal wirings such as copper wires) put together on a frame portion of the capacitive input device, a transparent resin laver is provided on a side opposite to the surface for the inputting with a finger or the like.

In addition, examples of the transfer film of the related art include those disclosed in JP2017-064988A.

JP2017-064988A discloses a transfer film including a temporary support, a first transparent resin layer, and a second transparent resin layer in this order, in which the second transparent resin layer contains a metal oxide particle and an organic component, and in a case where an area of a thickness direction distribution profile of a ratio of a metal atom constituting the metal oxide particle in the second transparent resin layer to a carbon atom constituting the organic component is defined as A and a peak height of the profile is defined as P, Expression (1) is satisfied.

0.01 (nm)⁻¹≤P/A≤0.08 (nm)⁻¹ Equation (1)

In addition, an example in which a titanium oxide particle is used as the metal oxide particle is also disclosed.

### SUMMARY OF THE INVENTION

An object to be achieved by one embodiment of the invention is to provide a transfer film capable of forming a film having excellent adhesiveness and a low haze.

Another object to be achieved by another embodiment of the invention is to provide a manufacturing method of a cured film formed of the transfer film, a manufacturing method of a laminate, and a manufacturing method of a touch panel.

A unit for achieving the objects includes the following embodiments.

<1> A transfer film which satisfies at least one of the following (1) or (2).

(1) The transfer film comprises a temporary support, and a first transparent layer including a polymerizable compound, a polymerization initiator, and a resin, and the first transparent layer further contains a metal oxide particle containing titanium oxide and tin oxide.

(2) The transfer film comprises a temporary support, and a first transparent layer including a polymerizable compound, a polymerization initiator, and a resin, and a second transparent layer, and the second transparent layer contains a metal oxide particle containing titanium oxide and tin oxide.

<2> The transfer film according to <1>, in which the transfer film satisfies the (2).

<3> The transfer film according to <1> or <2>, in which the titanium oxide in the metal oxide particle contains a rutile type titanium oxide.

<4> The transfer film according to any one of <1> to <3>, in which an average primary particle diameter of the metal oxide particle is 10 nm or less.

<5> The transfer film according to any one of <1> to <4>, in which a content of the tin oxide with respect to a content of the titanium oxide in the metal oxide particle is 5% by mass or more.

<6> The transfer film according to any one of <1> to <5>, in which the metal oxide particle further contains an inorganic oxide other than the titanium oxide and the tin oxide.

<7> The transfer film according to any one of <1> to <6>, in which the layer containing the metal oxide particle further contains a silane coupling agent or a titanium coupling agent.

<8> The transfer film according to any one of <1> to <7>, in which the transfer film is a transfer film for forming a protective film of a touch panel.

<9> A manufacturing method of a cured film, the method comprising: transferring at least the first transparent layer of the transfer film according to any one of <1> to <8> on a support; and curing at least a part of the first transparent layer to form a cured film.

<10> A manufacturing method of a laminate, the method comprising: transferring at least the first transparent layer of the transfer film according to any one of <1> to <8> on a substrate including an electrode; and curing at least a part of the first transparent layer to form a cured layer.

<11> The manufacturing method of a laminate according to <10>, in which the electrode is an electrode of a capacitive input device.

<12> A manufacturing method of a touch panel, the method comprising: preparing a substrate for a touch panel having a structure in which at least one of an electrode for a touch panel or a wiring for a touch panel is disposed on the substrate; forming a photosensitive layer on a surface of the substrate for a touch panel on a side where at least one of the electrode for a touch panel or the wiring for a touch panel is disposed, using the transfer film according to any one of <1> to <8>; performing patternwise exposing on the photosensitive layer formed on the substrate for a touch panel; and developing the patternwise exposed photosensitive layer to obtain a protective film for a touch panel which protects at least a part of at least one of the electrode for a touch panel or the wiring for a touch panel.

According to one embodiment of the invention, it is possible to provide a transfer film capable of forming a film having excellent adhesiveness and a low haze.

In addition, according to another embodiment of the invention, it is possible to provide a manufacturing method of a cured film formed of the transfer film, a manufacturing method of a laminate, and a manufacturing method of a touch panel.

### BRIEF DESCRIPTION OF THE DRAWINGS

FIG. 1 is a schematic cross sectional view showing an example of a transfer film according to the disclosure.

FIG. 2 is a schematic cross sectional view showing another example of the transfer film according to the disclosure.

FIG. 3 is a schematic cross sectional view showing a first specific example of a touch panel according to the disclosure.

FIG. 4 is a schematic cross sectional view showing a second specific example of the touch panel according to the disclosure.

FIG. 5 is a cross sectional view showing an example of a cover module used in the disclosure together with a display device.

FIG. 6 is a top view showing another example of the cover module used in the disclosure.

### DESCRIPTION OF THE PREFERRED EMBODIMENTS

Hereinafter, the content of the disclosure will be described in detail. The configuration elements will be described below based on the representative embodiments of the disclosure, but the disclosure is not limited to such embodiments.

In the disclosure, a term “to” showing a range of numerical values is used as a meaning including a lower limit value and an upper limit value disclosed before and after the term.

In a range of numerical values described in stages in this specification, the upper limit value or the lower limit value described in one range of numerical values may be replaced with an upper limit value or a lower limit value of the range of numerical values described in other stages. In addition, in a range of numerical values described in this specification, the upper limit value or the lower limit value of the range of numerical values may be replaced with values shown in the examples.

Regarding a term, group (atomic group) of this disclosure, a term with no description of “substituted” and “unsubstituted” includes both a group not including a substituent and a group including a substituent. For example, an “alkyl group” not only includes an alkyl group not including a substituent (unsubstituted alkyl group), but also an alkyl group including a substituent (substituted alkyl group).

In the specification, a “total solid content” refers to a total mass of components excluding a solvent from the entire composition. In addition, the “solid content” is a component excluding the solvent, as described above, and may be a solid or a liquid at 25° C., for example.

In addition, in the disclosure, “% by mass” is identical to “% by weight” and “part by mass” is identical to “part by weight”.

Further, in the disclosure, a combination of two or more preferable embodiments is the more preferable embodiments.

In the disclosure, in a case where a plurality of substances corresponding to components are present in a composition, an amount of each component in the composition means a total amount of the plurality of substances present in the composition, unless otherwise noted.

In the disclosure, a term “step” not only includes an independent step, but also includes a step, in a case where the step may not be distinguished from the other step, as long as the expected object of the step is achieved.

In the disclosure, “(meth)acrylic acid” has a concept including both acrylic acid and a methacrylic acid, “(meth)acrylate” has a concept including both acrylate and methacrylate, and “(meth)acryloyl group” has a concept including both acryloyl group and methacryloyl group.

A weight-average molecular weight (Mw) and a number average molecular weight (Mn) of the disclosure, unless otherwise noted, are detected by a gel permeation chromatography (GPC) analysis device using a column of TSKgel GMHxL, TSKgel G4000HxL, TSKgel G2000HxL (all product names manufactured by Tosoh Corporation), by using tetrahydrofuran (THF) as a solvent and a differential refractometer, and are molecular weights obtained by conversion using polystyrene as a standard substance.

In the disclosure, a ratio of the constitutional unit in a resin represents a molar ratio unless otherwise noted.

In the disclosure, the molecular weight, in a case where there is a molecular weight distribution, represents the weight-average molecular weight (Mw), unless otherwise noted.

The refractive index in the disclosure means a value measured with light at a wavelength of 550 nm at 25° C. by an ellipsometer, unless otherwise noted.

Hereinafter, the disclosure will be described in detail.

(Transfer Film)

A transfer film according to the disclosure satisfies at least one of the following (1) or (2).

(1) The transfer film comprises a temporary support, and a first transparent layer including a polymerizable compound, a polymerization initiator, and a resin, and the first transparent layer further contains a metal oxide particle containing titanium oxide and tin oxide.

(2) The transfer film comprises a temporary support, and a first transparent layer including a polymerizable compound, a polymerization initiator, and a resin, and a second transparent layer, and the second transparent layer contains a metal oxide particle containing titanium oxide and tin oxide.

That is, a transfer film of a first embodiment according to the disclosure includes a temporary support, and a first transparent layer including a polymerizable compound, a polymerization initiator, and a resin, and the first transparent layer further contains a metal oxide particle containing titanium oxide and tin oxide.

In addition, a transfer film of a second embodiment according to the disclosure includes a temporary support, a first transparent layer including a polymerizable compound, a polymerization initiator, and a resin, and a second transparent layer, and the second transparent layer contains a metal oxide particle containing titanium oxide and tin oxide.

From viewpoints of adhesiveness and haze, it is preferable that the specific particle is contained in the second transparent layer (the section (2), the second embodiment). By including the specific particle in the second transparent layer (second embodiment), excellent concealing properties of a transparent electrode pattern is obtained in the laminated formed by transfer.

In the second embodiment of the transfer film according to the present disclosure, the first transparent layer may further contain a metal oxide particle containing titanium oxide and tin oxide.

In the present disclosure, a term “transfer film according to the present disclosure” includes both the transfer films of the first embodiment and the second embodiment.

In addition, in the present disclosure, the simple term “first transparent layer” includes both the first transparent layers of the first embodiment and the second embodiment.

Further, the transfer film according to the present disclosure can be suitably used as a transfer film for forming a protective film in a touch panel, and can be more preferably used as a transfer film for forming a transparent electrode protective film in a touch panel.

In addition, the transfer film according to the present disclosure can also be suitably used as a transfer film for forming a refractive index adjustment laver.

As a result of intensive studies, the inventors have found that it is possible to provide a transfer film capable of forming a film having excellent adhesiveness and a low haze, by using the above configuration.

An operation mechanism for excellent effect by this is not clear, but is assumed as follows.

By containing the metal oxide particle containing titanium oxide and tin oxide, particularly by containing the tin oxide, a film having excellent compatibility with the resin and having a low haze can be obtained. In addition, since a refractive index of the titanium oxide and the tin oxide, particularly the titanium oxide, is high by containing the metal oxide particle containing the titanium oxide and the tin oxide, a desired refractive index can be realized by adding a small amount of the metal oxide. Therefore, it is presumed that the adhesiveness to the base material can be improved by increasing the amount of organic components in the transfer film.

The “haze” in the present disclosure is an index related to transparency and represents turbidity (cloudiness). The smaller the haze value, the less cloudiness and turbidity, and the better the transparency.

Hereinafter, the transfer film according to the present disclosure will be described in detail in the order of the first embodiment and the second embodiment.

### First Embodiment

The transfer film of the first embodiment according to the disclosure includes a temporary support, and a first transparent layer including a polymerizable compound, a polymerization initiator, and a resin, and the first transparent layer further contains a metal oxide particle containing titanium oxide and tin oxide.

<Temporary Support>

The transfer film according to the disclosure includes a temporary support.

The temporary support is preferably a film and more preferably a resin film.

As the temporary support, a film which has flexibility and does not generate significant deformation, shrinkage, or stretching under pressure or under pressure and heating can be used.

Examples of such a film include a polyethylene terephthalate film, a cellulose triacetate film, a polystyrene film, a polyimide film, and a polycarbonate film.

Among these, a biaxial stretching polyethylene terephthalate film is particularly preferable.

It is preferable that the film used as the temporary support does not have deformation such as wrinkles or scratches.

A haze of the film used as the temporary support is preferably 1.0% or less and more preferably 0.5% or less. A total number of particles having a diameter of 5 μm or more and aggregates having a diameter of 5 μm or more included in the film is preferably 5 piece/mm or less.

In addition, on both surfaces of the temporary support that, a density of broken bubble marks having a diameter of 40 μm to 100 μm caused by rupture of bubbles in the resin of the temporary support is preferably 5 piece/0.25 m² or less.

Further, a surface roughness Sa (SRa) of the surface of the temporary support on the first transparent layer side is preferably 20 nm or less, more preferably 10 nm or less, and even more preferably 5 nm or less. A SRz is preferably 100 nm or less. The surface roughness SRa of the surface of the temporary support that does not come into contact with the first transparent layer is preferably 20 nm or less and more preferably 1 nm to 12 nm. A maximum height Sz (SRz) of the surface is preferably 300 nm or less.

Examples of the biaxial stretching polyethylene terephthalate film satisfying the above include LUMIRROR 16QS62 (manufactured by Toray Industries, Inc.). LUMIRROR 16QS52 (manufactured by Toray Industries, Inc.), LUMIRROR 16QS48 (manufactured by Toray Industries, Inc.), and LUMIRROR 12QS62 (manufactured by Toray Industries, Inc.)

A thickness of the temporary support is not particularly limited, and is, for example, preferably 3 μm to 200 μm, more preferably 4 μm to 50 μm, and even more preferably 5 μm to 30 μm.

<First Transparent Layer>

The transfer film of the first embodiment according to the disclosure includes a temporary support, and a first transparent layer including a polymerizable compound, a polymerization initiator, and a resin, and the first transparent layer further contains a metal oxide particle containing titanium oxide and tin oxide.

The metal oxide particle containing titanium oxide and tin oxide in the first transparent layer will be described later.

In the present disclosure, “transparent” means that a transmittance of visible light having a wavelength of 400 nm to 700 nm is 80% or more. Accordingly, the “transparent layer” indicates a layer having a transmittance of visible light having a wavelength of 400 nm to 700 nm is 80% or more. The transmittance of the visible light of the “transparent layer” is preferably 90% or more.

In addition, a light transmittance of each layer of the transfer film and the transfer film is a value measured using a spectrophotometer, and can be measured, for example, using a spectrophotometer U-3310 manufactured by Hitachi, Ltd.

—Metal Oxide Particle Containing Titanium Oxide and Tin Oxide—

In the first embodiment of the transfer film according to the present disclosure, the first transparent layer may further contain a metal oxide particle containing titanium oxide and tin oxide.

Hereinafter, the metal oxide particle containing titanium oxide and tin oxide are also referred to as a “specific particle”.

The specific particle is a metal oxide particle containing titanium oxide and tin oxide, that is, a titanium oxide-tin oxide composite particle.

The titanium oxide in the specific particle is preferably a titanium dioxide, from a viewpoint of haze.

A crystal structure of the titanium oxide (titanium dioxide) in the specific particle may be any of a anatase type (tetragonal crystal), a rutile type (tetragonal crystal), and a brookite type (orthorhombic crystal).

Among those, from viewpoints of the refractive index, adhesiveness, haze, and light resistance of a film to be obtained, the specific particle preferably contains a rutile type titanium oxide and more preferably a rutile type titanium oxide.

In addition, the tin oxide in the specific particle is preferably a tin dioxide, from a viewpoint of haze.

The specific particle preferably contains a metal oxide other than titanium oxide and tin oxide, from viewpoints of adhesiveness and haze.

Examples of metal oxide other than the titanium oxide and the tin oxide include oxides containing atoms such as Be, Mg, Ca, Sr, Ba, Sc, Y, La, Ce, Gd, Tb, Dy Yb, Lu, Zr, Hf, Nb, Mo, W, Zn, B, Al, Si, Ge, Pb, Sb, Bi and Te.

The metal of the metal oxide particle of the present disclosure also includes semimetal such as B, Si, Ge, As, Sb, or Te.

Among them, as the metal oxide other than the titanium oxide and the tin oxide, at least one kind of metal oxide selected from the group consisting of silicon dioxide, aluminum oxide, and zirconium oxide is preferable, and a silicon dioxide is more preferable, from viewpoints of adhesiveness, haze, and light resistance.

The metal oxide other than the titanium oxide and the tin oxide may be contained alone or in combination of two or more kinds thereof.

In addition, the specific particle may be a particle which is subjected to surface treatment such as a hydrophilization treatment and a hydrophobic treatment.

The surface treatment method is not particularly limited, and a well-known method can be used.

A content of titanium oxide in the specific particle is preferably 30% by mass or more, more preferably 50% by mass to 99% by mass, even more preferably 70% by mass to 95% by mass, and particularly preferably 70% by mass to 90% by mass, with respect to a total mass of the specific particle, from viewpoints of refractive index, adhesiveness, and haze of the film to be obtained.

A content of tin oxide in the specific particle is preferably 0.1% by mass to 50% by mass, more preferably 1% by mass to 30% by mass, and even more preferably 5% by mass to 20% by mass, with respect to a total mass of the specific particle, from viewpoints of refractive index, adhesiveness, and haze of the film to be obtained.

In a case where the specific particle contains the metal oxides other than the titanium oxide and the tin oxide, a content of the metal oxide other than the titanium oxide and the tin oxide with respect to the content of titanium oxide in the specific particle is preferably 0.1% by mass to 60% by mass, more preferably 0.5% by mass to 50% by mass, even more preferably 1% by mass to 30% by mass, and particularly preferably 5% by mass to 20% by mass, with respect to the total mass of the specific particle, from viewpoints of refractive index, adhesiveness, haze, and light resistance of the film to be obtained.

A shape of the specific particle is not particularly limited, and examples thereof include a spherical shape, a spindle shape, a prismatic shape, a columnar shape, a flat plate shape, and an indefinite shape.

An average primary particle diameter of the specific particle is preferably 100 nm or less, more preferably 20 nm or less, even more preferably 10 nm or less, and particularly preferably 1 nm to 10 nm, from viewpoints of adhesiveness and haze.

The average primary particle diameter of the specific particle in the present disclosure refers to an arithmetic mean obtained by measuring particle diameters of 200 random particles with a transmission electron microscope. In addition, a case where the shape of the particle is not a spherical shape, the longest side is set as the diameter.

The transfer film in the present disclosure may contain one kind of specific particle alone, or may contain two or more kinds of specific particle.

A content of the specific particle contained in the first transparent layer in the first embodiment is preferably 5% by mass to 90% by mass, more preferably 10% by mass to 85% by mass, even more preferably 15% by mass to 80% by mass, and particularly preferably 20°/o by mass to 70% by mass, with respect to a total mass of the first transparent layer, from viewpoints of refractive index, concealing properties of the transparent electrode pattern, adhesiveness, and haze of the film to be obtained.

<<Polymerizable Compound>>

The first transparent layer in the first embodiment contains a polymerizable compound.

The polymerizable compound is a component that contributes to photosensitivity (that is, photocuring properties) and strength of the cured film to be obtained.

Examples of the polymerizable compound include a polymerizable compound, for example, a radical polymerizable compound and a cationically polymerizable compound, and ethylenically unsaturated compound are preferable.

The ethylenically unsaturated compound is a compound having one or more ethylenically unsaturated groups.

The ethylenically unsaturated compound preferably contains a di- or higher functional ethylenically unsaturated compound.

Here, the di- or higher functional ethylenically unsaturated compound refers to a compound having two or more ethylenically unsaturated groups in one molecule.

As the ethylenically unsaturated group, a (meth)acryloyl group is more preferable.

As the ethylenically unsaturated compound, a (meth)acrylate compound is preferable.

From a viewpoint of curability after curing, the first transparent layer particularly preferably include a difunctional ethylenically unsaturated compound (preferably a difunctional (meth)acrylate compound) and a tri- or higher functional ethylenically unsaturated compound (preferably a tri- or higher functional (meth)acrylate compound).

The difunctional ethylenically unsaturated compound is not particularly limited and can be suitably selected from well-known compounds.

Examples of the difunctional ethylenically unsaturated compound include tricyclodecane dimethanol di(meth)acrylate, 1,9-nonanediol di(meth)acrylate, and 1,6-hexanediol di(meth)acrylate.

Specific examples of the difunctional ethylenically unsaturated compound include tricyclodecane dimethanol diacrylate (A-DCP, manufactured by Shin-Nakamura Chemical Co., Ltd.), 1,9-nonanediol diacrylate (A-NOD-N, manufactured by Shin-Nakamura Chemical Co., Ltd.), 1,6-hexanediol diacrylate (A-HD-N, manufactured by Shin-Nakamura Chemical Co., Ltd.), and polytetramethylene glycol #650 diacrylate (A-PTMG-65, manufactured by Shin-Nakamura Chemical Co., Ltd.)

The tri- or higher functional ethylenically unsaturated compound is not particularly limited and can be suitably selected from well-known compounds.

Examples of the tri- or higher functional ethylenically unsaturated compound include dipentaerythritol (tri/tetra/penta/hexa) (meth)acrylate, pentaerythritol (tri/tetra) (meth)acrylate, trimethylolpropane tri(meth)acrylate, ditrimethylolpropane tetra(meth)acrylate, isocyanuric acid (meth)acrylate, and a (meth)acrylate compound of a glycerin tri(meth)acrylate skeleton.

Here, the “(tri/tetra/penta/hexa) (meth)acrylate” has a concept including tri(meth)acrylate, tetra(meth)acrylate, penta(meth)acrylate, and hexa(meth)acrylate, and the “(tri/tetra) (meth)acrylate” has a concept including tri(meth)acrylate and tetra(meth)acrylate.

Examples of the ethylenically unsaturated compound also include a caprolactone-modified compound of a (meth)acrylate compound (KAYARAD (registered trademark) DPCA-20 manufactured by Nippon Kayaku Co., Ltd., A-9300-CL manufactured by Shin-Nakamura Chemical Co., Ltd., or the like), an alkylene oxide-modified compound of a (meth)acrylate compound (KAYARAD RP-1040 manufactured by Nippon Kayaku Co., Ltd., ATM-35E, A-9300 manufactured by Shin-Nakamura Chemical Co., Ltd., EBECRYL (registered trademark) 135 manufactured by Daicel-Allnex Ltd., or the like), and ethoxylated glycerin triacrylate (A-GLY-9E manufactured by Shin-Nakamura Chemical Co., Ltd.).

As the ethylenically unsaturated compound, a urethane (meth)acrylate compound (preferably tri- or higher functional urethane (meth)acrylate compound) is also used.

Examples of the tri- or higher functional urethane (meth)acrylate compound include 8UX-015A (manufactured by Taisei Fine Chemical Co., Ltd.), UA-32P (manufactured by Shin-Nakamura Chemical Co., Ltd.), and UA-1100H (manufactured by Shin-Nakamura Chemical Co., Ltd.).

In addition, the ethylenically unsaturated compound preferably includes an ethylenically unsaturated compound having an acid group, from a viewpoint of improving developability.

Examples of the acid group include a phosphoric acid group, a sulfonic acid group, and a carboxy group, and a carboxy group is preferable.

Examples of the ethylenically unsaturated compound including the acid group include a tri- or tetra-functional ethylenically unsaturated compound including the acid group (component obtained by introducing a carboxy group to pentaerythritol tri- and tetra-acrylate (PETA) skeleton (acid value=80 mgKOH/g to 120 mgKOH/g)), and a penta- to hexa-functional ethylenically unsaturated compound including the acid group (component obtained by introducing a carboxy group to dipentaerythritol penta- and hexa-acrylate (DPHA) skeleton (acid value=25 mgKOH/g to 70 mgKOH/g)).

The tri- or higher functional Ethylenically unsaturated compound including the acid group may be used in combination with the difunctional ethylenically unsaturated compound including the acid group, as necessary.

As the ethylenically unsaturated compound including the acid group, at least one kind selected from the group consisting of di- or higher functional ethylenically unsaturated compound including carboxy group and a carboxylic acid anhydride thereof is preferable. This improves developability and hardness of the cured film.

The di- or higher functional ethylenically unsaturated compound including a carboxy group is not particularly limited and can be suitably selected from well-known compounds.

For example, as the di- or higher functional ethylenically unsaturated compound including a carboxy group, ARONIX (registered trademark) TO-2349 (manufactured by Toagosei Co., Ltd.), ARONIX M-520 (manufactured by Toagosei Co., Ltd.), or ARONIX M-510 (manufactured by Toagosei Co., Ltd.) can be preferably used.

The ethylenically unsaturated compound including the acid group is also preferably a polymerizable compound including an acid group disclosed in paragraphs 0025 to 0030 of JP2004-239942A. The content of this publication is incorporated in this specification.

A weight-average molecular weight (Mw) of the ethylenically unsaturated compound used in the disclosure is preferably 200 to 3,000, more preferably 250 to 2,600, even more preferably 280 to 2,200, and particularly preferably 30 to 2,200.

In addition, a ratio of the content of the ethylenically unsaturated compound having a molecular weight of 300 or less, among the ethylenically unsaturated compound included in the first transparent layer is preferably 30% by mass or less, more preferably 25% by mass or less, and even more preferably 20% by mass or less, with respect to all of the ethylenically unsaturated compounds included in the first transparent layer.

The ethylenically unsaturated compound may be used alone or in combination of two or more thereof.

The content of the ethylenically unsaturated compound is preferably 1% by mass to 70% by mass, more preferably 10% by mass to 70% by mass, even more preferably 20% by mass to 60% by mass, and particularly preferably 20% by mass to 50% by mass, with respect to a total mass of the first transparent layer.

In addition, in a case where the first transparent layer includes a difunctional ethylenically unsaturated compound and a tri- or higher functional ethylenically unsaturated compound, the content of the difunctional ethylenically unsaturated compound is preferably 10% by mass to 90% by mass, more preferably 20% by mass to 85% by mass, and even more preferably 30% by mass to 80% by mass, with respect to all of the ethylenically unsaturated compounds included in the first transparent layer.

In this case, the content of the tri- or higher functional ethylenically unsaturated compound is preferably 10% by mass to 90% by mass, more preferably 15% by mass to 80% by mass, and even more preferably 20% by mass to 70% by mass, with respect to all of the ethylenically unsaturated compounds included in the first transparent layer.

In this case, the content of the di- or higher functional ethylenically unsaturated compound is preferably 40% by mass or more and less than 100% by mass, more preferably 40% by mass to 90% by mass, even more preferably 50% by mass to 80% by mass, and particularly preferably 50% by mass to 70% by mass, with respect to a total content of the difunctional ethylenically unsaturated compound and the tri- or higher functional ethylenically unsaturated compound.

In addition, in a case where the first transparent layer includes a di- or higher functional ethylenically unsaturated compound, the first transparent layer may further include a monofunctional ethylenically unsaturated compound.

Further, in a case where the first transparent layer includes a di- or higher functional ethylenically unsaturated compound, the di- or higher functional ethylenically unsaturated compound is preferably the main component in the ethylenically unsaturated compound contained in the first transparent layer.

Specifically, in a case where the first transparent layer includes di- or higher functional ethylenically unsaturated compound, the content of the di- or higher functional ethylenically unsaturated compound is preferably 40% by mass to 100% by mass, more preferably 50% by mass to 100% by mass, and particularly preferably 60% by mass to 100% by mass with respect to a total content of the ethylenically unsaturated compound included in the first transparent layer.

In a case where the first transparent layer includes the ethylenically unsaturated compound including an acid group (preferably, di- or higher functional ethylenically unsaturated compound including a carboxy group or a carboxylic acid anhydride thereof), the content of the ethylenically unsaturated compound including the acid group is preferably 1% by mass to 50% by mass, more preferably 1% by mass to 20% by mass, and even more preferably 1% by mass to 10% by mass, with respect to a total mass of the first transparent layer.

<<Polymerization Initiator>>

The first transparent layer in the first embodiment contains a polymerization initiator.

The polymerization initiator is not particularly limited and a well-known polymerization initiator can be used.

As the polymerization initiator, a photopolymerization initiator and a thermal polymerization initiator are preferable, and a photopolymerization initiator is more preferable.

Examples of the photopolymerization initiator include a photopolymerization initiator having an oxime ester structure (hereinafter, also referred to as an “oxime-based photopolymerization initiator”), a photopolymerization initiator having an α-aminoalkylphenone structure (hereinafter, an “α-aminoalkylphenone-based photopolymerization initiator”), a photopolymerization initiator having an α-hydroxyalkylphenone structure (hereinafter also referred to as an “α-hydroxyalkylphenone-based polymerization initiator”), a photopolymerization initiator having an acylphosphine oxide structure. (hereinafter, also referred to as an “acylphosphine oxide-based photopolymerization initiator”), and a photopolymerization initiator having an N-phenylglycine structure (hereinafter, “N-phenylglycine-based photopolymerization initiator”).

The photopolymerization initiator preferably includes at least one kind selected from the group consisting of the oxime-based photopolymerization initiator, the α-aminoalkylphenone-based photopolymerization initiator, the α-hydroxyalkylphenone-based polymerization initiator, and the N-phenylglycine-based photopolymerization initiator, and more preferably includes at least one kind selected from the group consisting of the oxime-based photopolymerization initiator, the α-aminoalkylphenone-based photopolymerization initiator, and the N-phenylglycine-based photopolymerization initiator.

In addition, as the photopolymerization initiator, for example, polymerization initiators disclosed in paragraphs 0031 to 0042 of JP2011-095716A and paragraphs 0064 to 0081 of JP2015-014783A may be used.

Examples of a commercially available product of the photopolymerization initiator include 1-[4-(phenylthio)-1,2-octanedione-2-(O-benzoyloxime)(product name: IRGACURE (registered trademark) OXE-01, manufactured by BASF Japan Ltd.), 1-[9-ethyl-6-(2-methylbenzoyl)-9H-carbazole-3-yl]ethanone-1-(0-acetyloxime) (product name: IRGACURE OXE-02, manufactured by BASF Japan Ltd.), 2-(dimethylamino)-2-[(4-methylphenyl)methyl]-1-[4-(4-morpholinyl)phenyl]-1-butanone (product name: IRGACURE 379EG, manufactured by BASF Japan Ltd.), 2-methyl-1-(4-methylthiophenyl)-2-morpholinopropan-1-one (product name: IRGACURE 907, manufactured by BASF Japan Ltd.), 2-hydroxy-1-{4-[4-(2-hydroxy-2-methyl-propionyl)-benzyl]phenyl}-2-methylpropan-1-one (product name: IRGACURE 127, manufactured by BASF Japan Ltd.), 2-benzyl-2-dimethylamino-1-(4-morpholinophenyl)-1-butanone (product name: IRGACURE 369, manufactured by BASF Japan Ltd.), 2-hydroxy-2-methyl-1-phenyl-propan-1-one (product name: IRGACURE 1173, manufactured by BASF Japan Ltd.), 1-hydroxy cyclohexyl phenyl ketone (product name: IRGACURE 184, manufactured by BASF Japan Ltd.), 2,2-dimethoxy-1,2-diphenylethan-1-one (product name: IRGACURE 651, manufactured by BASF Japan Ltd.), and an oxime ester type photopolymerization initiator (product name: Lunar 6, manufactured by DKSH Japan K.K.).

The photopolymerization initiator may be used alone or in combination of two or more thereof.

A content of the photopolymerization initiator is not particularly limited and is preferably 0.1% by mass or more, more preferably 0.2% by mass or more, and even more preferably 0.3% by mass or more with respect to the total mass of the first transparent layer.

In addition, the content of the photopolymerization initiator is preferably equal to or smaller than 10% by mass and more preferably equal to or smaller than 5% by mass, with respect to a total mass of the first transparent layer.

<<Resin>>

The first transparent layer in the first embodiment contains a resin.

The resin is preferably a binder polymer.

The resin is preferably an alkali soluble resin.

The resin is not particularly limited, but from a viewpoint of developability, the resin is preferably a resin having an acid value of 60 mgKOH/g or more, more preferably an alkali soluble resin having an acid value of 60 mgKOH/g or more, and particularly preferably a carboxy group-containing (meth)acrylic resin having an acid value of 60 mgKOH/g or more.

The carboxyl group-containing (meth)acrylic resin having an acid value of 60 mgKOH/g or more (hereinafter, may be referred to as a specific polymer A) is not particularly limited, as long as the acid value condition is satisfied, and a resin can be selected and used from well-known resins.

For example, a binder polymer which is a carboxyl group-containing (meth)acrylic resin having an acid value of 60 mgKOH/g or more among polymers disclosed in paragraph 0025 of JP2011-095716A, a carboxyl group-containing (meth)acrylic resin having an acid value of 60 mgKOH/g or more among polymers disclosed in paragraphs 0033 to 0052 of JP2010-237589A, and the like can be preferably used as the specific polymer A in the embodiment.

Here, the (meth)acrylic resin indicates to a resin containing at least one of a constitutional unit derived from (meth)acrylic acid or a constitutional unit derived from a (meth)acrylic acid ester.

A total ratio of the constitutional unit derived from (meth)acrylic acid and the constitutional unit derived from (meth)acrylic acid ester in the (meth)acrylic resin is preferably 30 mol % or more and more preferably 50 mol % or more.

A ratio of a constitutional unit derived from the monomer having a carboxy group in the specific polymer A is preferably 5% by mass to 50% by mass, more preferably 5% by mass to 40% by mass, and even more preferably in a range of 10% by mass to 30% by mass, with respect to 100% by mass of the specific polymer A.

The specific polymer A may have a reactive group, and as a unit for introducing the reactive group into the specific polymer A, a method for causing a reaction of an epoxy compound, blocked isocyanate compound, an isocyanate compound, a vinyl sulfone compound, an aldehyde compound, a methylol compound, a carboxylic acid anhydride, or the like with a hydroxy group, a carboxy group, a primary amino group, a secondary amino group, an acetoacetyl group, sulfonic acid, or the like is used.

Among these, the reactive group is preferably a radically polymerizable group, more preferably an ethylenically unsaturated group, and particularly preferably a (meth)acryloxy group.

In addition, the resin, particularly the specific polymer A, preferably has a constitutional unit having an aromatic ring, from a viewpoint of moisture permeability and hardness after curing.

Examples of a monomer forming the constitutional unit having an aromatic ring include styrene, tert-butoxystyrene, methylstyrene, α-methylstyrene, and benzyl (meth)acrylate.

As the constitutional unit having an aromatic ring, it is preferable to contain at least one constitutional unit represented by Formula P-2 which will be described later. The constitutional unit having an aromatic ring is preferably a constitutional unit derived from a styrene compound.

In a case where the resin includes a constitutional unit having an aromatic ring, a content of the constitutional unit having an aromatic ring is preferably 5% by mass to 90% by mass, and more preferably 10% by mass to 70% by mass, even more preferably 15% by mass to 50% by mass, with respect to a total mass of the resin.

In addition, the resin, particularly the specific polymer A, preferably has a constitutional unit having an alicyclic skeleton, from a viewpoint of tackiness and hardness after curing.

Specific examples of the monomer forming the constitutional unit having an alicyclic skeleton include dicyclopentanyl (meth)acrylate, cyclohexyl (meth)acrylate, and isobornyl (meth)acrylate.

Preferred examples of the aliphatic ring included in the constitutional unit having an alicyclic skeleton include a dicyclopentane ring, a cyclohexane ring, an isophorone ring, and a tricyclodecane ring. Among these, a tricyclodecane ring is particularly preferable.

In a case where the resin includes a constitutional unit having an alicyclic skeleton, a content of the constitutional unit having an alicyclic skeleton is preferably 5% by mass to 90% by mass, more preferably 10% by mass to 80% by mass, and even more preferably 20% by mass to 70% by mass, with respect to a total mass of the resin.

In addition, the resin, particularly the specific polymer A, preferably has a constitutional unit having an ethylenically unsaturated group and more preferably has a constitutional unit having an ethylenically unsaturated group in a side chain, from a viewpoint of tackiness and hardness after curing.

In the disclosure, the “main chain” represents a relatively longest binding chain in a molecule of a polymer compound constituting a resin, and the “side chain” represents an atomic group branched from the main chain.

The ethylenically unsaturated group is preferably a (meth)acryl group and more preferably a (meth)acryloxy group.

In a case where the resin includes a constitutional unit having an ethylenically unsaturated group, a content of the constitutional unit having an ethylenically unsaturated group is preferably 5% by mass to 70% by mass, and more preferably 5% by mass to 50% by mass, even more preferably 10% by mass to 40% by mass, with respect to a total mass of the resin.

The acid value of the resin used in the disclosure is preferably 60 mgKOH/g or more, and more preferably 60 mgKOH/g to 200 mgKOH/g, even more preferably 60 mgKOH/g to 150 mgKOH/g, and particularly preferably 60 mgKOH/g to 130 mgKOH/g.

In the specification, the acid value refers to a value measured according to the method disclosed in JIS K0070 (1992).

A weight-average molecular weight of the specific polymer A is preferably 5,000 or more and more preferably 10,000 to 100,000.

In addition, as the resin, any film-forming resin can be suitably selected and used according to the purpose, in addition to the specific polymer A. From a viewpoint of using the transfer film as the electrode protective film of the capacitive input device, a film having good surface hardness and heat resistance is preferable, an alkali soluble resin is more preferable, and among the alkali soluble resins, a well-known photosensitive siloxane resin material can be preferably used.

The resin used in the disclosure preferably includes a polymer containing a constitutional unit having a carboxylic acid anhydride structure (hereinafter, also referred to as a specific polymer B). By including the specific polymer B, the developability and the hardness after curing are more excellent.

The carboxylic acid anhydride structure may be either a chain carboxylic acid anhydride structure or a cyclic carboxylic acid anhydride structure, and is preferably a cyclic carboxylic acid anhydride structure.

The ring of the cyclic carboxylic acid anhydride structure is preferably a 5- to 7-membered ring, more preferably a 5-membered ring or a 6-membered ring, and even more preferably a 5-membered ring.

In addition, the cyclic carboxylic acid anhydride structure may be condensed or bonded with another ring structure to form a polycyclic structure, but preferably does not form a polycyclic structure.

In a case where another ring structure is condensed or bonded to the cyclic carboxylic acid anhydride structure to form a polycyclic structure, the polycyclic structure is preferably a bicyclo structure or a Spiro structure.

In the polycyclic structure, the number of other ring structures condensed or bonded to the cyclic carboxylic acid anhydride structure is preferably 1 to 5, and more preferably 1 to 3.

Examples of the other ring structure include a cyclic hydrocarbon group having 3 to 20 carbon atoms and a heterocyclic group having 3 to 20 carbon atoms.

The heterocyclic group is not particularly limited, and examples thereof include an aliphatic heterocyclic group and an aromatic heterocyclic group.

In addition, the heterocyclic group is preferably a 5-membered ring or a 6-membered ring, and particularly preferably a 5-membered ring.

Further, as the heterocyclic group, a heterocyclic group containing at least one oxygen atom (for example, an oxolane ring, an oxane ring, or a dioxane ring) is preferable.

The constitutional unit having a carboxylic acid anhydride structure is preferably a constitutional unit containing a divalent group obtained by removing two hydrogen atoms from a compound represented by Formula P-1 in a main chain, or a constitutional unit in which a monovalent group obtained by removing one hydrogen atom from a compound represented by Formula P-1 is bonded to the main chain directly or via a divalent linking group.

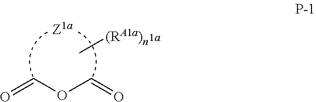

In Formula P-1, R^{A1a} represents a substituent and n^{1a} R^{A1a} may be the same or different.

Z^{1a} represents a divalent group forming a ring containing —C(═O)—O—C(═O)—. n^{1a} represents an integer of 0 or more.

As a substituent represented by R^{A1a}, the same substituent as the substituent which may be included in the carboxylic acid anhydride structure may be used, and the preferable range is also the same.

Z^{1a} is preferably an alkylene group having 2 to 4 carbon atoms, more preferably an alkylene group having 2 or 3 carbon atoms, and particularly preferably an alkylene group having 2 carbon atoms.

In addition, the partial structure represented by Formula P-1 may be condensed or bonded with another ring structure to form a polycyclic structure, but preferably does not form a polycyclic structure.

As the other ring structure here, the same ring structure as the other ring structure described above which may be condensed or bonded to the carboxylic acid anhydride structure may be used, and the preferable range is also the same.

n^{1a} represents an integer of 0 or more.

In a case where Z^{1a} represents an alkylene group having 2 to 4 carbon atoms, n^{1a} is preferably an integer of 0 to 4, more preferably an integer of 0 to 2, and even more preferably 0.

In a case where n^{1a} represents an integer of 2 or more, a plurality of R^{A1a} existing may be the same or different. In addition, the plurality of R^{A1a} existing may be bonded to each other to form a ring, but it is preferable that they are not bonded to each other to form a ring.

The constitutional unit having a carboxylic acid anhydride structure is preferably a constitutional unit derived from an unsaturated carboxylic acid anhydride, more preferably a constitutional unit derived from an unsaturated cyclic carboxylic acid anhydride, even more preferably a constitutional unit derived from an unsaturated alicyclic carboxylic acid anhydride, still more preferably a constitutional unit derived from maleic acid anhydride or itaconic anhydride, and particularly preferably a constitutional unit derived from maleic acid anhydride.

Hereinafter, specific examples of the constitutional unit having a carboxylic acid anhydride structure will be described, but the constitutional unit having a carboxylic acid anhydride structure is not limited to these specific examples.

In the following constitutional units, Rx represents a hydrogen atom, a methyl group, a CH₂OH group, or a CF₃ group, and Me represents a methyl group.

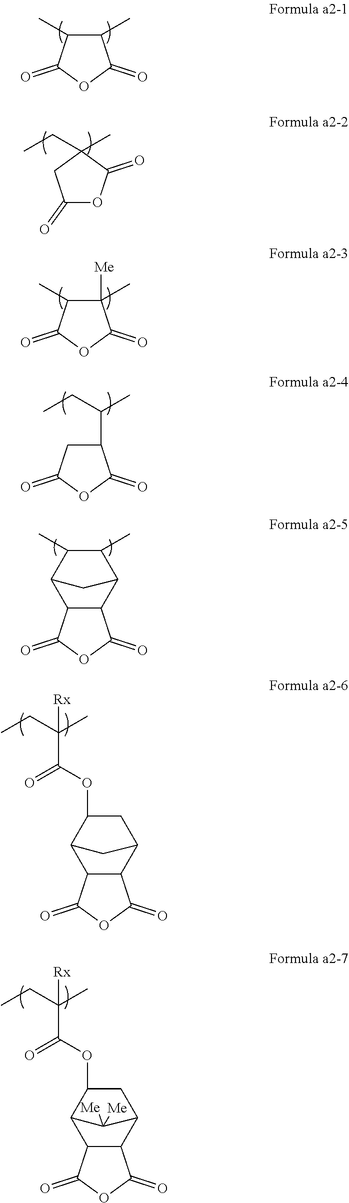

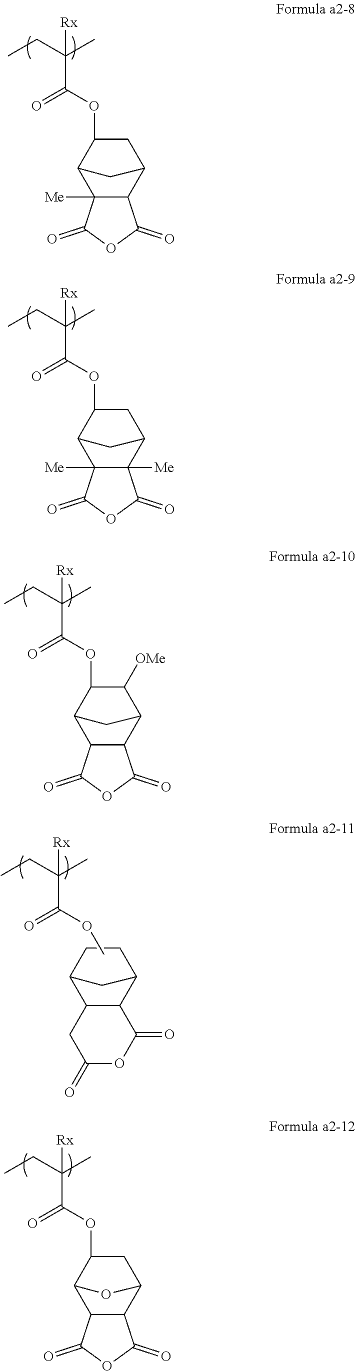

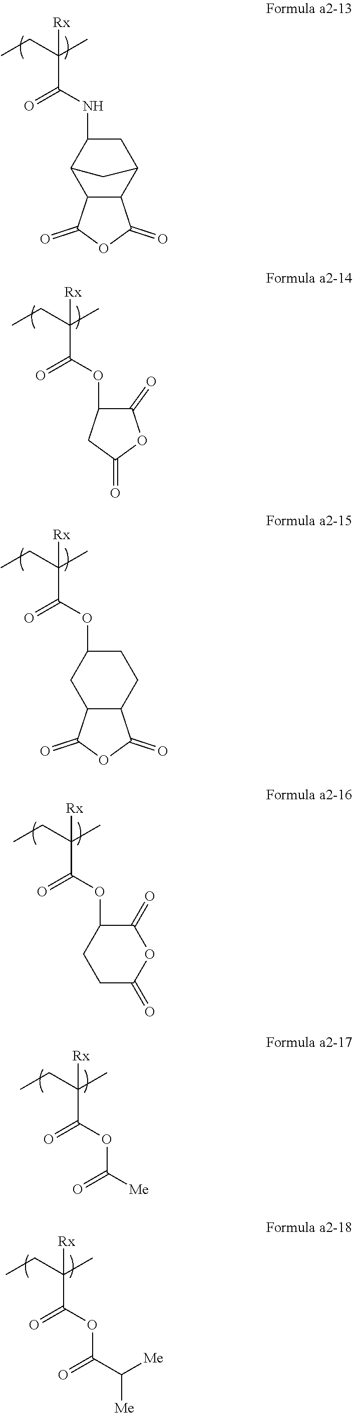

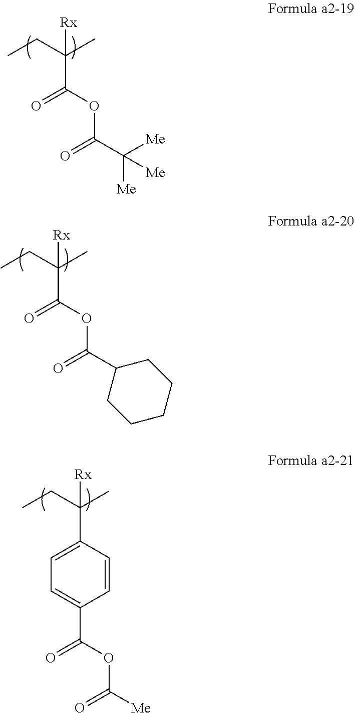

The constitutional unit having a carboxylic acid anhydride structure is preferably at least one of the constitutional units represented by any of Formulae a2-1 to a2-21, and more preferably one of the constitutional units represented by any of Formulae a2-1 to a2-21.

The constitutional unit having a carboxylic acid anhydride structure preferably has at least one of the constitutional unit represented by Formula a2-1 or the constitutional unit represented by Formula a2-2, and more preferably the constitutional unit represented by Formula a2-1, from viewpoints of developability and moisture permeability of the cured film to be obtained.

A content of constitutional unit having a carboxylic acid anhydride structure in the specific polymer B (in the case of two or more kinds, total content thereof. The same applies hereinafter) is preferably more than 0 mol % and 60 mol % or less, more preferably 5 mol % to 40 mol %, and even more preferably 10 mol % to 35 mol %, with respect to a total amount of the specific polymer B.

In the disclosure, in a case where the content of the “constitutional unit” is defined by a molar ratio, the “constitutional unit” is synonymous with the “monomer unit”. In addition, in the disclosure, the “monomer unit” may be modified after polymerization by a polymer reaction or the like. The same applies to the followings.

As the specific polymer B, it is preferable to contain at least one constitutional unit represented by Formula P-2. Accordingly, the moisture permeability of the cured film to be obtained is more reduced and the strength is further improved.

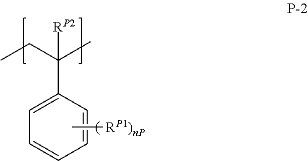

In Formula P-2, R^{P1} represents a hydroxy group, an alkyl group, an aryl group, an alkoxy group, a carboxy group, or a halogen atom, R^{P2} represents a hydrogen atom, an alkyl group, or an aryl group, and nP represents an integer of 0 to 5. In a case where nP is an integer of 2 or more, two or more existing R^{P1}'s may be the same or different.

R^{P1} is preferably an alkyl group having 1 to 10 carbon atoms, an aryl group having 6 to 12 carbon atoms, an alkoxy group having 1 to 10 carbon atoms, a carboxy group, an F atom, a Cl atom, a Br atom, or an I atom, and more preferably an alkyl group having 1 to 4 carbon atoms, a phenyl group, an alkoxy group having 1 to 4 carbon atoms, a Cl atom, or a Br atom. R is preferably a hydrogen atom, an alkyl group having 1 to 10 carbon atoms, or an aryl group having 6 to 12 carbon atoms, more preferably a hydrogen atom or an alkyl group having 1 to 4 carbon atoms, even more preferably a hydrogen atom, a methyl group, or an ethyl group, and particularly preferably a hydrogen atom.

nP is preferably an integer of 0 to 3, more preferably 0 or 1, and even more preferably 0.

A constitutional unit represented by Formula P-2 is preferably a constitutional unit derived from a styrene compound.

Examples of the styrene compound include styrene, p-methylstyrene, α-methylstyrene, α,p-dimethylstyrene, p-ethylstyrene, p-t-butylstyrene, and 1,1-diphenylethylene, styrene or α-methylstyrene is preferable, and styrene is particularly preferable.

The styrene compound for forming the constitutional unit represented by Formula P-2 may be only one or two or more kinds thereof.

In a case where the specific polymer B includes the constitutional unit represented by Formula P-2, a content of the constitutional units represented by Formula P-2 in the specific polymer B (in the case of two or more kinds, total content thereof. The same applies hereinafter) is preferably 5 mol % to 90 mol %, more preferably 30 mol % to 90 mol %, and even more preferably 40 mol % to 90 mol %, with respect to the total amount of the specific polymer B.

The specific polymer B may include at least one constitutional unit other than the constitutional unit having a carboxylic acid anhydride structure and the constitutional unit represented by Formula P-2.

The other constitutional unit preferably does not contain an acid group.

The other constitutional unit is not particularly limited, and a constitutional unit derived from a monofunctional ethylenically unsaturated compound is used.

As the monofunctional ethylenically unsaturated compound, well-known compounds can be used without particular limitation, and examples thereof include a (meth)acrylic acid derivative such as methyl (meth)acrylate, ethyl (meth)acrylate, n-butyl (meth)acrylate, 2-ethylhexyl (meth)acrylate, carbitol (meth)acrylate, cyclohexyl (meth)acrylate, benzyl (meth)acrylate, or epoxy (meth)acrylate; an N-vinyl compound such as N-vinylpyrrolidone or N-vinylcaprolactam; and a derivative of an allyl compound such as allyl glycidyl ether.

A content of the other constitutional units in the specific polymer B (in the case of two or more kinds, total content thereof) is preferably 0 mol % to 90 mol %, and more preferably 0 mol % to 70 mol %, with respect to the total amount of the specific polymer B.

A weight-average molecular weight of the resin is not particularly limited, and is preferably more than 3,000, more preferably more than 3,000 and 60,000 or less, and even more preferably 5,000 to 50,000.

The resin may be used alone or in combination of two or more kinds thereof.

A content of the resin is preferably 10% by mass to 90% by mass, more preferably 20% by mass to 80% by mass, and even more preferably 30% by mass to 70% by mass, with respect to the total mass of the first transparent layer, from viewpoints of hardness of the cured film to be obtained and handleability of the transfer film.

A mass ratio of the polymerizable compound with respect to the resin (content of the polymerizable compound/content of the resin) is preferably 0.20 to 2.0, more preferably 0.30 to 1.5, and particularly preferably 0.35 to 0.95, from a viewpoint of handleability of the transfer film.

<Thermal Crosslinking Compound>

The first transparent layer of the first embodiment preferably contains a thermal crosslinking compound and more preferably contains a blocked isocyanate compound, from a viewpoint of hardness after curing.

The thermal crosslinking compound means a “compound having one or more functional groups (thermal crosslinking group) capable of causing a crosslinking reaction by heating” in one molecule.

Examples of the thermal crosslinking compound include a blocked isocyanate compound, a bisphenol A type, a cresol novolac type, a biphenyl type, an epoxy compound of an alicyclic epoxy compound, and a melamine compound.

Among those, a blocked isocyanate compound is preferable, from a viewpoint of suppressing development residue, moisture permeability and bending resistance of the obtained cured film.

The blocked isocyanate compound refers to a “compound having a structure in which the isocyanate group of isocyanate is protected (masked) with a blocking agent”.

A dissociation temperature of the blocked isocyanate compound is preferably 100° C. to 160° C. and more preferably 130° C. to 150° C.

The dissociation temperature of blocked isocyanate of the specification is a “temperature at an endothermic peak accompanied with a deprotection reaction of blocked isocyanate, in a case where the measurement is performed by differential scanning calorimetry (DSC) analysis using a differential scanning calorimeter (manufactured by Seiko Instruments Inc., DSC6200)”.

Examples of the blocking agent having a dissociation temperature at 100° C. to 160° C. include a pyrazole compound (3,5-dimethylpyrazole, 3-methylpyrazole, 4-bromo-3,5-dimethylpyrazole, 4-nitro-3,5-dimethylpyrazole, or the like), an active methylene compound (diester malonate (dimethyl malonate, diethyl malonate, di n-butyl malonate, di-2-ethylhexyl malonate)) a triazole compound (1,2,4-triazole or the like), and an oxime compound (compound having a structure represented by —C(═N—OH)— in a molecule such as formaldoxime, acetoaldoxime, acetoxime, methyl ethyl ketoxime, or cyclohexanone oxime). Among these, from a viewpoint of preservation stability, an oxime compound or a pyrazole compound is preferable, and an oxime compound is particularly preferable.

In addition, it is preferable that the blocked isocyanate compound has an isocyanurate structure, from viewpoints of improving brittleness of the film, improving the adhesiveness with a transfer target, and the like. The blocked isocyanate compound having an isocyanurate structure can be prepared, for example, by converting hexamethylene diisocyanate into isocyanurate and protecting it.

Among blocked isocyanate compounds having an isocyanurate structure, a compound having an oxime structure using an oxime compound as a blocking agent is preferable, since a dissociation temperature is easily set in a preferable range and the development residue is easily reduced, compared to a compound having no oxime structure.

The blocked isocyanate compound used in the disclosure preferably has a radically polymerizable group, from a viewpoint of hardness after curing.

The radically polymerizable group is not particularly limited, and well-known polymerizable groups can be used, and examples thereof include a (meth)acryloxy group, a (meth)acrylamide group, an ethylenically unsaturated group such as styryl group, and an epoxy group such as a glycidyl group. Among these, as the polymerizable group, an ethylenically unsaturated group is preferable, and a (meth)acryloxy group is more preferable, from viewpoints of surface shape of the surface of the cured film to be obtained, a development speed, and reactivity.

As the blocked isocyanate compound used in the disclosure, a commercially available blocked isocyanate compound can also be used. Examples thereof include Karenz AOI-BM, Karenz MOI-BM, Karenz, Karenz MOI-BP (all manufactured by Showa Denko K.K.), and a block type Duranate series (manufactured by Asahi Kasei Chemicals Corporation).

A molecular weight of the blocked isocyanate compound used in the disclosure is preferably 200 to 3,000, more preferably 250 to 2,600, and particularly preferably 280 to 2,200.

In the disclosure, the thermal crosslinking compound may be used alone or in combination of two or more kinds thereof.

A content of the thermal crosslinking compound is preferably 1% by mass to 50% by mass and more preferably 5% by mass to 30% by mass, with respect to the total mass of the first transparent layer, from a viewpoint of the hardness of the obtained cured film.

<<Heterocyclic Compound>>

The first transparent layer of the first embodiment preferably further includes a heterocyclic compound, from viewpoints of discoloration prevention properties of the metal wiring in contact and linearity of an obtained pattern.

Examples of hetero atom included in the heterocyclic compound include an oxygen atom, a nitrogen atom, and a sulfur atom. Among them, from a viewpoint of discoloration prevention properties of the metal wiring in contact and linearity of the obtained pattern, it is preferable to have at least one atom selected from the group consisting of a nitrogen atom, a sulfur atom, and an oxygen atom as the hetero atom, and it is more preferable to have at least a nitrogen atom as the hetero atom.

The heterocyclic compound preferably has a nitrogen atom, from a viewpoint of discoloration prevention properties of metal wiring in contact, and linearity of the obtained pattern. The heterocyclic ring in the heterocyclic compound more preferably includes a nitrogen atom, the heterocyclic ring in the heterocyclic compound is even more preferably a 5-membered ring containing a nitrogen atom, and the heterocyclic ring in the heterocyclic compound is particularly preferably a 5-membered ring containing a nitrogen atom, a sulfur atom, and an oxygen atom.

In addition, the heterocyclic ring of the heterocyclic compound is preferably a 5-membered ring or a 6-membered ring and more preferably a 5-membered ring, from a viewpoint of discoloration prevention properties of metal wiring in contact and linearity of the obtained pattern.

The heterocyclic compound is preferably a heterocyclic compound having a mercapto group (thiol group) and more preferably a heterocyclic compound in which a mercapto group is directly bonded to the heterocyclic ring, from a viewpoint of discoloration prevention properties of metal wiring in contact and linearity of the obtained pattern.

In addition, in a case where the heterocyclic compound has a mercapto group, the number of mercapto groups in the heterocyclic compound is not particularly limited, but from a viewpoint of discoloration prevention properties of metal wiring in contact and linearity of the obtained pattern, it is preferably 1 to 6, more preferably 1 to 4, even more preferably 1 or 2, and particularly preferably 1.

Examples of the heterocyclic compound preferably include a triazole compound, a benzotriazole compound, a tetrazole compound, a thiadiazole compound, a triazine compound, a rhodanine compound, a thiazole compound, a benzothiazole compound, a benzimidazole compound, a benzoxazole compound, and a pyrimidine compound.

Among them, a triazole compound, a benzotriazole compound, a tetrazole compound, a thiadiazole compound, a triazine compound, a rhodanine compound, a thiazole compounds, a benzimidazole compounds, or a benzoxazole compound is preferable, a triazole compounds, a benzotriazole compound, a tetrazole compound, a thiadiazole compound, a thiazole compound, a benzothiazole compound, a benzimidazole compound, or a benzoxazole compound is more preferable, and a thiadiazole compound, a thiazole compound, a benzothiazole compound, or a benzoxazole compound is particularly preferable.

The heterocyclic compound is not particularly limited, but it is preferably a compound represented by any one of Formulae H1 to H13, from viewpoints of adhesiveness, discoloration prevention properties of metal wiring in contact, and linearity of the obtained pattern.

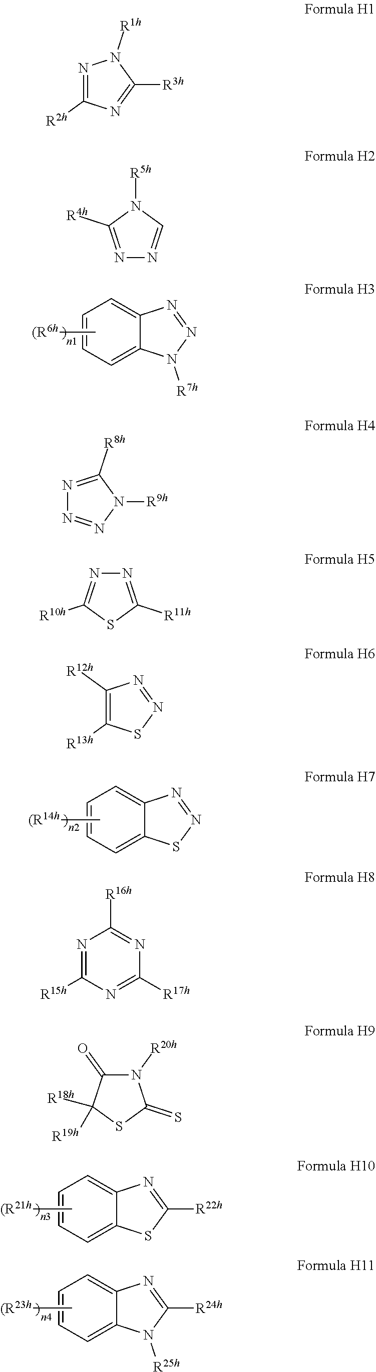

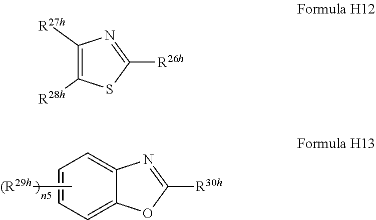

In Formulae H1 to H13, R^{1h}, R^{5h}, R^{7h}, R^{9h}, R^{20h}, and R^{25h} each independently represent a hydrogen atom, an alkyl group, an aryl group, a heteroaryl group, or an amino group, R^{2h} to R^{4h}, R^{8h}, R^{10h} to R^{13h}, R^{15h} to R^{18h}, R^{22h}, R^{24h}, R^{26h} to R^{28h}, and R^{30h} each independently represent a hydrogen atom, an alkyl group, an aryl group, a heteroaryl group, an amino group, an alkylamino group, an arylamino group, a mercapto group, an alkylthio group, or an arylthio group, R^{6h}, R^{14h}, R^{21h}, R^{23h}, and R^{29h} each independently represent a halogen atom, an alkyl group, an aryl group, a heteroaryl group, an amino group, an alkylamino group, an arylamino group, a mercapto group, an alkylthio group, an arylthio group, a carboxy group, a hydroxy group, an alkoxy group, or an aryloxy group, R^{19h} represents a hydrogen atom, an alkyl group, an aryl group, or a heteroaryl group, n1 to n5 each independently represents an integer of 0 to 4.

The compound represented by Formula H1 or Formula H2 is a triazole compound, the compound represented by Formula H3 is a benzotriazole compound, the compound represented by Formula H4 is a tetrazole compound, the compound represented by Formula H5 to Formula H7 is a thiadiazole compound, the compound represented by Formula H8 is a triazine compound, the compound represented by Formula H9 is a rhodanine compound, the compound represented by Formula H10 is a benzothiazole compound, the compound represented by Formula H11 is a benzimidazole compound, the compound represented by Formula H12 is a thiazole compound, and the compound represented by the Formula H13 is a benzoxazole compound.

R^{1h}, R^{7h}, R^{9h}, R^{20h}, and R^{25h} are each independently preferably a hydrogen atom, an alkyl group, an aryl group, or a heteroaryl group, more preferably a hydrogen atom or an alkyl group, and particularly preferably a hydrogen atom.

R^{5h} is preferably a hydrogen atom, an alkyl group, or an amino group and more preferably a hydrogen atom or an amino group.

R^{2h} to R^{4h}, R^{8h}, R^{10h} to R^{13h}, R^{22h}, R^{24h}, R^{26h} to R^{28h}, and R^{30h} are each independently preferably a hydrogen atom, an alkyl group, an aryl group, a heteroaryl group, an amino group, a mercapto group, or an alkylthio group, and more preferably a hydrogen atom, an amino group, a mercapto group, or an alkylthio group.

R^{15h} to R^{17h} are each independently preferably a hydrogen atom, an alkyl group, an aryl group, a heteroaryl group, an amino group, a mercapto group, or an alkylthio group, more preferably an amino group or a heteroaryl group, and particularly preferably an amino group or a pyridyl group.

In addition, from a viewpoint of synthesis, R^{15h} to R^{17h} are preferably the same group.

R^{18h} is preferably a hydrogen atom, an alkyl group, an aryl group, a heteroaryl group, an amino group, a mercapto group, or an alkylthio group, more preferably a hydrogen atom, an amino group, a mercapto group, or an alkylthio group, and even more preferably a hydrogen atom.

R^{6h}, R^{14h}, R^{21h}, R²³, and R^{29h} are each independently preferably an alkyl group, an aryl group, a heteroaryl group, an amino group, an alkylamino group, an arylamino group, a mercapto group, an alkylthio group, arylthio group, a carboxy group, a hydroxy group, an alkoxy group, or an aryloxy group, and more preferably an alkyl group, an aryl group, a heteroaryl group, an amino group, a mercapto group, an alkylthio group, an arylthio group, or a carboxy group.

In addition, in R^{6h}, R^{14h}, R^{21h}, R^{23h}, and R^{29h}, a hydrogen atom at any position on the benzene ring in each formula can be substituted and bonded.

R^{19h} is preferably a hydrogen atom or an alkyl group and more preferably a hydrogen atom.

n1 to n5 are each independently preferably an integer of 0 to 2, more preferably 0 or 1, and particularly preferably 0.

From a viewpoint of adhesiveness, the heterocyclic compound is preferably a compound represented by any of Formulae H1, H2, and H4 to H13, more preferably a compound represented by any of Formulae H4 to H13, even more preferably a compound represented by any of Formulae H5 to H7, H10 and H13, particularly preferably a compound represented by any of Formulae H5 to H7 and H13.

In addition, from a viewpoint of discoloration prevention properties metal wiring in contact and linearity of the obtained pattern, the heterocyclic compound is preferably a compound represented by any of Formulae H5 to H7 and H13, more preferably a compound represented by any of Formula H5, Formula H6, and Formula H13, even more preferably a compound represented by Formula H6 or a compound represented by Formula H13, and particularly preferably a compound represented by Formula H13.

As the heterocyclic compound, specifically, the following compounds can be preferably exemplified.

The following compounds can be exemplified as a triazole compound and a benzotriazole compound.

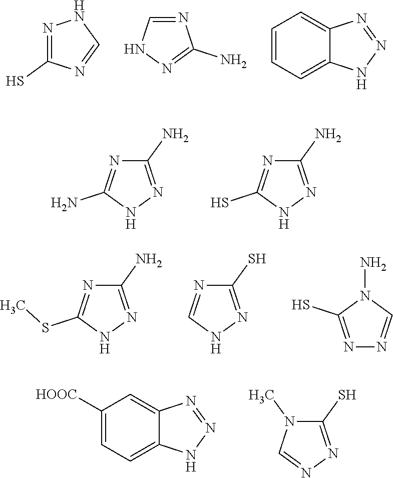

The following compounds can be exemplified as a tetrazole compound.

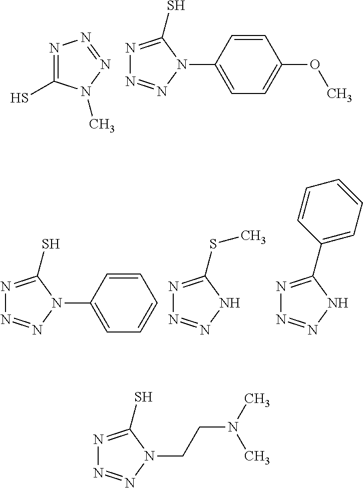

The following compounds can be exemplified as a thiadiazole compound.

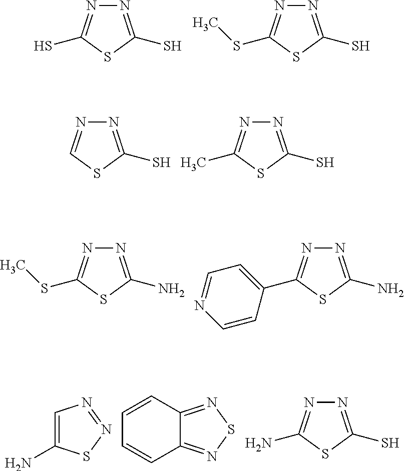

The following compounds can be exemplified as a triazine compound.

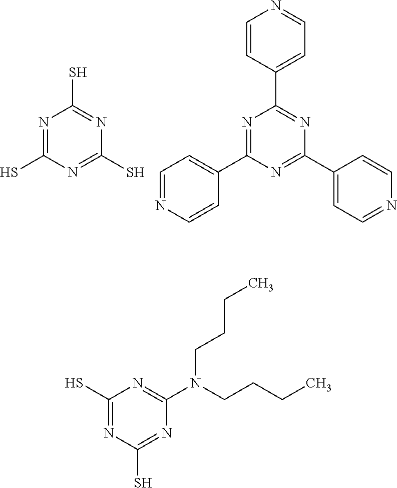

The following compounds can be exemplified as a rhodanine compound.

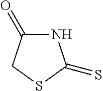

The following compounds are exemplified as a thiazole compound.

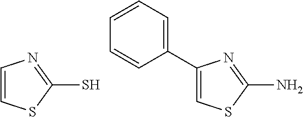

The following compounds are exemplified as a benzothiazole compound.

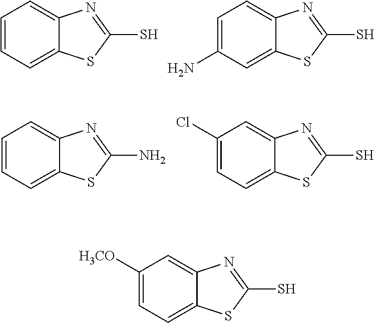 [SMILES: Sc1nc2ccccc2s1 ; Nc1ccc2nc(S)sc2c1 ; Nc1nc2ccccc2s1 ; Sc1nc2cc(Cl)ccc2s1 ; COc1ccc2sc(S)nc2c1]

The following compounds can be exemplified as a benzimidazole compound.

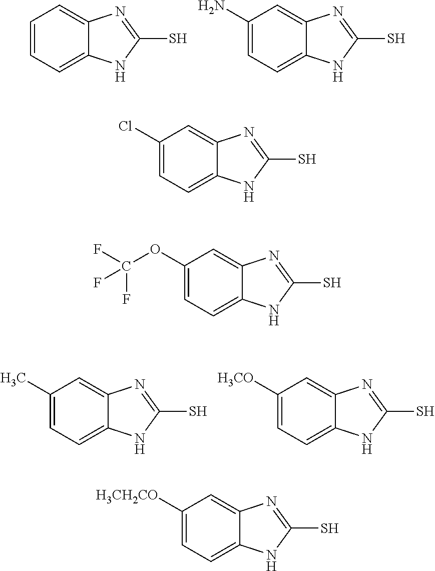

The following compounds can be exemplified as a benzoxazole compound.

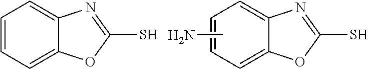

The first transparent layer may contain one kind or two or more kinds of the heterocyclic compound described above.

The content of the heterocyclic compound is not particularly limited, but from a viewpoint of the discoloration prevention properties metal wiring in contact and the linearity of the obtained pattern, is preferably 0.01% by mass to 20% by mass, more preferably 0.1% by mass to 10% by mass, even more preferably 0.5% by mass to 8% by mass, particularly preferably 1% by mass to 5% by mass, with respect to the total mass of the first transparent layer. In a case where the content thereof is in the above range, the obtained cured product is excellent in hardness and corrosion resistance to metal wiring, and the obtained cured product is excellent in transparency.

<<Thiol Compound>>

The first transparent layer in the first embodiment preferably further contains a thiol compound.

As the thiol compound, a monofunctional thiol compound or a polyfunctional thiol compound is preferably used. Among them, from a viewpoint of hardness after curing, the thiol compound preferably contains a di- or higher functional thiol compound (polyfunctional thiol compound) and is more preferably a polyfunctional thiol compound.

In the disclosure, the polyfunctional thiol compound refers to a compound having two or more mercapto groups (thiol groups) in a molecule. The polyfunctional thiol compound is preferably a low-molecular-weight compound having a molecular weight of 100 or more, and specifically, the molecular weight thereof is more preferably 100 to 1.500 and even more preferably 150 to 1000.

The number of functional groups of the polyfunctional thiol compound is preferably 2 to 10, more preferably 2 to 8, and even more preferably 2 to 6, from a viewpoint of hardness after curing.

In addition, the polyfunctional thiol compound is preferably an aliphatic polyfunctional thiol compound, from viewpoints of tackiness and bending resistance and hardness after curing.

Further, the thiol compound is more preferably a secondary thiol compound, from a viewpoint of bending resistance and hardness after curing.

Specific examples of the polyfunctional thiol compound include trimethylolpropane tris (3-mercaptobutyrate), 1,4-bis (3-mercaptobutyryloxy) butane, pentaerythritol tetrakis (3-mercaptobutyrate), 1,3,5-tris (3-mercaptobutyryloxyethyl)-1,3,5-triazine-2,4,6 (1H,3H,5H)-trione, trimethylolethanetris (3-mercaptobutyrate), tris [(3-mercaptopropionyloxy) ethyl]isocyanurate, trimethylolpropane tris (3-mercaptopropionate), pentaerythritol tetrakis (3-mercaptopropionate), tetraethylene glycol bis (3-mercaptopropionate), dipentaerythritol hexakis (3-mercaptopropionate), ethylene glycol bisthiopropionate, 1,4-bis (3-mercaptobutyryloxy) butane, 1,2-benzenedithiol, 1,3-benzenedithiol, 1,2-ethanedithiol, 1,3-propanedithiol, 1,6-hexamethylenedithiol, 2,2′-(ethylenedithio) diethanethiol, meso-2,3-dimercaptosuccinic acid, p-xylylenedithiol, m-xylylenedithiol, and di(mercaptoethyl) ether.

Among these, trimethylolpropane tris (3-mercaptobutyrate), 1,4-bis (3-mercaptobutyryloxy) butane, pentaerythritol tetrakis (3-mercaptobutyrate), 1,3,5-tris (3-mercaptobutyryloxyethyl)-1,3,5-triazine-2,4,6 (1H, 3H, 5H)-trione, trimethylolethanetris (3-mercaptobutyrate), tris [(3-mercaptopropionyloxy) ethyl] isocyanurate, trimethylolpropane tris (3-mercaptopropionate), pentaerythritol tetrakis (3-mercaptopropionate), tetraethylene glycol bis (3-mercaptopropionate), and dipentaerythritol hexakis (3-mercaptopropionate) are preferable.

As the monofunctional thiol compound, both an aliphatic thiol compound and an aromatic thiol compound can be used.

Specific examples of the monofunctional aliphatic thiol compound include 1-octanethiol, 1-dodecanethiol, β-mercaptopropionic acid, methyl-3-mercaptopropionate, 2-ethylhexyl-3-mercaptopropionate, n-octyl-3-mercaptopropionate, methoxybutyl-3-mercaptopropionate, and stearyl-3-mercaptopropionate.

Examples of the monofunctional aromatic thiol compound include benzenethiol, toluenethiol, and xylenethiol.

The thiol compound is preferably a thiol compound having an ester bond and more preferably includes a compound represented by Formula 1, from a viewpoint of tackiness, bending resistance and hardness after curing.

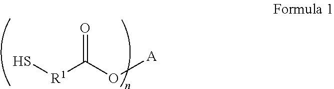

In Formula 1, n represents an integer of 1 to 6, A represents an n-valent organic group having 1 to 15 carbon atoms or a group represented by Formula 2, and R¹'s each independently represent a divalent organic group having 1 to 15 carbon atoms. Here, in a case where A represents a group represented by Formula 2, n represents 3.

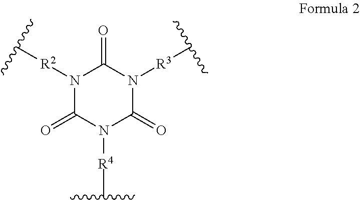

In Formula 2, R² to R⁴ each independently represent a divalent organic group having 1 to 15 carbon atoms, and wavy line parts represent bonding positions to an oxygen atom adjacent to A in Formula 1.

From a viewpoint of hardness after curing, n in Formula 1 is preferably an integer of 2 to 6.

A in Formula 1 is preferably an n-valent aliphatic group having 1 to 15 carbon atoms or a group represented by Formula 2, more preferably an n-valent aliphatic group having 4 to 15 carbon atoms or a group represented by Formula 2, even more preferably an n-valent aliphatic group having 5 to 10 carbon atoms or a group represented by Formula 2, and particularly preferably a group represented by Formula 2, from a viewpoint of tackiness, and bending resistance and hardness after curing.

In addition, A in Formula 1 is preferably an n-valent group consisting of a hydrogen atom and a carbon atom or an n-valent group consisting of a hydrogen atom, a carbon atom, and an oxygen atom, more preferably an n-valent group consisting of a hydrogen atom and a carbon atom, and particularly preferably an n-valent aliphatic hydrocarbon group, from a viewpoint of tackiness, bending resistance and hardness after curing.

R¹'s in Formula 1 are each independently preferably an alkylene group having 1 to 15 carbon atoms, more preferably an alkylene group having 2 to 4 carbon atoms, even more preferably an alkylene group having 3 carbon atoms, and particularly preferably a 1,2-propylene group, from a viewpoint of tackiness, bending resistance and hardness after curing. The alkylene group may be linear or branched.

R² to R⁴ in Formula 2 are each independently preferably an aliphatic group having 2 to 15 carbon atoms, more preferably an alkylene group having 2 to 15 carbon atoms or a polvalkyleneoxyalkyl group having 3 to 15 carbon atoms, even more preferably an alkylene group having 2 to 15 carbon atoms, and particularly preferably an ethylene group, from a viewpoints of tackiness, and bending resistance and hardness after curing.

In addition, as the polyfunctional thiol compound, a compound having two or more groups represented by Formula S-1 is preferable.

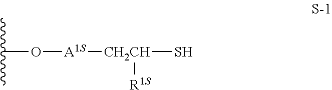

In Formula S-1, R^{1S} represents a hydrogen atom or an alkyl group, A^{1S} represents —CO— or —CH₂—, and wavy line parts represent bonding positions to another structure.

The polyfunctional thiol compound is preferably a compound having 2 to 6 groups represented by Formula S-1.

The alkyl group of R^{1S} in Formula S-1 is a linear, branched, or cyclic alkyl group, and a range of the number of carbon atoms is preferably 1 to 16 and more preferably 1 to 10. Specific examples of the alkyl group include a methyl group, an ethyl group, a propyl group, an isopropyl group, a butyl group, an isobutyl group, an s-butyl group, a t-butyl group, a pentyl group, a hexyl group, and a 2-ethylhexyl group, and a methyl group, an ethyl group, a propyl group, or an isopropyl group is preferable.

As R^{1S}, a hydrogen atom, a methyl group, an ethyl group, a propyl group, or an isopropyl group is particularly preferable, and a methyl group or an ethyl group is most preferable.

In addition, the polyfunctional thiol compound is particularly preferably a compound represented by Formula S-2 having a plurality of groups represented by Formula S-1.

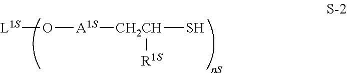

In Formula S-2, R^{1S}'s each independently represent a hydrogen atom or an alkyl group, A^{1S}'s each independently represent —CO— or —CH₂—, L^{1S} represents an nS-valent linking group, and nS represents an integer of 2 to 8. From a viewpoint of synthesis, it is preferable that all R^{1S}'s have the same group, and that all A^{1S}'s have the same group.

R^{1S} in Formula S-2 is same as R^{1S} in Formula S-1 and the preferred range is also the same. nS is preferably an integer of 2 to 6.

Examples of L^{1S}, which is an nS-valent linking group in Formula S-2, include a divalent linking group such as —(CH₂)_{mS}— (mS represents an integer of 2 to 6), a trivalent linking group such as a trimethylolpropane residue, isocyanuric ring having three of —(CH₂)_{pS}— (pS represents an integer of 2 to 6), a tetravalent linking group such as a pentaerythritol residue, and a pentavalent or hexavalent linking group such as a dipentaerythritol residue.

Specific examples of the thiol compound preferably include the following compounds, but are not limited thereto.

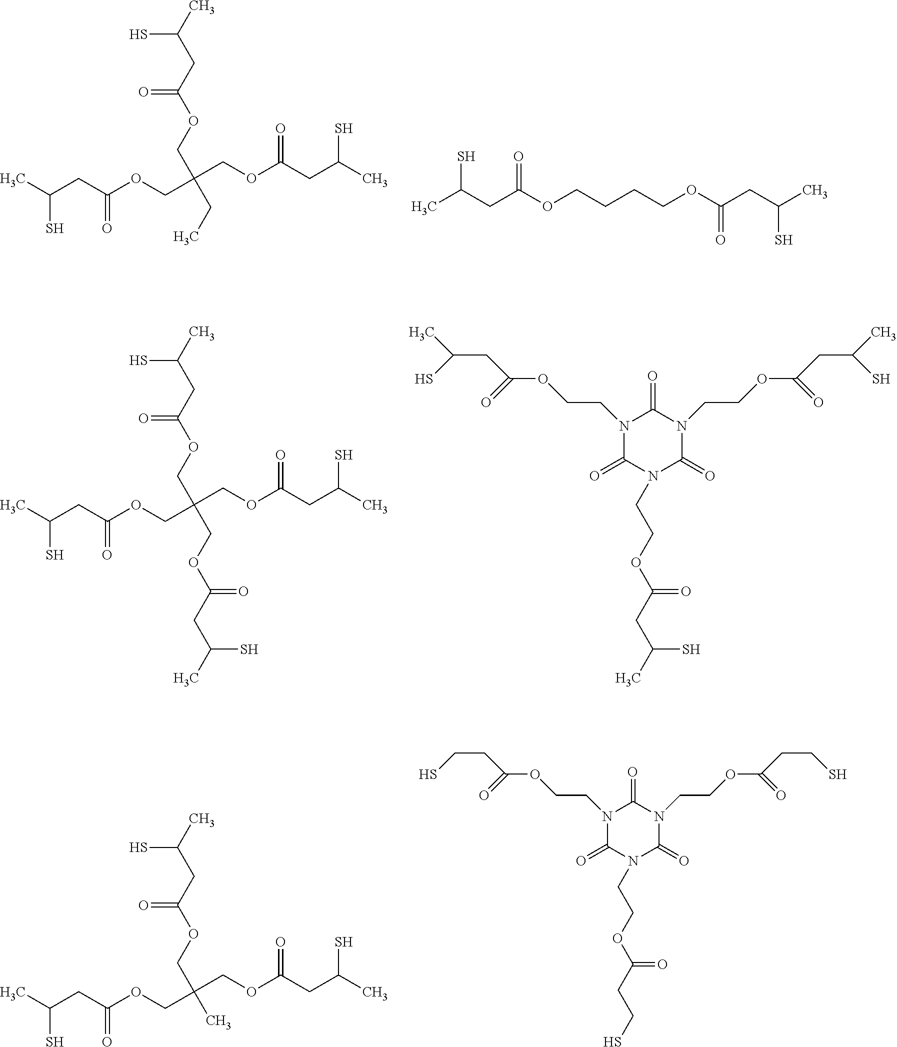 [SMILES: CCC(COC(=O)CC(C)S)(COC(=O)CC(C)S)COC(=O)CC(C)S ; CC(S)CC(=O)OCCCCOC(=O)CC(C)S ; CC(S)CC(=O)OCC(COC(=O)CC(C)S)(COC(=O)CC(C)S)COC(=O)CC(C)S ; CC(S)CC(=O)OCCn1c(=O)n(CCOC(=O)CC(C)S)c(=O)n(CCOC(=O)CC(C)S)c1=O ; CC(S)CC(=O)OCC(C)(COC(=O)CC(C)S)COC(=O)CC(C)S ; O=C(CCS)OCCn1c(=O)n(CCOC(=O)CCS)c(=O)n(CCOC(=O)CCS)c1=O]

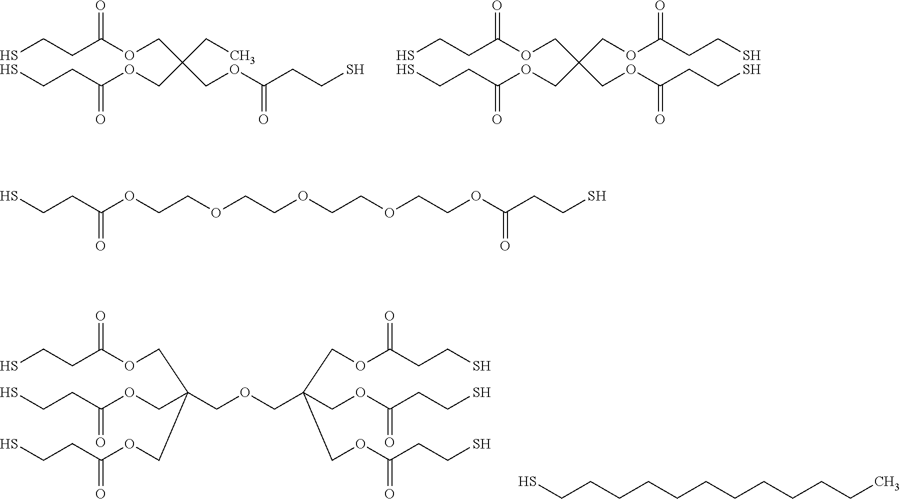 [SMILES: CCC(COC(=O)CCS)(COC(=O)CCS)COC(=O)CCS ; O=C(CCS)OCC(COC(=O)CCS)(COC(=O)CCS)COC(=O)CCS ; O=C(CCS)OCCOCCOCCOCCOC(=O)CCS ; O=C(CCS)OCC(COCC(COC(=O)CCS)(COC(=O)CCS)COC(=O)CCS)(COC(=O)CCS)COC(=O)CCS ; CCCCCCCCCCCCS]

The thiol compounds may be used alone or in combination of two or more thereof.

The content of the thiol compound is preferably 0.1% by mass to 40% by mass, more preferably 0.5% by mass to 30% by mass, and particularly preferably 1% by mass to 25% by mass, with respect to the total mass of the first transparent layer.

<<Surfactant>>

The first transparent layer in the first embodiment contains a surfactant.

As the surfactant, for example, surfactants disclosed in paragraph 0017 of JP4502784B and paragraphs 0060 to 0071 of JP2009-237362A, well-known fluorine-based surfactants, and the like can be used.

As the surfactant, a fluorine-based surfactant is preferable.

As a commercially available fluorine-based surfactant, MEGAFACE (registered trademark) F551 (manufactured by DIC Corporation) is used.

In a case where the first transparent layer includes a surfactant, a content of the surfactant is preferably 0.01% by mass to 3% by mass, more preferably 0.05% by mass to 1% by mass, and even more preferably 0.1% by mass to 0.8% by mass, with respect to the total mass of the first transparent layer.

<<Polymerization Inhibitor>>

The first transparent layer in the first embodiment contains a polymerization inhibitor.

As the polymerization inhibitor, for example, a thermal polymerization inhibitor (also referred to as a polymerization inhibitor) disclosed in paragraph 0018 of JP4502784B can be used.

Among them, phenothiazine, phenoxazine, or 4-methoxyphenol can be preferably used.

In a case where the first transparent layer includes a polymerization inhibitor, a content of the polymerization inhibitor is preferably 0.01% by mass to 3% by mass, more preferably 0.01% by mass to 1% by mass, and even more preferably 0.01% by mass to 0.8% by mass, with respect to the total mass of the first transparent layer.

<<Hydrogen Donating Compound>>

The first transparent layer in the first embodiment preferably further contains a hydrogen donating compound.

In the disclosure, the hydrogen donating compound has an action of further improving sensitivity of the photopolymerization initiator to active light, or suppressing inhibition of polymerization of the polymerizable compound by oxygen.

Examples of such a hydrogen donating compound include amines, for example, M. R. Sander et al., “Journal of Polymer Society,” Vol. 10, page 3173 (1972), JP1969-020189B (JP-S-44-020189B), JP1976-082102A (JP-S-51-082102A), JP1977-134692A (JP-S-52-134692A). JP1984-138205A (JP-S-59-138205A), JP1985-084305A (JP-S-60-084305A), JP1987-018537A (JP-S-62-018537), JP1989-033104A (JP-S-64-033104A), and Research Disclosure 33825, and specific examples thereof include triethanolamine, p-dimethylaminobenzoic acid ethyl ester, p-formyldimethylaniline, and p-methylthiodimethylaniline.

In addition, other examples of the hydrogen donating compound further include an amino acid compound (for example, N-phenylglycine or the like), an organic metal compound disclosed in JP1973-042965B (JP-S48-042965B) (for example, tributyltin acetate, or the like), a hydrogen donor disclosed in JP1980-034414B (JP-S55-034414B), and a sulfur compound disclosed in JP1994-308727A (JP-H6-308727A) (for example, trithiane or the like).

A content of the hydrogen donating compounds is preferably in a range of 0.1% by mass to 30% by mass, more preferably in a range of 1% by mass to 25% by mass, and even more preferably in a range of 0.5% by mass to 20% by mass, with respect to the total mass of the first transparent layer, from a viewpoint of improving a curing speed with balance between a polymerization growth speed and chain transfer.

<<Silane Coupling Agent and Titanium Coupling Agent>>

From a viewpoint of dispersion stability of the metal oxide particle, the first transparent layer in the first embodiment preferably further contains a silane coupling agent or a titanium coupling agent. In addition, the first transparent layer may contain both the silane coupling agent and the titanium coupling agent.

The silane coupling agent and the titanium coupling agent may be used alone or in combination of two or more kinds thereof.

A total content of the silane coupling agent and the titanium coupling agent is preferably 0.1% by mass to 30% by mass, more preferably 0.2% by mass to 20% by mass, even more preferably 0.5% by mass to 10% by mass, and particularly preferably 0.5% by mass to 5% by mass, with respect to a total mass of the first transparent layer.

The silane coupling agent is not particularly limited and dimethyldimethoxysilane, dimethyldiethoxysilane, methylethyldimethoxysilane, methylethyldiethoxysilane, methyltrimethoxysilane, methyltriethoxysilane, ethyltrimethoxysilane, decyltrimethoxysilane, phenyltriethoxysilane, p-styryltrimethoxysilane, vinyltrichlorosilane, vinyltrimethoxysilane, vinvltriethoxysilane, allyltrimethoxysilane, 3-methacryloxypropyltriethoxysilane, 3-methacryloxypropyltrimethoxysilane, 3-methacryloxypropylmethyldiethoxysilane, 3-methacryloxypropylmethyldimethoxysilane, 2-methacryloxypropyltrimethoxysilane, 3-acryloxypropyltrimethoxysilane, 3-chloropropyltrimethoxysilane, 3-glycidoxypropyltrimethoxysilane, 3-glycidoxypropylmethyldiethoxysilane, 2-(3,4-epoxycyclohexyl) ethyltrimethoxysilane, 3-(3,4-epoxycyclohexyl), N-2 (aminoethyl)-3-aminopropyltrimethoxysilane, 3-aminopropyltriethoxysilane, N-phenyl-3-aminopropyltrimethoxysilane, 3-mercaptopropyltrimethoxysilane, 3-isocyanatepropyltriethoxysilane, 3-ureidopropyltrialkoxysilanetris-(trimethoxysilylpropyl) isocyanurate, methyl triisocyanate silane, and the like can be used, and these may be used alone or in combination of a plurality thereof. Among these, 3-methacryloxypropyltrimethoxysilane, 3-acryloxypropyltrimethoxysilane, and 3-glycidoxypropyltrimethoxysilane are preferable, from a viewpoint of dispersion stability of the metal oxide particle.

Commercially available products can be used as the silane coupling agent and examples thereof include KA-1003, KBM-1003, KBE-1003, KBM-303, KBM-403, KBE-402, KBE-403, KBM-1403, KBM-502, KBM-503, KBE-502, KBE-503, KBM-5103, KBM-602, KBM-603, KBE-603, KBM-903, KBE-903, KBE-9103, KBM-573, KBM-575, KBM-6123, KBE-585, KBM-703, KBM-802, KBM-803, KBE-846, KBE-9007, KBM-04, KBE-04, KBM-13, KBE-13, KBE-22, KBE-103, HMDS-3, KBM-3063, KBM-3103C, KPN-3504, and KF-99 (all manufactured by Shin-Etsu Chemical Co., Ltd.)

The titanium coupling agent is not particularly limited, and examples thereof include isopropyltriisostearoyl titanate, isopropyltri-n-dodecylbenzenesulfonyl titanate, isopropyltris (dioctylpyrophosphate) titanate, tetraisopropylbis (dioctylphosphite) titanate, tetraoctylbis (ditridecylphosphite) titanate, tetra (2,2-diallyloxymethyl-1-butyl) bis (di-tridecyl) phosphite titanate, bis (dioctylpyrophosphate) oxyacetate titanate, bis (dioctylpyrophosphate) ethylene titanate, isopropyltrioctanoyl titanate, isopropyldimethacryloyl isostearoyl titanate, isopropylisostearoyl diacrylic titanate, isopropyltri (dioctyl phosphate) titanate, isopropyltricylphenyl titanate, isopropyltri (N-aminoethyl-aminoethyl) titanate, tetraisopropyl titanate, tetranormal butyl titanate, butyl titanate dimer, tetrakis (2-ethylhexyl) titanate, tetrastearyl titanate, tetramethyl titanate, diethoxybis (acetylacetonato) titanium, diisopropylbis (acetylacetonato) titanium, diisopropoxybis (ethylacetoneacetate) titanium, isopropoxy (2-ethyl-1,3-hexanediorat) titanium, di(2-ethylhexoxy) bis (2-ethyl-1,3-hexanediorat) titanium, di-n-butoxybis (triethanolamineato) titanium, tetraacetylacetone titanium, hydroxybis (lactoto) titanium, dicumylphenyloxyacetate titanate, and diisostearoylethylene titanate.

As the titanium coupling agent, a commercially available product can be used, and examples thereof include KR-TTS, KR-46B, KR-55, KR-41B, KR-38S, KR-138S, KR-238S, 338X, KR44, and KR9SA which are Plenact series manufactured by Ajinomoto Fine-Techno Co., Ltd.; TA-10, TA-25, TA-22, TA-30, TC-100, TC-200, TC-401, and TC-750 which are Organtics series manufactured by Matsumoto Fine Chemicals Co., Ltd.; A-1, B-1, TOT, TST, TAA, TAT, TLA, TOG. TBSTA, A-10, TBT, B-2, B4, B-7, B-10. TBSTA-400. TTS, TOA-30, TSDMA, TTAB, and TTOP manufactured by Nippon Soda Co., Ltd.

<<Other Components>>

The first transparent layer of the disclosure may include a component other than the components described above.

Examples of the other components include a thermal polymerization inhibitor disclosed in paragraph 0018 of JP4502784B, and other additives disclosed in paragraphs 0058 to 0071 of JP2000-310706A.

In addition, the first transparent layer may include a small amount of colorant (pigment, dye, and the like) as the other component, but it is preferable that a colorant is not substantially included, from a viewpoint of transparency.

Specifically, a content of the colorant in the first transparent layer is preferably smaller than 1% by mass and more preferably smaller than 0.1% by mass with respect to a total mass of the first transparent layer.

A thickness of the first transparent layer is preferably 20 μm or less, more preferably 15 μm or less, and particularly preferably 12 μm or less.

It is advantageous in a case where the thickness of the first transparent layer is 20 μm or less, from viewpoints of reducing a thickness of the entire transfer film, improving transmittance of the first transparent layer or the cured film to be obtained, and suppressing yellowing of the first transparent layer or the cured film to be obtained.

From a viewpoint of manufacturing suitability, the thickness of the first transparent layer is preferably 0.5 μm or more, more preferably 1 μm or more, and particularly preferably 2 μm or more.

The refractive index of the first transparent layer in the first embodiment is preferably 1.50 to 2.10, more preferably 1.60 to 1.90, even more preferably 1.63 to 1.80, and particularly preferably 1.65 to 1.78, from a viewpoint of concealing properties of the transparent electrode pattern.

In the disclosure, the “refractive index” indicates a refractive index at a wavelength of 550 nm.

The “refractive index” in the disclosure means a value measured with visible light at a wavelength of 550 nm at a temperature of 23° C. by ellipsometry, unless otherwise noted.

A method for forming the first transparent layer is not particularly limited, and a well-known method can be used.

As an example of the method for forming the first transparent layer, a method forming the photosensitive layer by applying a photosensitive resin composition containing a solvent onto a temporary support and then drying, as necessary is used.

As the coating method, a well-known method can be used, and examples thereof include a printing method, a spraying method, a roll coating method, a bar coating method, a curtain coating method, a spin coating method, and a die coating method (that is, slit coating method), and a die coating method is preferable.

As the drying method, a well-known method such as natural drying, heating drying, and drying under reduced pressure can be applied alone or in combination of plural thereof.

—Solvent—

The photosensitive resin composition preferably further includes a solvent, from a viewpoint of forming a layer by applying.

As the solvent, a solvent normally used can be used without particular limitations.

The solvent is preferably an organic solvent.

Examples of the organic solvent include methyl ethyl ketone, propylene glycol monomethyl ether, propylene glycol monomethyl ether acetate (another name: 1-methoxy-2-propyl acetate), diethylene glycol ethyl methyl ether, cyclohexanone, methyl isobutyl ketone, ethyl lactate, methyl lactate, caprolactam, n-propanol, and 2-propanol. In addition, the solvent used may include a mixed solvent which is a mixture of these compounds.

As the solvent, a mixed solvent of methyl ethyl ketone and propylene glycol monomethyl ether acetate, or a mixed solvent of diethylene glycol ethyl methyl ether and propylene glycol monomethyl ether acetate is preferably used.

In a case of using the solvent, a content of solid contents of the photosensitive resin composition is preferably 5% by mass to 80% by mass, more preferably 5% by mass to 40% by mass, and particularly preferably 5% by mass to 30% by mass with respect to a total amount of the photosensitive resin composition.

In a case of using the solvent, a viscosity (25° C.) of the photosensitive resin composition is preferably 1 mPa-s to 50 mPa s, more preferably 2 mPa-s to 40 mPa s, and particularly preferably 3 mPa-s to 30 mPa s, from a viewpoint of coating properties.

The viscosity is, for example, measured using VISCOMETER TV-22 (manufactured by Toki Sangyo Co. Ltd.).

In a case where the photosensitive resin composition includes the solvent, a surface tension (25° C.) of the photosensitive resin composition is preferably 5 mN/m to 100 mN/m, more preferably 10 mN/m to 80 mN/m, and particularly preferably 15 mN/m to 40 mN/m, from a viewpoint of coating properties.

The surface tension is, for example, measured using Automatic Surface Tensiometer CBVP-Z (manufactured by Kyowa Interface Science Co., Ltd.).

As the solvent, a solvent disclosed in paragraphs 0054 and 0055 of US2005/282073A can also be used, and the content of this specification is incorporated in the present specification.

In addition, as the solvent, an organic solvent (high-boiling-point solvent) having a boiling point of 180° C. to 250° C. can also be used, as necessary.

In a case where the first transparent layer is formed of the photosensitive resin composition containing a solvent, it is not necessary that the solvent in the first transparent layer is completely removed, and a content of the solvent in the first transparent layer is preferably 1% by mass or less and more preferably 0.5% by mass or less, with respect to the total mass of the first transparent layer.

<Protective Film>

The transfer film of the first embodiment according to the disclosure may further comprise a protective film on a side opposite to the temporary support from the first transparent layer.

Examples of the protective film include a polyethylene terephthalate film, a polypropylene film, a polystyrene film, and a polycarbonate film.

It is preferable that the film used as the protective film does not have deformation such as wrinkles or scratches.

A haze of the film used as the protective film is preferably 1.0% or less, and a total number of particles having a diameter of 5 μm or more and aggregates having a diameter of 5 μm or more included in the film is preferably 5 piece/mm² or less.

In addition, on both surfaces of the protective film, a density of broken bubble marks having a diameter of 40 μm to 100 μm caused by rupture of bubbles in the resin of the protective film is preferably 5 piece/0.25 m² or less.

Examples of the protective film satisfying the above include LUMIRROR 16QS62 (manufactured by Toray Industries. Inc.), LUMIRROR 16QS52 (manufactured by Toray Industries, Inc.), LUMIRROR 16QS48 (manufactured by Toray Industries, Inc.), LUMIRROR 12QS62 (manufactured by Toray Industries, Inc.), TORAYFAN 12KW37 (manufactured by Toray Industries, Inc.). TORAYFAN 25KW37 (manufactured by Toray Industries, Inc.), ALPHAN E-501L (Oji F-Tex Co., Ltd.), and ALPHAN HS-501 (Oji F-tex Co., Ltd.).

A thickness of the protective film is not particularly limited, and is, for example, preferably 5 μm to 200 μm, and is particularly preferably 10 μm to 150 μm, from viewpoints of ease of handling and general-purpose properties.

<Thermoplastic Resin Layer>

The transfer film of the first embodiment according to the disclosure may further comprise a thermoplastic resin layer between a temporary support and a first transparent layer.

In a case where the transfer film comprises the thermoplastic resin layer and the transfer film is transferred to a substrate to form a laminate, air bubbles are hardly generated on each element of the laminate. In a case where this laminate is used in an image display device, image unevenness is hardly generated and excellent display properties are obtained.

The thermoplastic resin layer preferably has alkali solubility.

The thermoplastic resin layer functions as a cushion material which absorbs ruggedness of the surface of the substrate at the time of transfer.

The ruggedness of the surface of the substrate includes an image, an electrode, a wiring, and the like which are formed in advance. The thermoplastic resin layer preferably has properties capable of being deformed in accordance with ruggedness.

The thermoplastic resin layer preferably includes an organic polymer substance disclosed in JP1993-072724A (JP-H5-072724A), and more preferably includes an organic polymer substance having a softening point approximately equal to or lower than 80° C. by a Vicat method (specifically, polymer softening point measurement method using an American Society for Testing and Materials ASTM D1235).

A thickness of the thermoplastic resin layer is preferably 3 m to 30 μm, more preferably 4 μm to 25 μm, and even more preferably 5 μm to 20 μm.

In a case where the thickness of the thermoplastic resin layer is equal to or greater than 3 μm, followability with respect to the ruggedness of the surface of the substrate is improved, and accordingly, the ruggedness of the surface of the substrate can be effectively absorbed.

In a case where the thickness of the thermoplastic resin layer is equal to or smaller than 30 μm, process suitability is further improved. For example, burden of the drying (solvent removal) in a case of applying and forming the thermoplastic resin on the temporary support is further reduced, and the development time of the thermoplastic resin layer after the transfer is shortened.

The thermoplastic resin layer can be formed by applying and, as necessary, drying a composition for forming a thermoplastic resin layer including a solvent and a thermoplastic organic polymer on the temporary support.

Specific examples of the coating and drying method are respectively the same as the specific examples of the coating and drying in a case of forming the first transparent layer.

The solvent is not particularly limited, as long as a polymer component forming the thermoplastic resin layer is dissolved, and examples thereof include organic solvents (for example, methyl ethyl ketone, cyclohexanone, propylene glycol monomethyl ether acetate, n-propanol, and 2-propanol).

A viscosity of the thermoplastic resin layer measured at 100° C. is preferably 1,000 to 10.000 Pa·s. In addition, the viscosity of the thermoplastic resin layer measured at 100° C. is preferably lower than the viscosity of the first transparent layer measured at 100° C.

<Interlayer>

The transfer film of the first embodiment according to the disclosure may further comprise an interlayer between a temporary support and a first transparent layer.

In a case where the transfer film according to the disclosure comprises the thermoplastic resin layer, the interlayer is preferably disposed between the thermoplastic resin layer and the first transparent layer.

As the component of the interlayer, a resin which is a mixture including polyvinyl alcohol, polyvinyl pyrrolidone, cellulose, or at least two kinds thereof.

In addition, as the interlayer, a component disclosed in JP1993-072724A (JP-H5-072724A) as a“separation layer” can also be used.

In a case of producing the transfer film of the embodiment comprising the thermoplastic resin layer, the interlayer, and the first transparent layer on the temporary support in this order, the interlayer can be, for example, formed by applying and, as necessary, drying a composition for forming an interlayer including a solvent which does not dissolve the thermoplastic resin layer, and the resin as the component of the interlayer. Specific examples of the coating and drying method are respectively the same as the specific examples of the coating and drying in a case of forming the first transparent layer.

In this case, for example, first, the composition for forming a thermoplastic resin layer is applied and dried on the temporary support to form the thermoplastic resin layer. Next, the composition for forming an interlayer is applied and dried on this thermoplastic resin layer to form the interlayer. After that, the photosensitive resin composition of the embodiment including the organic solvent is applied and dried on the interlayer to form the first transparent layer. The organic solvent in this case is preferably an organic solvent which does not dissolve the interlayer.

<Other Layers>

The transfer film of the first embodiment according to the present disclosure may further include other layers.

The other layer is not particularly limited and may include a known layer in the transfer film.

—Impurities—

In the transfer film according to the present disclosure, from a viewpoint of improving reliability or patterning property, it is preferable that the content of impurities in each layer described above is small.

Specific examples of impurities include sodium, potassium, magnesium, calcium, iron, manganese, copper, aluminum, titanium, chromium, cobalt, nickel, zinc, tin, ions thereof, and halide ions (chloride ions, bromide ion, and iodide ion) and the like. Among those, sodium ion, potassium ion, and chloride ion are easily mixed as impurities, and accordingly, the following content is particularly preferable.

The content of impurities in each layer is preferably 1,000 ppm or less, more preferably 200 ppm or less, and particularly preferably 40 ppm or less based on mass. Although the lower limit is not particularly defined, it can be set to 10 ppb or more and 100 ppb or more based on mass, from a viewpoint of the limit that can be reduced in practice and a measurement limit. As a specific numerical value of each impurities, for example, 0.1 ppm can be set.

Examples of the method for reducing impurities to the above range include selecting a raw material of each layer containing no impurities, preventing impurities from being mixed in at the time of forming the layer, and washing and removing the impurities. By such a method, the amount of impurities can be kept within the above range.

The impurities can be quantified by well-known methods such as Inductively Coupled Plasma (ICP) emission spectroscopy, atomic absorption spectroscopy, and ion chromatography.

In addition, it is preferable that a content of compounds such as benzene, formaldehyde, trichlorethylene, 1,3-butadiene, carbon tetrachloride, chloroform, N,N-dimethylformamide, N,N-dimethylacetamide, and hexane in each layer is small. The content of these compounds in each layer is preferably 1,000 ppm or less, more preferably 200 ppm or less, and particularly preferably 40 ppm or less based on mass. Although the lower limit is not particularly defined, it can be set to 10 ppb or more and 100 ppb or more based on mass, from a viewpoint of the limit that can be reduced in practice and a measurement limit.

The content of impurities in the compound can be suppressed in the same manner as the impurities in the metal described above. In addition, it can be quantified by a well-known measurement method.

### Second Embodiment

A transfer film of a second embodiment according to the disclosure includes a temporary support, a first transparent layer including a polymerizable compound, a polymerization initiator, and a resin, and a second transparent layer, and the second transparent layer contains a metal oxide particle containing titanium oxide and tin oxide.

A temporary support, a protective film, a thermoplastic resin layer, and other layers of the transfer film of the second embodiment according to the present disclosure, and the preferred embodiments thereof, are the same as the temporary support, the protective film, the thermoplastic resin layer, and the other layers of the transfer film of the first embodiment according to the disclosure, and the preferred embodiments thereof.

<First Transparent Layer>

The transfer film of the second embodiment according to the disclosure includes a temporary support, and a first transparent layer including a polymerizable compound, a polymerization initiator, and a resin.

The transfer film according to the disclosure includes a first transparent layer including a polymerizable compound, a polymerization initiator, and a resin on a temporary support.

The first transparent layer in the second embodiment contains a specific particle.

The preferred embodiment of the specific particle that may be contained in the first transparent layer in the second embodiment is the same as the preferred embodiment of the specific particle contained in the first transparent layer in the second embodiment.

In the present disclosure, “transparent” means that a transmittance of visible light having a wavelength of 400 nm to 700 nm is 80% or more. Accordingly, the “transparent layer” indicates a layer having a transmittance of visible light having a wavelength of 400 nm to 700 nm is 80% or more. The transmittance of the visible light of the “transparent layer” is preferably 90% or more.

In addition, a light transmittance of each layer of the transfer film and the transfer film is a value measured using a spectrophotometer, and can be measured, for example, using a spectrophotometer U-3310 manufactured by Hitachi, Ltd.

<<Polymerizable Compound>>

The first transparent layer in the second embodiment contains a polymerizable compound.

The polymerizable compound is a component that contributes to photosensitivity (that is, photocuring properties) and strength of the cured film to be obtained.

As the polymerizable compound used in the first transparent layer in the second embodiment, the same polymerizable compound as the polymerizable compound used in the first transparent layer in the first embodiment can be used, and the same also applies to the preferred embodiment.

The ethylenically unsaturated compound may be used alone or in combination of two or more thereof.

The content of the ethylenically unsaturated compound is preferably 1% by mass to 70% by mass, more preferably 10% by mass to 70% by mass, even more preferably 20% by mass to 60% by mass, and particularly preferably 20% by mass to 50% by mass, with respect to a total mass of the first transparent layer.

In addition, in a case where the first transparent layer includes a difunctional ethylenically unsaturated compound and a tri- or higher functional ethylenically unsaturated compound, the content of the difunctional ethylenically unsaturated compound is preferably 10% by mass to 90% by mass, more preferably 20% by mass to 85% by mass, and even more preferably 30% by mass to 80% by mass, with respect to all of the ethylenically unsaturated compounds included in the first transparent layer.

In this case, the content of the tri- or higher functional ethylenically unsaturated compound is preferably 10% by mass to 90% by mass, more preferably 15% by mass to 80% by mass, and even more preferably 20% by mass to 70% by mass, with respect to all of the ethylenically unsaturated compounds included in the first transparent layer.

In this case, the content of the di- or higher functional ethylenically unsaturated compound is preferably 40% by mass or more and less than 100% by mass, more preferably 40% by mass to 90% by mass, even more preferably 50% by mass to 80% by mass, and particularly preferably 50% by mass to 70% by mass, with respect to a total content of the difunctional ethylenically unsaturated compound and the tri- or higher functional ethylenically unsaturated compound.

In addition, in a case where the first transparent layer includes a di- or higher functional ethylenically unsaturated compound, the first transparent layer may further include a monofunctional ethylenically unsaturated compound.

Further, in a case where the first transparent layer includes a di- or higher functional ethylenically unsaturated compound, the di- or higher functional ethylenically unsaturated compound is preferably the main component in the ethylenically unsaturated compound contained in the first transparent layer.

Specifically, in a case where the first transparent layer includes di- or higher functional ethylenically unsaturated compound, the content of the di- or higher functional ethylenically unsaturated compound is preferably 40% by mass to 100% by mass, more preferably 50% by mass to 100% by mass, and particularly preferably 60% by mass to 100% by mass with respect to a total content of the ethylenically unsaturated compound included in the first transparent layer.

In a case where the first transparent layer includes the ethylenically unsaturated compound including an acid group (preferably, di- or higher functional ethylenically unsaturated compound including a carboxy group or a carboxylic acid anhydride thereof), the content of the ethylenically unsaturated compound including the acid group is preferably 1% by mass to 50% by mass, more preferably 1% by mass to 20% by mass, and even more preferably 1% by mass to 10% by mass, with respect to a total mass of the first transparent layer.

<<Polymerization Initiator>

The first transparent layer in the second embodiment contains a polymerization initiator.

The polymerization initiator is not particularly limited and a well-known polymerization initiator can be used.

As the polymerization initiator used in the first transparent layer in the second embodiment, the same polymerization initiator as the polymerization initiator used in the first transparent layer in the first embodiment can be used, and the same also applies to the preferred embodiment.

The photopolymerization initiator may be used alone or in combination of two or more thereof.

A content of the photopolymerization initiator is not particularly limited and is preferably 0.1% by mass or more, more preferably 0.2% by mass or more, and even more preferably 0.3% by mass or more with respect to the total mass of the first transparent layer.

In addition, the content of the photopolymerization initiator is preferably equal to or smaller than 10% by mass and more preferably equal to or smaller than 5% by mass, with respect to a total mass of the first transparent layer.

<<Resin>>

The first transparent layer in the second embodiment contains a resin.

The resin is preferably a binder polymer.

The resin is preferably an alkali soluble resin.

As the resin used in the first transparent layer in the second embodiment, the same resin as the resin used in the first transparent layer in the first embodiment can be used, and the same also applies to the preferred embodiment.

The resin may be used alone or in combination of two or more kinds thereof.

A content of the resin is preferably 10% by mass to 90% by mass, more preferably 20% by mass to 80% by mass, and even more preferably 30% by mass to 70% by mass, with respect to the total mass of the first transparent layer, from viewpoints of hardness of the cured film to be obtained and handleability of the transfer film.

<Thermal Crosslinking Compound>

The first transparent layer preferably contains a thermal crosslinking compound and more preferably contains a blocked isocyanate compound, from a viewpoint of hardness after curing.

The thermal crosslinking compound means a “compound having one or more functional groups (thermal crosslinking group) capable of causing a crosslinking reaction by heating” in one molecule.

As the thermal crosslinking compound used in the first transparent layer in the second embodiment, the same thermal crosslinking compound as the thermal crosslinking compound used in the first transparent layer in the first embodiment can be used, and the same also applies to the preferred embodiment.

In the disclosure, the thermal crosslinking compound may be used alone or in combination of two or more kinds thereof.

A content of the thermal crosslinking compound is preferably 1% by mass to 50% by mass and more preferably 5% by mass to 30% by mass, with respect to the total mass of the first transparent layer, from a viewpoint of the hardness of the obtained cured film.

<<Heterocyclic Compound>>

The first transparent layer of the second embodiment preferably further includes a heterocyclic compound, from viewpoints of discoloration prevention properties of the metal wiring in contact and linearity of an obtained pattern.

As the heterocyclic compound used in the first transparent layer in the second embodiment, the same heterocyclic compound as the heterocyclic compound used in the first transparent layer in the first embodiment can be used, and the same also applies to the preferred embodiment.

The first transparent layer may contain one kind or two or more kinds of the heterocyclic compound described above.

The content of the heterocyclic compound is not particularly limited, but from a viewpoint of the discoloration prevention properties metal wiring in contact and the linearity of the obtained pattern, is preferably 0.01% by mass to 20% by mass, more preferably 0.1% by mass to 10% by mass, even more preferably 0.5% by mass to 8% by mass, particularly preferably 1% by mass to 5% by mass, with respect to the total mass of the first transparent layer. In a case where the content thereof is in the above range, the obtained cured product is excellent in hardness and corrosion resistance to metal wiring, and the obtained cured product is excellent in transparency.

<<Thiol Compound>>

The first transparent layer in the second embodiment preferably further contains a thiol compound.

As the thiol compound, a monofunctional thiol compound or a polyfunctional thiol compound is preferably used. Among them, from a viewpoint of hardness after curing, the thiol compound preferably contains a di- or higher functional thiol compound (polyfunctional thiol compound) and is more preferably a polyfunctional thiol compound.

As the thiol compound used in the first transparent layer in the second embodiment, the same thiol compound as the thiol compound used in the first transparent layer in the first embodiment can be used, and the same also applies to the preferred embodiment.

The thiol compounds may be used alone or in combination of two or more thereof.

The content of the thiol compound is preferably 0.1% by mass to 40% by mass, more preferably 0.5% by mass to 30% by mass, and particularly preferably 1% by mass to 25% by mass, with respect to the total mass of the first transparent layer.

<<Surfactant>>

The first transparent layer in the second embodiment contains a surfactant.

As the surfactant, for example, surfactants disclosed in paragraph 0017 of JP4502784B and paragraphs 0060 to 0071 of JP2009-237362A, well-known fluorine-based surfactants, and the like can be used.

As the surfactant, a fluorine-based surfactant is preferable.

As a commercially available fluorine-based surfactant, MEGAFACE (registered trademark) F551 (manufactured by DIC Corporation) is used.

In a case where the first transparent layer includes a surfactant, a content of the surfactant is preferably 0.01% by mass to 3% by mass, more preferably 0.05% by mass to 1% by mass, and even more preferably 0.1% by mass to 0.8% by mass, with respect to the total mass of the first transparent layer.

<<Polymerization Inhibitor>>

The first transparent layer in the second embodiment contains a polymerization inhibitor.

As the polymerization inhibitor, for example, a thermal polymerization inhibitor (also referred to as a polymerization inhibitor) disclosed in paragraph 0018 of JP4502784B can be used.

Among them, phenothiazine, phenoxazine, or 4-methoxyphenol can be preferably used.

In a case where the first transparent layer includes a polymerization inhibitor, a content of the polymerization inhibitor is preferably 0.01% by mass to 3% by mass, more preferably 0.01% by mass to 1% by mass, and even more preferably 0.01% by mass to 0.8% by mass, with respect to the total mass of the first transparent layer.

<<Hydrogen Donating Compound>>

The first transparent layer in the second embodiment preferably further contains a hydrogen donating compound.

In the disclosure, the hydrogen donating compound has an action of further improving sensitivity of the photopolymerization initiator to active light, or suppressing inhibition of polymerization of the polymerizable compound by oxygen.

Examples of such a hydrogen donating compound include amines, for example, M. R. Sander et al., “Journal of Polymer Society,” Vol. 10, page 3173 (1972), JP1969-020189B (JP-S-44-020189B), JP1976-082102A (JP-S-51-082102A), JP1977-134692A (JP-S-52-134692A), JP1984-138205A (JP-S-59-138205A), JP1985-084305A (JP-S-60-084305A), JP1987-018537A (JP-S-62-018537), JP1989-033104A (JP-S-64-033104A), and Research Disclosure 33825, and specific examples thereof include triethanolamine, p-dimethylaminobenzoic acid ethyl ester, p-formyldimethylaniline, and p-methylthiodimethylaniline.

In addition, other examples of the hydrogen donating compound further include an amino acid compound (for example, N-phenylglycine or the like), an organic metal compound disclosed in JP1973-042965B (JP-S48-042965B) (for example, tributyltin acetate, or the like), a hydrogen donor disclosed in JP1980-034414B (JP-S55-034414B), and a sulfur compound disclosed in JP1994-308727A (JP-H6-308727A) (for example, trithiane or the like).

A content of the hydrogen donating compounds is preferably in a range of 0.1% by mass to 30% by mass, more preferably in a range of 1% by mass to 25% by mass, and even more preferably in a range of 0.5% by mass to 20% by mass, with respect to the total mass of the first transparent layer, from a viewpoint of improving a curing speed with balance between a polymerization growth speed and chain transfer.

<<Other Components>>

The first transparent layer of second embodiment may include a component other than the components described above.

Examples of the other components include a thermal polymerization inhibitor disclosed in paragraph 0018 of JP4502784B, and other additives disclosed in paragraphs 0058 to 0071 of JP2000-310706A.

In addition, the impurities and the preferable content thereof in the first transparent layer in the second embodiment are the same as those in the first transparent layer in the first embodiment described above.

In addition, the first transparent layer may include a small amount of colorant (pigment, dye, and the like) as the other component, but it is preferable that a colorant is not substantially included, from a viewpoint of transparency.

Specifically, a content of the colorant in the first transparent layer is preferably smaller than 1% by mass and more preferably smaller than 0.1% by mass with respect to a total mass of the first transparent layer.

A thickness of the first transparent layer is preferably 20 μm or less, more preferably 15 μm or less, and particularly preferably 12 μm or less.

It is advantageous in a case where the thickness of the first transparent layer is 20 μm or less, from viewpoints of reducing a thickness of the entire transfer film, improving transmittance of the first transparent layer or the cured film to be obtained, and suppressing yellowing of the first transparent layer or the cured film to be obtained.

From a viewpoint of manufacturing suitability, the thickness of the first transparent layer is preferably 0.5 μm or more, more preferably 1 μm or more, and particularly preferably 2 μm or more.

In the second embodiment, the refractive index of the first transparent layer, in a case where the first transparent layer contains the specific particle, is preferably 1.50 to 2.10, more preferably 1.60 to 1.90, even more preferably 1.63 to 1.80, and particularly preferably 1.65 to 1.78, from a viewpoint of concealing properties of the transparent electrode pattern.

In the second embodiment, the refractive index of the first transparent layer, in a case where the first transparent layer does not contain the specific particle, is not particularly limited, and is preferably 1.47 to 1.56, more preferably 1.48 to 1.55 even more preferably 1.49 to 1.54, and particularly preferably 1.50 to 1.53, from a viewpoint of concealing properties of the transparent electrode pattern.

In the disclosure, the “refractive index” indicates a refractive index at a wavelength of 550 nm.

The “refractive index” in the disclosure means a value measured with visible light at a wavelength of 550 nm at a temperature of 23° C. by ellipsometry, unless otherwise noted.

A method for forming the first transparent layer is not particularly limited, and a well-known method can be used.

As an example of the method for forming the first transparent layer, a method forming the photosensitive layer by applying a photosensitive resin composition containing a solvent onto a temporary support and then drying, as necessary is used.

As the coating method, a well-known method can be used, and examples thereof include a printing method, a spraying method, a roll coating method, a bar coating method, a curtain coating method, a spin coating method, and a die coating method (that is, slit coating method), and a die coating method is preferable.

As the drying method, a well-known method such as natural drying, heating drying, and drying under reduced pressure can be applied alone or in combination of plural thereof.

—Solvent—

The photosensitive resin composition preferably further includes a solvent, from a viewpoint of forming a layer by applying.

As the solvent, a solvent normally used can be used without particular limitations.

The solvent is preferably an organic solvent.

Examples of the organic solvent include methyl ethyl ketone, propylene glycol monomethyl ether, propylene glycol monomethyl ether acetate (another name: 1-methoxy-2-propyl acetate), diethylene glycol ethyl methyl ether, cyclohexanone, methyl isobutyl ketone, ethyl lactate, methyl lactate, caprolactam, n-propanol, and 2-propanol. In addition, the solvent used may include a mixed solvent which is a mixture of these compounds.

As the solvent, a mixed solvent of methyl ethyl ketone and propylene glycol monomethyl ether acetate, or a mixed solvent of diethylene glycol ethyl methyl ether and propylene glycol monomethyl ether acetate is preferably used.

In a case of using the solvent, a content of solid contents of the photosensitive resin composition is preferably 5% by mass to 80% by mass, more preferably 5% by mass to 40% by mass, and particularly preferably 5% by mass to 30% by mass with respect to a total amount of the photosensitive resin composition.

In a case of using the solvent, a viscosity (25° C.) of the photosensitive resin composition is preferably 1 mPa s to 50 mPa-s, more preferably 2 mPa s to 40 mPa-s, and particularly preferably 3 mPa-s to 30 mPa s, from a viewpoint of coating properties.

The viscosity is, for example, measured using VISCOMETER TV-22 (manufactured by Toki Sangyo Co. Ltd.).

In a case where the photosensitive resin composition includes the solvent, a surface tension (25° C.) of the photosensitive resin composition is preferably 5 mN/m to 100 mN/m, more preferably 10 mN/m to 80 mN/m, and particularly preferably 15 mN/m to 40 mN/m, from a viewpoint of coating properties.

The surface tension is, for example, measured using Automatic Surface Tensiometer CBVP-Z (manufactured by Kyowa Interface Science Co., Ltd.).

As the solvent, a solvent disclosed in paragraphs 0054 and 0055 of US2005/282073A can also be used, and the content of this specification is incorporated in the present specification.

In addition, as the solvent, an organic solvent (high-boiling-point solvent) having a boiling point of 180° C. to 250° C. can also be used, as necessary.

In a case where the first transparent layer is formed of the photosensitive resin composition containing a solvent, it is not necessary that the solvent in the first transparent layer is completely removed, and a content of the solvent in the first transparent layer is preferably 1% by mass or less and more preferably 0.5% by mass or less, with respect to the total mass of the first transparent layer.

<Second Transparent Layer>

In the transfer film of the second embodiment according to the present disclosure includes the second transparent layer and the second transparent layer contains a metal oxide particle containing titanium oxide and tin oxide.

In addition, it is preferable that the second transparent layer contains metal oxide particle (specific particle) containing titanium oxide and tin oxide, that is, satisfies the above section (2) (the second embodiment), from a viewpoint of adhesiveness and haze.

Further, the refractive index of the second transparent layer is preferably greater than the refractive index of the first transparent layer, from a viewpoint of concealing properties of the transparent electrode pattern, adhesiveness, and haze.

The refractive index of the second transparent layer is preferably 1.50 to 2.10, more preferably 1.60 to 1.90, even more preferably 1.63 to 1.80, and particularly preferably 1.65 to 1.78, from a viewpoint of concealing properties of the transparent electrode pattern.

The second transparent layer may have photocuring properties (that is, photosensitivity), may have thermosetting properties, or may have both photocuring properties and thermosetting properties.

From a viewpoint of forming the cured film having excellent hardness by the photocuring after the transfer, the second transparent layer preferably has photocuring properties.

From viewpoints of further improving hardness of the cured film by the heat curing, the second transparent layer preferably has thermosetting properties.

The second transparent layer preferably has thermosetting properties and photocuring properties.

The second transparent layer preferably has alkali solubility (for example, solubility with respect to weak alkali aqueous solution).

The embodiment in which the second transparent layer has photosensitivity, has an advantage, from a viewpoint of collectively patterning the first transparent layer and the second transparent layer transferred onto the substrate by photolithography at one time, after the transferring.

<<Metal Oxide Particle Containing Titanium Oxide and Tin Oxide>>

In the second embodiment of the transfer film according to the present disclosure, the second transparent layer may further contain a metal oxide particle containing titanium oxide and tin oxide.

The specific particle is a metal oxide particle containing titanium oxide and tin oxide, that is, a titanium oxide-tin oxide composite particle.

The titanium oxide in the specific particle is preferably a titanium dioxide, from a viewpoint of haze.

A crystal structure of the titanium oxide (titanium dioxide) in the specific particle may be any of a anatase type (tetragonal crystal), a rutile type (tetragonal crystal), and a brookite type (orthorhombic crystal).

Among those, from viewpoints of the refractive index, adhesiveness, haze, and light resistance of a film to be obtained, the specific particle preferably contains a rutile type titanium oxide and more preferably a rutile type titanium oxide.

In addition, the tin oxide in the specific particle is preferably a tin dioxide, from a viewpoint of haze.

The specific particle preferably contains a metal oxide other than titanium oxide and tin oxide, from viewpoints of adhesiveness and haze.

Examples of metal oxide other than the titanium oxide and the tin oxide include oxides containing atoms such as Be, Mg, Ca, Sr, Ba, Sc, Y, La, Ce, Gd, Tb, Dy, Yb, Lu, Zr, Hf, Nb, Mo, W, Zn, B, Al, Si, Ge, Pb, Sb, Bi and Te.

The metal of the metal oxide particle of the present disclosure also includes semimetal such as B, Si, Ge, As, Sb, or Te.

Among them, as the metal oxide other than the titanium oxide and the tin oxide, at least one kind of metal oxide selected from the group consisting of silicon dioxide, aluminum oxide, and zirconium oxide is preferable, and a silicon dioxide is more preferable, from viewpoints of adhesiveness, haze, and light resistance.

The metal oxide other than the titanium oxide and the tin oxide may be contained alone or in combination of two or more kinds thereof.

In addition, the specific particle may be a particle which is subjected to surface treatment such as a hydrophilization treatment and a hydrophobic treatment.

The surface treatment method is not particularly limited, and a well-known method can be used.

A content of titanium oxide in the specific particle is preferably 30% by mass or more, more preferably 50% by mass to 99% by mass, even more preferably 70% by mass to 95% by mass, and particularly preferably 70% by mass to 90% by mass, with respect to a total mass of the specific particle, from viewpoints of refractive index, adhesiveness, and haze of the film to be obtained.

A content of tin oxide in the specific particle is preferably 0.1% by mass to 500% by mass, more preferably 1% by mass to 30% by mass, and even more preferably 5% by mass to 20% by mass, with respect to a total mass of the specific particle, from viewpoints of refractive index, adhesiveness, and haze of the film to be obtained.

In a case where the specific particle contains the metal oxides other than the titanium oxide and the tin oxide, a content of the metal oxide other than the titanium oxide and the tin oxide with respect to the content of titanium oxide in the specific particle is preferably 0.1% by mass to 60% by mass, more preferably 0.5% by mass to 50% by mass, even more preferably 1% by mass to 30% by mass, and particularly preferably 5% by mass to 20% by mass, with respect to the total mass of the specific particle, from viewpoints of refractive index, adhesiveness, haze, and light resistance of the film to be obtained.

A shape of the specific particle is not particularly limited, and examples thereof include a spherical shape, a spindle shape, a prismatic shape, a columnar shape, a flat plate shape, and an indefinite shape.

An average primary particle diameter of the specific particle is preferably 100 nm or less, more preferably 20 nm or less, even more preferably 10 nm or less, and particularly preferably 1 nm to 10 nm, from viewpoints of adhesiveness and haze.

The average primary particle diameter of the specific particle in the present disclosure refers to an arithmetic mean obtained by measuring particle diameters of 200 random particles with a transmission electron microscope. In addition, a case where the shape of the particle is not a spherical shape, the longest side is set as the diameter.

The transfer film in the second embodiment may contain one kind of specific particle alone, or may contain two or more kinds of specific particle.

A content of the specific particle contained in the second transparent layer in the second embodiment is preferably 20% by mass to 95% by mass, more preferably 30% by mass to 90% by mass, even more preferably 35% by mass to 85% by mass, particularly preferably 45% by mass to 75% by mass, and most preferably 55% by mass to 75% by mass, with respect to a total mass of the second transparent layer, from viewpoints of refractive index, concealing properties of the transparent electrode pattern, adhesiveness, and haze of the film to be obtained.

A thickness of the second transparent layer is preferably equal to or smaller than 50) nm, more preferably equal to or smaller than 150 nm, and particularly preferably equal to or smaller than 90 nm.

In addition, the thickness of the second transparent layer is preferably equal to or greater than 20 nm, more preferably equal to or greater than 30 nm, even more preferably equal to or greater than 40 nm, and particularly preferably equal to or greater than 50 nm.

The thickness of the second transparent layer is most preferably 50 nm to 90 nm.

The refractive index of the second transparent layer is preferably adjusted in accordance with the refractive index of the transparent electrode pattern.

For example, in a case where the refractive index of the transparent electrode pattern is 1.8 to 2.0, as in a case of the transparent electrode pattern consisting of indium tin oxide (ITO), the refractive index of the second transparent layer is preferably equal to or greater than 1.60 and more preferably equal to or greater than 1.65. An upper limit of the refractive index of the second transparent layer in this case is not particularly limited, and is preferably equal to or smaller than 2.1, more preferably equal to or smaller than 1.85, even more preferably equal to or smaller than 1.78, and particularly preferably equal to or smaller than 1.74.

In addition, in a case where the refractive index of the transparent electrode pattern is greater than 2.0, as in a case of the transparent electrode pattern consisting of indium zinc oxide (IZO), for example, the refractive index of the second transparent layer is preferably 1.65 to 1.95 and more preferably 1.70 to 1.85.

A method for controlling the refractive index of the second transparent layer is not particularly limited, and examples thereof include a method using a resin having a predetermined refractive index alone, a method using a resin and specific particles, and a method using a composite of metal salt and a resin, and the method using the resin and the specific particles is preferable.

In addition, the second transparent layer in the second embodiment preferably contains a resin and a polymerizable compound, and preferably contains a resin, a polymerizable compound, and the specific particle.

The preferred embodiment of the resin and the polymerizable compound of the second transparent layer in the second embodiment is the same as the preferred embodiment of the resin and the polymerizable compound of the first transparent layer in the second embodiment.

A content of the resin of the second transparent layer is preferably 10% by mass to 90% by mass, more preferably 10% by mass to 80% by mass, and even more preferably 10% by mass to 70% by mass, with respect to the total mass of the second transparent layer, from viewpoints of hardness of the cured film to be obtained and handleability of the transfer film.

As the polymerizable compound of the second transparent layer, it is preferable to use an ethylenically unsaturated compound.

The content of the ethylenically unsaturated compound in the second transparent layer is preferably 0.1% by mass to 30% by mass, more preferably 0.5% by mass to 20% by mass, even more preferably 0.5% by mass to 10% by mass, and particularly preferably 0.5% by mass to 5% by mass, with respect to a total mass of the second transparent laver.

In addition, it is preferable that the second transparent layer contains a tri- or higher functional ethylenically unsaturated compound. Further, it is preferable that the second transparent layer contains an ethylenically unsaturated compound containing an acid group.

The preferred embodiment of the specific particle contained in the second transparent layer in the second embodiment is the same as the content described in the preferred embodiment of the specific particle described above.

In addition, the preferable content of the specific particle contained in the second transparent layer in the second embodiment is as described above.

In addition, the second transparent layer in the second embodiment preferably contains at least one kind of a heterocyclic compound.

In a case where the second transparent layer includes a heterocyclic compound, surface treatment can be performed with respect to a member (for example, conductive member formed on a substrate) in a direct contact with the second transparent layer, in a case of transferring the second transparent layer onto the substrate (that is, a target to be transferred). This surface treatment applies a metal oxide inhibiting function (protection properties) with respect to the member in a direct contact with the second transparent layer.

Examples of the heterocyclic compound include those described above.

From a viewpoint of dispersion stability of the metal oxide particle, the second transparent layer in the second embodiment preferably further contains a silane coupling agent or a titanium coupling agent. In addition, the second transparent layer may contain both the silane coupling agent and the titanium coupling agent.

As the silane coupling agent and the titanium coupling agent used in the second transparent layer in the second embodiment, the same silane coupling agent and the titanium coupling agent as the silane coupling agent and the titanium coupling agent used in the first transparent layer in the first embodiment can be used, and the same also applies to the preferred embodiment.

The second transparent layer of second embodiment may include a component other than the components described above.

As other components contained in the second transparent layer in the second embodiment, the same components as each component contained in the first transparent layer in the second embodiment are used.

The second transparent layer preferably includes a surfactant as the other component.

In addition, the impurities and the preferable content thereof in the second transparent layer in the second embodiment are the same as those in the first transparent layer in the first embodiment described above.

A forming method of the second transparent layer is not particularly limited.

As an example of the forming method of the second transparent layer, a method of forming the layer by applying and, as necessary, drying a composition for forming a second transparent layer of the embodiment including an aqueous solvent, on the first transparent layer formed on the temporary support is used.

Specific examples of the coating and drying method are respectively the same as the specific examples of the coating and drying in a case of forming the first transparent layer.

The composition for forming the second transparent layer can include each component of the second transparent layer described above.

The composition for forming the second transparent layer, for example, preferably includes a binder polymer, an ethylenically unsaturated compound, particles, and an aqueous solvent.

In addition, as the composition for forming the second transparent layer, a composition including ammonium salt disclosed in paragraphs 0034 to 0056 of WO2016/009980 is also preferable.

<Third Transparent Layer>

The transfer film of the second embodiment according to the present disclosure preferably includes a third transparent layer, and more preferably has a third transparent layer on the second transparent layer.

The third transparent layer in the second embodiment is preferably a layer not containing specific particle.

The third transparent layer in the second embodiment preferably contains a resin and a polymerizable compound.

In addition, a preferred embodiment of the resin and the polymerizable compound in the third transparent layer, and the preferred content are the same as the preferred embodiment of the resin and the polymerizable compound in the first transparent layer or the second transparent layer and the preferred content.

The third transparent layer of second embodiment may include a component other than the components described above.

As other components contained in the third transparent layer, the same components as each component contained in the first transparent laver or the second transparent layer other than the specific particle are used.

A forming method of the third transparent layer is not particularly limited. As an example of the forming method of the third transparent layer, a method of forming the layer by applying and, as necessary, drying a composition for forming a third transparent layer of the embodiment including an aqueous or organic solvent, on the second transparent layer is used. In addition, as another forming method, a method of forming a layer by extracting components of the first transparent layer and unevenly distributing those on the second transparent layer, in a case of applying and drying the composition for forming the second transparent layer containing an aqueous solvent on the first transparent layer formed on the temporary support is used. Further, as another forming method, there is a method of forming by phase separation of the composition for forming the second transparent layer, in a case of applying and drying the composition for forming the second transparent layer.

From a viewpoint of adhesiveness and haze, it is preferable that the specific particle is not included or the content of the specific particle in the third transparent layer is 5% by mass or less with respect to the total mass of the third transparent layer, it is more preferable that the specific particle is not included or the content thereof is 1.0% by mass or less with respect to the total mass of the third transparent layer, it is even more preferable that the specific particle is not included or the content thereof is 0.5% by mass or less with respect to the total mass of the third transparent layer, and it is particularly preferable that the specific particle is not included.

The thickness of the third transparent layer is preferably 0.5 nm to 30 nm and more preferably 1 nm to 15 nm, from a viewpoint of adhesiveness and haze.

### Specific Examples of Transfer Film

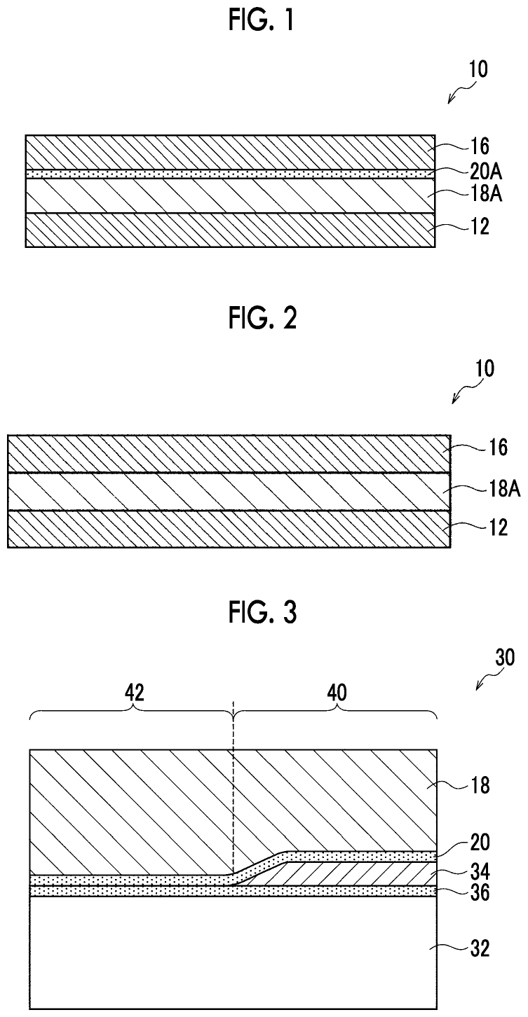

FIG. 1 is a schematic cross sectional view of a transfer film 10 which is a specific example of the transfer film according to the disclosure.

As shown in FIG. 1, the transfer film 10 has a laminated structure of “protective film 16/second transparent layer 20A/first transparent layer 18A/temporary support 12” (that is, laminated structure in which a temporary support 12, a first transparent layer 18A, a second transparent layer 20A, and a protective film 16 are arranged in this order).

However, the transfer film according to the disclosure is not limited to the transfer film 10, and the second transparent layer 20A and the protective film 16 may be omitted, for example. In addition, at least one of the thermoplastic resin layer or the interlayer described above may be comprised between the temporary support 12 and the first transparent layer 18A.

The second transparent layer 20A is a layer arranged on a side opposite to the side where the temporary support 12 exists as seen from the first transparent layer 18A.

The transfer film 10 is a negative type material (negative type film).

In addition, a case where the specific particle is contained at least in the second transparent layer 20A indicates an example of the second embodiment in the transfer film according to the present disclosure.

A manufacturing method of the transfer film according to the disclosure is not particularly limited.

In the case of producing the transfer film 10 shown in FIG. 1, the method for producing a transfer film according to the present disclosure preferably includes, for example, a step of forming first transparent layer 18A on the temporary support 12, a step of forming the second transparent layer 20A on the first transparent layer 18A, and a step of forming the protective film 16 on the second transparent layer 20A in this order.

The manufacturing method of the transfer film 10 may include a step of volatilizing ammonia disclosed in a paragraph 0056 of WO2016/009980A, between the step of forming the second transparent layer 20A and the step of forming the protective film 16.

FIG. 2 is a schematic cross sectional view of a transfer film 10 which is another specific example of the transfer film according to the disclosure.

As shown in FIG. 2, the transfer film 10 has a laminated structure of “protective film 16/first transparent layer 18A/temporary support 12” (that is, laminated structure in which a temporary support 12, a first transparent layer 18A, and a protective film 16 are arranged in this order).

In addition, the first transparent layer 18A in FIG. 2 contains the specific particle, and the transfer film 10 shown in FIG. 2 represents an example of the transfer film of the first embodiment according to the present disclosure.

(Cured Film and Manufacturing Method Thereof)

In a case of using the transfer film of the first embodiment as the transfer film according to the present disclosure, the cured film according to the present disclosure is a cured film obtained by at least transferring and curing the first transparent layer of the transfer film according to the present disclosure.

In a case of using the transfer film of the second embodiment as the transfer film according to the present disclosure, the cured film according to the present disclosure is a cured film obtained by at least transferring and curing the first transparent layer and the second transparent layer of the transfer film according to the present disclosure.

In addition, the cured film may have a desired pattern shape.

A transfer target to which at least the first transparent layer of the transfer film according to the present disclosure is transferred is not particularly limited, and a support, a substrate which will be described later, and the like are suitably used.

The cured film according to the disclosure can be suitably used as an interlayer insulating film (insulating film) or an overcoat film (protective film), and is more suitably used as a protective film for a touch panel.

The cured film according to the disclosure has excellent film physical properties, and thus is useful for usage in an organic EL display device or a liquid crystal display device.

Among these, the cured film according to the disclosure can be suitably used as a protective film for a touch panel and can be more suitably used as a protective film for touch panel wiring.

A thickness of the cured film is not particularly limited and is preferably 1 μm to 20 μm, more preferably 2 μm to 15 μm, and particularly preferably 3 μm to 12 μm.

The method for producing the cured film according to the present disclosure may be any method using the transfer film according to the present disclosure.

In a case of using the transfer film according to the first embodiment, the method for producing a cured film according to the present disclosure is preferably a method including a step of at least transferring the first transparent layer of the transfer film onto a support, and a step of curing at least a part of the first transparent layer to form a cured film, and is more preferably a method including a step of at least transferring the first transparent layer, and a step of curing at least the transferred first transparent layer to form a cured layer.

In a case of using the transfer film according to the second embodiment, the method for producing a cured film according to the present disclosure is preferably a method including at least transferring the first transparent layer and the second transparent layer of the transfer film onto a support, and curing at least a part of the first transparent layer to form a cured film.

In a case where the second transparent layer of the transfer film of the second embodiment is a layer including a polymerizable compound and a polymerization initiator, the method for producing a cured film according to the present disclosure is preferably a method including at least transferring the first transparent layer and the second transparent layer of the transfer film onto a support, and curing at least a part of the first transparent layer and curing at least a part of the second transparent layer to form a cured film.

The transfer in the method for producing a cured film according to the present disclosure can be performed by using a well-known transfer method and laminating method. In addition, for details of the preferable transfer method, a preferred embodiment in the photosensitive layer forming step of the manufacturing method of a touch panel which will be described later can be referred to.

In a case where the transfer film according to the present disclosure includes only a first transparent layer and a second transparent layer, for example, a method of laminating the transfer film according to the present disclosure on a support, and bringing the second transparent layer side of the transfer film according to the disclosure into contact with the support to transfer is used.

In a case where the transfer film according to the present disclosure includes a first transparent layer, a second transparent layer, and a third transparent layer as a photosensitive layer, a method of bringing the third transparent layer side of the transfer film according to the present disclosure into contact with the support to transfer is used.

The support in the method for producing a cured film according to the present disclosure is not particularly limited and may be suitably selected as desired.

Examples of the support include a resin film and a substrate.

Examples of the resin film include the resin film of the temporary support described above.

Examples of the substrate include a well-known substrate such as a resin substrate, a glass substrate, a metal substrate, and a silicon substrate, and a well-known structure such as an electrode may be further provided on a surface of a substrate and inside the substrate.

As the substrate, a substrate of a laminated which will be described later is preferably used.

The curing in the method for producing a cured film according to the present disclosure is preferably curing by light or heat depending on the composition of each layer in the transfer film according to the present disclosure used.

Among these, the curing by exposure is preferable, and curing by patternwise exposure is more preferable, from a viewpoint of forming a pattern in a desired shape.

The curing method by light or heat is not particularly limited, and the curing can be performed by a well-known method. In addition, for the preferred pattern expose method, a preferred embodiment in the patternwise exposure step of the manufacturing method of a touch panel which will be described later can be referred to.

In addition, the method for manufacturing the cured film of the disclosure may include a step other than the steps described above.

The other steps are not particularly limited and may include well-known steps, as desired.

(Laminate and Capacitive Input Device)

The laminate according to the disclosure described below may include the cured film according to the disclosure, but is preferably a laminate obtained by laminating a substrate, an electrode, and the cured film according to the disclosure in this order.

In addition, the cured film of the laminate according to the disclosure may have a desired pattern shape.

In addition, the cured film of the laminate according to the present disclosure is preferably a cured film obtained by transferring the first transparent layer and curing at least a part thereof. Further, in the second embodiment, a cured film obtained by transferring the first transparent layer and the second transparent layer and curing at least a part thereof is preferable, and a cured film obtained by transferring the first transparent layer, the second transparent layer, and the third transparent layer, and curing at least a part thereof is more preferable.

The capacitive input device according to the disclosure includes the cured film according to the disclosure or the laminate according to the disclosure.

The substrate is preferably a substrate including an electrode of the capacitive input device.

In addition, the electrode is preferably an electrode of an electrode of the capacitive input device.

The electrode of the capacitive input device may be a transparent electrode pattern or a leading wiring. In the laminate, the electrode of the capacitive input device is preferably an electrode pattern and more preferably a transparent electrode pattern.

It is preferable that the laminate according to the disclosure includes a substrate, a transparent electrode pattern, a second transparent layer disposed to be adjacent to the transparent electrode pattern, and a first transparent layer disposed to be adjacent to the second transparent layer, and a refractive index of the second transparent layer is higher than a refractive index of the first transparent layer. The refractive index of the second transparent laver is preferably equal to or greater than 1.6.

With the configuration of the laminated described above, the concealing properties of the transparent electrode pattern is improved.

As the substrate, a glass substrate or a resin substrate is preferable.

In addition, the substrate is preferably a transparent substrate and more preferably a transparent resin substrate. The transparency in the disclosure means that the transmittance of all visible light is 85% or more, preferably 90% or more, and more preferably 95% or more.

A refractive index of the substrate is preferably 1.50 to 1.52.

As the glass substrate, tempered glass such as GORILLA GLASS (registered trademark) manufactured by Corning Incorporated can be used.

As the resin substrate, at least one of a component with no optical strains or a component having high transparency is preferably used, and a substrate formed of a resin such as polyethylene terephthalate (PET), polyethylene naphthalate (PEN), polycarbonate (PC), triacetyl cellulose (TAC), polyimide (PI), polybenzoxazole (PBO), or cycloolefin polymer (COP) is used, for example.

As a material of the transparent substrate, a material disclosed in JP2010-086684A, JP2010-152809A, and JP2010-257492A is preferably used.

As the capacitive input device, a touch panel is suitably used.

As the electrode for a touch panel, a transparent electrode pattern disposed at least in an image display region of the touch panel is used. The electrode for a touch panel may extend from the image display region to a frame portion of the touch panel.

As the wiring for a touch panel, the leading wiring (lead-out wiring) disposed on the frame portion of the touch panel is used, for example.

As a preferred embodiment of the substrate for a touch panel and the touch panel, an embodiment in which the transparent electrode pattern and the leading wiring are electrically connected to each other by laminating a part of the leading wiring on a portion of the transparent electrode pattern extending to the frame portion of the touch panel, is suitable.

As a material of the transparent electrode pattern, a film of metal oxide such as indium tin oxide (ITO) and indium zinc oxide (IZO) is preferable.

As a material of the leading wiring, metal is preferable. Examples of the metal which is the material of the leading wiring include gold, silver, copper, molybdenum, aluminum, titanium, chromium, zinc, and manganese, and alloy formed of two or more kinds of these metal elements. As the material of the leading wiring, copper, molybdenum, aluminum, or titanium is preferable, copper is particularly preferable.

The electrode protective film for a touch panel according to the disclosure is provided so as to cover the electrode and the like directly or through other layers, in order to protect the electrode and the like (that is, at least one of the electrode for a touch panel or the wiring for a touch panel).

The preferred range of a thickness of the electrode protective film for a touch panel is the same as the preferred range of a thickness of the first transparent layer described above.

The electrode protective film according to the disclosure, preferably the electrode protective film for a touch panel may include an opening.

The opening can be formed by dissolving an unexposed portion of the first transparent layer with a developer.

In this case, in a case where the electrode protective film for a touch panel is formed under the laminating condition at a high temperature using the transfer film, the development residue of the opening of the electrode protective film for a touch panel is suppressed.

The touch panel may further comprise a first refractive index adjusting layer between the electrode and the like and the electrode protective layer for a touch panel (for example, see first specific example of the touch panel which will be described later).

The preferred embodiment of the first refractive index adjusting layer is the same as the preferred embodiment of the second transparent layer comprised in the transfer film in the second embodiment. The first refractive index adjusting layer may be formed by applying and drying a composition for forming the first refractive index adjusting layer, or may be formed by transferring the refractive index adjusting layer of the transfer film comprising the refractive index adjusting layer.

The touch panel of the embodiment comprising the first refractive index adjusting layer is preferably formed by transferring the first transparent layer and the second transparent layer of the transfer film by using the transfer film according to the second embodiment. In this case, the electrode protective layer for a touch panel is formed of the first transparent layer of the transfer film, and the first refractive index adjusting layer is formed of the second transparent layer of the transfer film.

In addition, the touch panel or the substrate for a touch panel may comprise a second refractive index adjusting layer between the substrate and the electrode and the like (for example, see, first specific example of the touch panel which will be described later).

The preferred embodiment of the second refractive index adjusting layer is the same as the preferred embodiment of the second transparent layer comprised in the transfer film.

The embodiment in which the touch panel of the disclosure comprises the first refractive index adjusting layer (more preferably, embodiment of comprising the first refractive index adjusting layer and the second refractive index adjusting layer) has an advantage in which the electrode and the like are hardly recognized (that is, so-called see-through is suppressed).

Regarding the structure of the touch panel, a structure of a capacitive input device disclosed in JP2014-010814A or JP2014-108541A may be referred to.

### First Specific Example of Touch Panel

FIG. 3 is a schematic cross sectional view of a touch panel 30 which is a first specific example of the touch panel according to the disclosure. More specifically, FIG. 3 is a schematic cross sectional view of an image display region of the touch panel 30.

As shown in FIG. 3, the touch panel 30 has a structure in which a substrate 32, a second refractive index adjusting layer 36, a transparent electrode pattern 34 as the electrode for a touch panel, a first refractive index adjusting layer 20, and an electrode protective film 18 for a touch panel are disposed in this order.

In the touch panel 30, the electrode protective film 18 for a touch panel and the first refractive index adjusting layer 20 cover the entire transparent electrode pattern 34. However, the touch panel according to the disclosure is not limited to this embodiment. The electrode protective film 18 for a touch panel and the first refractive index adjusting layer 20 may cover at least a portion of the transparent electrode pattern 34.

In addition, the second refractive index adjusting layer 36 and the first refractive index adjusting layer 20 are preferably respectively continuously coated over a first region 40 in which the transparent electrode pattern 34 is present and a second region 42 in which the transparent electrode pattern 34 is not present directly or through another layer. Accordingly, the transparent electrode pattern 34 is more hardly recognized.

The second refractive index adjusting layer 36 and the first refractive index adjusting layer 20 are preferably coated directly over both of the first region 40 and the second region 42, rather than the coating through the other layer. Examples of the “other layer” include an insulating layer and an electrode pattern other than the transparent electrode pattern 34.

The first refractive index adjusting layer 20 is laminated over both of the first region 40 and the second region 42. The first refractive index adjusting layer 20 is adjacent to the second refractive index adjusting layer 36 and is also adjacent to the transparent electrode pattern 34.

In a case where the shape of the end portion of the transparent electrode pattern 34 at a portion in contact with the second refractive index adjusting layer 36 is a tapered shape as shown in FIG. 3, the first refractive index adjusting layer 20 is preferably laminated along the tapered shape (that is, at the same tilt as the taper angle).

As the transparent electrode pattern 34, the ITO transparent electrode pattern is suitable.

The transparent electrode pattern 34 can be, for example, formed by the following method.

A thin film for an electrode (for example, ITO film) is formed on the substrate 32 on which the second refractive index adjusting layer 36 is formed by sputtering. By applying a photosensitive resist for etching or transferring a photosensitive film for etching onto the thin film for an electrode, an etching protective layer is formed. Then, this etching protective layer is patterned in a desired pattern shape by exposure and development. Next, a portion of the thin film for an electrode which is not covered with the patterned etching protective layer is removed by etching. Accordingly, the thin film for an electrode is set to have a pattern having a desired shape (that is, transparent electrode pattern 34). Then, the patterned etching protective layer is removed by a peeling solution.

The first refractive index adjusting layer 20 and the electrode protective film 18 for a touch panel are, for example, formed on the substrate 32 (that is, substrate for a touch panel) on which the second refractive index adjusting layer 36 and the transparent electrode pattern 34 are provided in order, as described below.

First, the transfer film 10 (that is, transfer film 10 having a laminated structure of “protective film 16/second transparent layer 20A/first transparent layer 18A/temporary support 12”) shown in FIG. 1 is prepared.

Next, the protective film 16 is removed from the transfer film 10.

Then, the transfer film 10, from which the protective film 16 is removed, is laminated on the substrate 32 (that is, substrate for a touch panel) on which the second refractive index adjusting layer 36 and the transparent electrode pattern 34 are provided in order. The laminating is performed in a direction in which the second transparent layer 20A of the transfer film 10, from which the protective film 16 is removed, and the transparent electrode pattern 34 are in contact with each other. By this laminating, a laminate having a laminated structure of “temporary support 12/first transparent layer 18A/second transparent layer 20A/transparent electrode pattern 34/second refractive index adjusting layer 36/substrate 32” is obtained.

Next, the temporary support 12 is removed from the laminate.

Then, by performing the patternwise exposure with respect to the laminate, from which the temporary support 12 is removed, the first transparent layer 18A and the second transparent layer 20A are cured in a pattern shape. The curing of the first transparent layer 18A and the second transparent layer 20A in a pattern shape may be respectively individually performed by individual patternwise exposure, but the curing is preferably performed at the same time by the patternwise exposure at one time.

Next, by removing the unexposed portion (that is, uncured portion) of the first transparent layer 18A and the second transparent layer 20A by the development, the electrode protective film 18 for a touch panel which is a patterned cured product of the first transparent layer 18A (not shown regarding the pattern shape), and the first refractive index adjusting layer 20 which is a patterned cured product of the second transparent layer 20A (not shown regarding the pattern shape) are respectively obtained. The development of the first transparent layer 18A and the second transparent layer 20A after the patternwise exposure may be respectively individually performed by individual development, but the development is preferably performed at the same time by the development at one time.

The preferred embodiments of the laminating, the patternwise exposure, and the development will be described later.

Regarding the structure of the touch panel, a structure of a capacitive input device disclosed in JP2014-010814A or JP2014-108541A may be referred to.

### Second Specific Example of Touch Panel

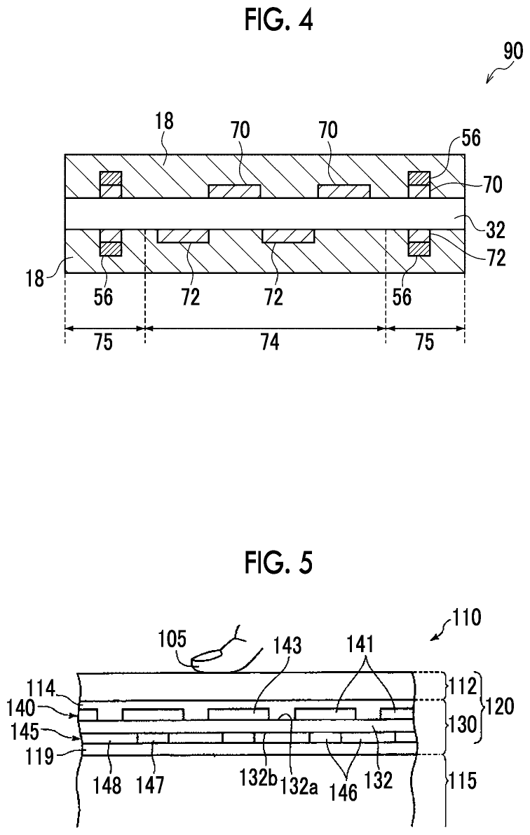

FIG. 4 is a schematic cross sectional view of a touch panel 90 which is a second specific example of the touch panel according to the disclosure.

As shown in FIG. 4, the touch panel 90 includes an image display region 74 and an image non-display region 75 (that is, frame portion).

As shown in FIG. 4, the touch panel 90 comprises the electrode for a touch panel on both surfaces of the substrate 32. Specifically, the touch panel 90 comprises a first transparent electrode pattern 70 on one surface of the substrate 32 and comprises a second transparent electrode pattern 72 on the other surface thereof.

In the touch panel 90, a leading wiring 56 is connected to the first transparent electrode pattern 70 and the second transparent electrode pattern 72, respectively. The leading wiring 56 is, for example, a copper wiring.

In the touch panel 90, the electrode protective film 18 for a touch panel is formed on one surface of the substrate 32 so as to cover the first transparent electrode pattern 70 and the leading wiring 56, and the electrode protective film 18 for a touch panel is formed on the other surface of the substrate 32 so as to cover the second transparent electrode pattern 72 and the leading wiring 56.

The first refractive index adjusting layer and the second refractive index adjusting layer of the first specific example may be provided on the one surface and the other surface of the substrate 32, respectively.

In addition, another example of the touch panel according to the present disclosure is shown in FIG. 5.

FIG. 5 is a cross sectional view showing an example of a cover module used in the disclosure together with a display device. In addition, another example of the touch panel according to the present disclosure shown in FIG. 5 consists of a cover module 120 and a display device 115.

The capacitive cover module 120 shown in FIG. 5 comprises a film sensor 130 and a cover panel 112 in which the film sensor 130 is attached to a rear surface by a protective film 114.

As shown in FIG. 5, the film sensor 130 includes a base film 132, a first electrode portion 140 provided on a surface 132a on one side (observer side) of the base film 132, and a second electrode portion 145 provided on a surface 132b on the other side (the side of the display device 115) of the base film 132.

The first electrode portion 140 includes a first conductor 141 arranged in a predetermined pattern on the surface 132a on one side (observer side, side in contact with a finger 105 in FIG. 5) of the base film 132. The second electrode portion 145 includes a second conductor 146 arranged in a predetermined pattern on the surface 132b on the other side (the side of the display device 115) of the base film 132. As described above, the film sensor 130 is arranged on the display panel of the display device 115.

The base film 132, the first conductor 141, and the second conductor 146 have transmittance, and the observer can observe an image displayed on the display device 115 through them.

The first conductor 141 and the second conductor 146 are formed of a conductive material (for example, indium tin oxide (ITO)), and are electrically connected to a detection circuit of a detection controller (not shown) configured to detect a contact position of the outer conductor 105 such as a finger with the cover panel 112.

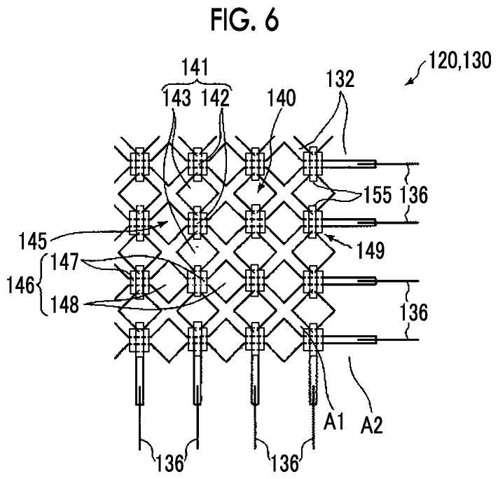

In addition, an example of the cover module used in the touch panel according to the present disclosure is shown in FIG. 6.

FIG. 6 is a top view showing another example of the cover module used in the disclosure.

As shown in FIG. 6, the cover module may be provided on the surface 131a on one side of the base film 132 so as to be insulating from the first electrode portion 140 and the second electrode portion 145. In a case of being observed from a normal direction of the film surface of the base film 132, the first conductor 141 included in the first electrode portion 140 and the second conductor 146 included in the second electrode portion 145 intersect each other only at line portions 142 and 147 of the conductors 141 and 146, but in the disclosure, an insulating layer 149 is interposed between the conductors 141 and 146 in an intersection region of the conductors 141 and 146. A bridge portion 155 formed from above the insulating layer 149 provided in the intersection region and electrically connecting the bulging portions of the adjacent conductors 141 is formed as a bridge portion in another step of the bulging portion 143 of the conductor 141 and the line portion 147 and the bulging portion 148 of the conductor 146.

(Method for Manufacturing Laminate)

The method for producing a laminate according to the disclosure may be a method using the transfer film according to the disclosure, is preferably a method including a step of transferring at least the first transparent layer of the transfer film according to the disclosure on a substrate having an electrode, and a step of curing at least a part of the first transparent layer to form a cured layer, and is more preferably method including a step of transferring at least the first transparent layer, and a step of curing at least a part of the transferred first transparent layer to form a cured layer.

The preferred embodiment of the laminate obtained by the method for producing the laminate according to the present disclosure is the same as the preferred embodiment of the laminate according to the present disclosure described above.

In addition, the laminate according to the present disclosure is preferably a laminate produced by the method for producing a laminate according to the present disclosure.

The transfer in the method for producing a laminate according to the present disclosure can be performed by using a well-known transfer method and laminating method. In addition, for details of the preferable transfer method, a preferred embodiment in the photosensitive layer forming step of the manufacturing method of a touch panel which will be described later can be referred to.

The substrate having the above electrodes in the method for producing a laminate according to the present disclosure preferably includes electrodes on the surface of the substrate. In addition, the transfer in the method for producing a laminate according to the present disclosure is preferably transfer of the first transparent layer of the transfer film according to the disclosure so as to come into contact with at least a part of the electrode of the substrate including the electrode on the surface.

The curing in the method for producing a laminate according to the present disclosure is preferably curing by light or heat depending on the composition of each layer in the transfer film according to the present disclosure used.

Among these, the curing by exposure is preferable, and curing by patternwise exposure is more preferable, from a viewpoint of forming a pattern in a desired shape.

The curing method by light or heat is not particularly limited, and the curing can be performed by a well-known method. In addition, for the preferred pattern expose method, a preferred embodiment in the patternwise exposure step of the manufacturing method of a touch panel which will be described later can be referred to.

In addition, the method for manufacturing the laminate of the disclosure may include a step other than the steps described above.

The other steps are not particularly limited and may include well-known steps, as desired.

(Manufacturing Method of Touch Panel)

The method of manufacturing the touch panel according to the disclosure is not particularly limited, and the following manufacturing method is preferable.

The preferred manufacturing method of the touch panel according to the disclosure includes

a step for convenience, and is a step of preparing a substrate for a touch panel having a structure in which the electrode and the like (that is, at least one of the electrode for a touch panel or the wiring for a touch panel) are disposed on a substrate (hereinafter, also referred to as a “preparation step”),

a step of forming a photosensitive layer on a surface of the substrate for a touch panel, on a side where the electrode and the like are disposed, using the transfer film according to the disclosure (hereinafter, also referred to as a “photosensitive layer forming step”),

a step of performing the patternwise exposure with respect to the photosensitive layer formed on the surface of the substrate for a touch panel (hereinafter, also referred to as a “patternwise exposure step”), and

a step of developing the patternwise exposed photosensitive layer to obtain an electrode protective film for a touch panel which protects at least a part of the electrode or the like (hereinafter, also referred to as a “development step”).

According to the preferred manufacturing method, a touch panel comprising the electrode protective film for a touch panel having excellent bending resistance can be manufactured.

In addition, in the preferred manufacturing method, even in a case where the photosensitive layer is formed under the laminating condition at a high temperature using the transfer film according to the disclosure, the occurrence of the development residue is suppressed in the unexposed portion of the photosensitive layer after the development.

Hereinafter, each step of the preferred manufacturing method will be described.

<Preparation Step>

The preparation step is a step for convenience, and is a step of preparing a substrate for a touch panel having a structure in which the electrode and the like (that is, at least one of the electrode for a touch panel or the wiring for a touch panel) are disposed on the substrate.

The preparation step may be a step of only simply preparing the substrate for a touch panel manufactured in advance, or may be a step of manufacturing the substrate for a touch panel.

The preferred embodiment of the substrate for a touch panel is as described above.

<Photosensitive Layer Forming Step>

The photosensitive layer forming step is a step of forming a photosensitive layer on a surface of the substrate for a touch panel, on a side where the electrode and the like are disposed, using the transfer film according to the disclosure.

Hereinafter, in the photosensitive layer forming step, the embodiment using the transfer film according to the disclosure will be described.

Examples of the photosensitive layer include a first transparent layer, a second transparent layer, and a third transparent layer of the transfer film according to the present disclosure.

In a case where the transfer film according to the disclosure includes the first transparent layer and the second transparent laver as a photosensitive layer, for example, the photosensitive layer is formed on the surface by laminating the transfer film according to the disclosure on the surface of the substrate for a touch panel on a side on which the electrode and the like are disposed, and transferring the second transparent layer of the transfer film according to the disclosure on the surface.

In a case where the transfer film according to the present disclosure includes a first transparent layer, a second transparent layer, and a third transparent layer as a photosensitive layer, the photosensitive layer is formed on the surface by transferring the third transparent layer of the transfer film according to the disclosure onto the surface.

The laminating (transfer of the photosensitive layer) can be performed using a well-known laminator such as a vacuum laminator or an auto-cut laminator.

As the laminating condition, a general condition can be applied.

The laminating temperature is preferably 80° C. to 150° C., more preferably 90° C. to 150° C., and particularly preferably 100° C. to 150° C.

As described above, in the embodiment using the transfer film according to the disclosure, even in a case where the laminating temperature is a high temperature (for example, 120° C. to 150° C.), the occurrence of the development residue due to thermal fogging is suppressed.

In a case of using a laminator comprising a rubber roller, the laminating temperature indicates a temperature of the rubber roller.

A temperature of the substrate in a case of laminating is not particularly limited. The temperature of the substrate at the time of laminating is 0° C. to 150° C., preferably 20° C. to 150° C., and more preferably 30° C. to 150° C. In a case of using a resin substrate as the substrate, the temperature of the substrate at the time of laminating is preferably 10° C. to 80° C., more preferably 20° C. to 60° C., and particularly preferably 30° C. to 50° C.

In addition, linear pressure at the time of laminating is preferably 0.5 N/cm to 20 N/cm, more preferably 1 N/cm to 10 N/cm, and particularly preferably 1 N/cm to 5 N/cm.

In addition, a transportation speed (laminating speed) at the time of laminating is preferably 0.5 m/min to 5 m/min and more preferably 1.5 m/min to 3 m/min.

For example, in a case of using the transfer film of the first embodiment having a laminated structure of “the protective film/first transparent layer/interlayer/thermoplastic resin layer/temporary support”, first, the protective film is peeled off from the transfer film to expose the first transparent layer, the transfer film and the substrate for a touch panel are bonded to each other so that the exposed first transparent layer and the surface of the substrate for a touch panel on a side on which the electrode and the like are disposed are in contact with each other, and heating and pressurizing are performed. Accordingly, the first transparent layer of the transfer film of the first embodiment is transferred onto the surface of the substrate for a touch panel on a side on which the electrode and the like are disposed, and a laminate having a laminated structure of “temporary support/thermoplastic resin layer/interlayer/first transparent layer/electrode and the like/substrate” is formed. In this laminated structure, the portion of “electrode and the like/substrate” is the substrate for a touch panel.

After that, the temporary support is peeled off from the laminate, as necessary. However, the patternwise exposure which will be described later can be also performed, by leaving the temporary support.

As an example of the method of transferring the first transparent layer of the transfer film on the substrate for a touch panel and performing patternwise exposure and development, a description disclosed in paragraphs 0035 to 0051 of JP2006-023696A can also be referred to.

<Patternwise Exposure Step>

The patternwise exposure step is a step of performing the patternwise exposure with respect to the photosensitive layer formed on the substrate for a touch panel.

Here, the patternwise exposure indicates exposure of the embodiment of performing the exposure in a pattern shape, that is, the embodiment in which an exposed portion and an unexposed portion are present.

The exposed portion of the photosensitive layer on the substrate for a touch panel in the patternwise exposure is cured and finally becomes the cured film.

Meanwhile, the unexposed portion of the photosensitive layer on the substrate for a touch panel in the patternwise exposure is not cured, and is removed (dissolved) with a developer in the subsequent development step. With the unexposed portion, the opening of the cured film can be formed after the development step.

The patternwise exposure may be exposed through a mask or may be digital exposure using a laser or the like.

As a light source of the patternwise exposure, a light source can be suitably selected, as long as it can emit light at a wavelength region (for example, 365 nm or 405 nm) at which the photosensitive layer can be cured. Examples of the light source include various lasers, a light emitting diode (LED), an ultra-high pressure mercury lamp, a high pressure mercury lamp, and a metal halide lamp. An exposure intensity is preferably 5 mJ/cm² to 200 mJ/cm², and more preferably 10 m/cm² to 200 m/cm².

In a case where the photosensitive layer is formed on the substrate using the transfer film, the patternwise exposure may be performed after peeling the temporary support, or the temporary support may be peeled off after performing the exposure before peeling off the temporary support.

In addition, in the exposure step, the heat treatment (so-called post exposure bake (PEB)) may be performed with respect to the photosensitive layer after the patternwise exposure and before the development.

<Development Step>

The development step is a step of obtaining the electrode protective film for a touch panel which protects at least a portion of the electrode and the like, by developing the patternwise exposed photosensitive layer (that is, by dissolving the unexposed portion of the patternwise exposure with a developer).

A developer used in the development is not particularly limited, and a well-known developer such as a developer disclosed in JP993-072724A (JP-H5-072724A) can be used.

As the developer, an alkali aqueous solution is preferably used.

Examples of the alkali compound which can be included in the alkali aqueous solution include sodium hydroxide, potassium hydroxide, sodium carbonate, potassium carbonate, sodium hydrogen carbonate, potassium hydrogencarbonate, tetramethyl ammonium hydroxide, tetraethyl ammonium hydroxide, tetrapropyl ammonium hydroxide, tetrabutylammonium hydroxide, and choline (2-hydroxyethyltrimethylammonium hydroxide).

The pH of the alkali aqueous solution at 25° C. is preferably 8 to 13, more preferably 9 to 12, and particularly preferably 10 to 12.

A content of the alkaline compound in the alkali aqueous solution is preferably 0.1% by mass to 5% by mass and more preferably 0.1% by mass to 3% by mass with respect to a total amount of the alkali aqueous solution.

The developer may include an organic solvent having miscibility with water.

Examples of the organic solvent include methanol, ethanol, 2-propanol, 1-propanol, butanol, diacetone alcohol, ethylene glycol monomethyl ether, ethylene glycol monoethyl ether, ethylene glycol mono-n-butyl ether, benzyl alcohol, acetone, methyl ethyl ketone, cyclohexanone, ε-caprolactone, γ-butyrolactone, dimethylformamide, dimethylacetamide, hexamethylphosphoramide, ethyl lactate, methyl lactate, ε-caprolactam, and N-methylpyrrolidone.

A concentration of the organic solvent is preferably 0.1% by mass to 30% by mass.

The developer may include a well-known surfactant. A concentration of the surfactant is preferably 0.01% by mass to 10% by mass.

A liquid temperature of the developer is preferably 20° C. to 40° C.

Examples of the development method include methods such as puddle development, shower development, shower and spin development, and dip development.

In a case of the shower development, the unexposed portion of the photosensitive layer is removed by spraying the developer to the photosensitive layer after the patternwise exposure as a shower. In a case of using the transfer film comprising at least one of the photosensitive layer, the thermoplastic resin layer, or the interlayer, after the transfer of these layers onto the substrate and before the development of the photosensitive layer, an alkali solution having a low solubility of the photosensitive layer may be sprayed as a shower, and at least one of the thermoplastic resin layer or the interlayer (both layers, in a case where both layers are present) may be removed in advance.

In addition, after the development, the development residue is preferably removed by spraying a cleaning agent with a shower and rubbing with a brush or the like.

A liquid temperature of the developer is preferably 20° C. to 40° C.

The development step may include a stage of performing the development, and a stage of performing the heat treatment (hereinafter, also referred to as “post baking”) with respect to the cured film obtained by the development.

In a case where the substrate is a resin substrate, a temperature of the post baking is preferably 100° C. to 160° C. and more preferably 130° C. to 160° C.

A resistance value of the transparent electrode pattern can also be adjusted by this post baking.

In addition, in a case where the photosensitive layer includes a carboxy group-containing (meth)acrylic resin, at least a part of the carboxy group-containing (meth)acrylic resin can be changed to carboxylic acid anhydride by the post baking. This improves developability and hardness of the cured film.

In addition, the development step may include a stage of performing the development, and a stage of exposing the cured film obtained by the development (hereinafter, also referred to as “post exposure”).

In a case where the development step includes a stage of performing the post exposure and a stage of performing the post baking, the post exposure, and the post baking are preferably performed in this order.

Regarding the patternwise exposure and the development, a description disclosed in paragraphs 0035 to 0051 of JP2006-023696A can be referred to, for example.

The preferred manufacturing method of the touch panel of the disclosure may include a step other than the steps described above. As the other step, a step (for example, washing step or the like) which may be provided in a normal photolithography step can be applied without any particular limitations.

(Image Display Device)

The image display device according to the disclosure comprises the capacitive input device according to the disclosure, preferably, the touch panel according to the disclosure (for example, touch panels of the first and second specific examples).

As the image display device according to the disclosure, a liquid crystal display device having a structure in which the touch panel according to the disclosure is overlapped on a well-known liquid crystal display element is preferable.

As the structure of the image display device comprising the touch panel, for example, a structure disclosed in “The latest Touch Panel Technology” (published 6 Jul. 2009, Techno Times), “Technologies and Developments of Touch Panels” supervised by Yuji Mitani, CMC Publishing CO., LTD. (2004, 12), FPD International 2009 Forum T-11 lecture text book, Cypress Semiconductor Corporation application note AN 2292 can be applied.

### EXAMPLES

Hereinafter, the disclosure will be described more specifically with reference to examples. The material, the amount used, the ratio, the process contents, the process procedure, and the like shown in the following examples can be suitably changed, within a range not departing from a gist of the disclosure. Accordingly, the range of the disclosure is not limited to specific examples shown below. “part” and “%” are based on mass, unless otherwise noted.

In the following examples, a weight-average molecular weight of a resin is a weight-average molecular weight obtained by performing polystyrene conversion of a value measured by gel permeation chromatography (GPC). Further, a theoretical acid value was used for the acid value.

<Preparation of Coating Solution for Forming First Transparent Layer>

Materials A-1 to A-8, which are first coating liquids for forming a transparent layer, were prepared so as to have compositions shown in Table 1 or Table 2.

TABLE 1

| | | Material | Material | Material |
|---|---|---|---|---|
| | Material | A-1 | A-2 | A-3 |
| Metal oxide | Titania Sol R: TiO₂ particles (containing tin oxide and silicon | — | — | 33.28 |
| particle | dioxide) methanol dispersion liquid (non-volatilized amount: 30.5%) | | | |
| | manufactured by Nissan Chemical Corporation | | | |
| Polymerizable | Tricyclodecanedimethanol diacrylate | 5.60 | 5.60 | 3.64 |
| compound | (A-DCP, manufactured by Shin-Nakamura Chemical Co., Ltd.) | | | |
| | Carboxy group-containing monomer ARONIX TO-2349 | 0.93 | 0.93 | 0.60 |
| | (manufactured by TOAGOSEI CO., LTD.) | | | |
| | Urethanee acrylate 8UX-015A | 2.80 | — | 1.82 |
| | (manufactured by TAISEI FINE CHEMICAL CO., LTD.) | | | |
| Thiol compound | MTNR1 (manufactured by SHOWA DENKO K.K.) | — | 2.80 | — |
| Binder polymer | The following compound A (acid value 95 mgKOH/g) | 15.44 | 15.44 | 10.04 |
| Photopolymeri- | 1-[9-ethyl-6-(2-methylbenzoyl)-9H-carbazol-3-yl]ethan-1- | 0.11 | 0.11 | 0.07 |
| zation initiator | (O-acetyloxime) (OXE-02, manufactured by BASF Japan Ltd.) | | | |
| | 2-methyl-1-(4-methylthiophenyl)-2-morpholinopropan-1-one | 0.21 | 0.21 | 0.14 |
| | (Irgacure 907, manufactured by BASF Japan Ltd.) | | | |
| Sensitizer | N-phenylglycine | 0.03 | 0.03 | 0.02 |
| Blocked isocyanate | Karenz AOI-BM (manufactured by SHOWA DENKO K.K.) | 3.62 | 3.62 | 2.35 |
| compound | | | | |
| Additive | 1,2,4-triazole (manufactured by Otsuka Chemical Co., Ltd.) | 0.09 | — | 0.06 |
| | Mercaptothiadiazole | — | 0.09 | — |
| | MEGAFACE F551A (manufactured by DIC CORPORATION) | 0.16 | 0.16 | 0.10 |
| Solvent | 1-methoxy-2-propyl acetate | 31.01 | 31.01 | 7.88 |
| | Methyl ethyl ketone | 40.00 | 40.00 | 40.00 |

| | | | |
|---|---|---|---|
| Polymerizable compound/binder polymer ratio (mass ratio) | 0.60 | 0.60 | 0.60 |
| Total (parts by mass) | 100 | 100 | 100 |

TABLE 2

| | | Material | Material | Material | Material | Material |
|---|---|---|---|---|---|---|
| | Material | A-4 | A-5 | A-6 | A-7 | A-8 |
| TiO₂ particles | Titania Sol R: TiO₂ particles (containing tin oxide and silicon | — | — | 40.16 | — | — |
| | dioxide) methanol dispersion liquid (non-volatilized amount: | | | | | |
| | 30.5%) manufactured by Nissan Chemical Corporation | | | | | |
| Polymerizable | Tricyclodecanedimethanol diacrylate | 5.60 | 5.60 | 3.64 | 4.21 | 4.49 |
| compound | (A-DCP, manufactured by Shin-Nakamura Chemical Co., Ltd.) | | | | | |
| | Carboxy group-containing monomer ARONIX TO-2349 | 0.93 | 0.93 | 0.60 | 0.70 | 0.75 |
| | (manufactured by TOAGOSEI CO., LTD.) | | | | | |
| | Urethanee acrylate 8UX-015A | 2.80 | — | 1.82 | — | — |
| | (manufactured by TAISEI FINE CHEMICAL CO., LTD.) | | | | | |
| | A-NOD-N | — | — | — | 2.10 | — |
| | (manufactured by Shin-Nakamura Chemical Co., Ltd.) | | | | | |
| | A-DOD-N | — | — | — | — | 2.24 |
| | (manufactured by Shin-Nakamura Chemical Co., Ltd.) | | | | | |
| Thiol | MTNR1 (manufactured by SHOWA DENKO K.K.) | — | 2.80 | — | — | — |
| compound | | | | | | |
| Binder polymer | The following compound A (acid value 95 mgKOH/g) | — | — | — | — | — |
| | P-10 (acid value: 103 mgKOH/g, concentration of solid contents: | 42.53 | 42.53 | 30.30 | — | — |
| | 36.3% by mass) | | | | | |
| | P-20 (acid value: 83 mgKOH/g, concentration of solid contents: | — | — | — | 38.78 | 37.45 |
| | 36.3% by mass) | | | | | |
| Photopoly- | 1-[9-ethyl-6-(2-methylbenzoyl)-9H-carbazol-3-yl]ethan-1-(O- | 0.11 | 0.11 | 0.07 | 0.08 | 0.09 |
| meriztion | acetyloxime) (OXE-02, manufactured by BASF Japan Ltd.) | | | | | |
| initiator | 2-methyl-1-(4-methylthiophenyl)-2-morpholinopropan-1-one | 0.21 | 0.21 | 0.14 | 0.16 | 0.16 |
| | (Irgacure 907, manufactured by BASF Japan Ltd.) | | | | | |
| Sensitizer | N-phenylglycine | 0.03 | 0.03 | 0.02 | 0.03 | 0.03 |
| Blocked | Karenz AOI-BM (manufactured by SHOWA DENKO K.K.) | 3.62 | 3.62 | 2.35 | 3.13 | 3.13 |
| isocyanate | | | | | | |
| compound | | | | | | |
| Additive | 1,2,4-triazole (manufactured by Otsuka Chemical Co., Ltd.) | 0.09 | — | 0.06 | — | — |
| | Mercaptothiadiazole | — | 0.09 | — | — | — |
| | Benzimidazole (manufactured by Tokyo Chemical Industry Co., | — | — | — | 0.17 | 0.17 |
| | Ltd.) | | | | | |
| | SMA EF-40 (manufactured by Cray Valley) | — | — | — | 0.30 | 0.30 |
| | MEGAFACE F551A | 0.16 | 0.16 | 0.10 | 0.16 | 0.16 |
| | (manufactured by DIC Corporation) | | | | | |
| Solvent | 1-methoxy-2 -propyl acetate | 3.92 | 3.92 | 0.00 | 10.18 | 11.03 |
| | Methyl ethyl ketone | 40.00 | 40.00 | 20.73 | 40.00 | 40.00 |

| | | | | | |
|---|---|---|---|---|---|
| Polymerizable compound/binder polymer ratio (mass ratio) | 0.60 | 0.60 | 0.55 | 0.50 | 0.55 |
| Total (parts by mass) | 100 | 100 | 100 | 100 | 100 |

TO-2349: Monomer having a carboxy group (Aronix (registered trademark) TO-2349 manufactured by Toagosei Co., Ltd., a mixture of a pentafunctional ethylenically unsaturated compound and a hexafunctional ethylenically unsaturated compound)
MTNR1: Thiol compound, 1,3,5-tris(3-mercapatobutyloxyethyl)-1,3,5-triazine-2,4,6(1H,3H,5H)-trion, Karenz MTNR1 manufactured by Showa Denko K. K.

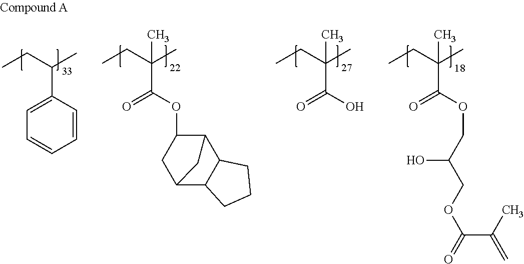

A numerical value written together with each constitutional unit in Compound A is a content ratio (molar ratio) of the constitutional unit. A weight-average molecular weight Mw of Compound A was 17,000, and Mn was 7000.

<Synthesis of Binder Polymers P-10>

244.2 parts by mass of propylene glycol monomethyl ether (MFG, manufactured by FUJIFILM Wako Pure Chemical Corporation) was put into a three-necked flask and held at 90° C. under nitrogen. A mixed solution of 118.7 parts by mass of dicyclopentanyl methacrylate (manufactured by Tokyo Chemical Industry Co., Ltd.), 94.7 parts by mass of methacrylic acid (MAA, manufactured by FUJIFILM Wako Pure Chemical Corporation), 90.0 parts by mass of styrene (manufactured by FUJIFILM Wako Pure Chemical Corporation), 188.5 parts by mass of MFG,

0.0610 parts by mass of p-methoxyphenol (manufactured by FUJIFILM Wako Pure Chemical Corporation), and 16.9 parts by mass of V-601 (dimethyl 2,2′-azobis (2-methyl propionate), FUJIFILM Wako Pure Chemical Corporation) was added dropwise over 3 hours.

After the dropwise addition, the mixture was stirred at 90° C. for 1 hour, a mixed solution of V-601 (2.1 parts by mass) and MFG (5.2 parts by mass) was added and stirred for 1 hour, and a mixed solution of V-601 (2.1 parts by mass) and MFG (5.2 parts by mass) was further added thereto. After stirring for 1 hour, a mixed solution of V-601 (2.1 parts by mass) and MFG (5.2 parts by mass) was further added. After stirring for 3 hours, 2.9 parts by mass of MFG and 166.9 parts by mass of propylene glycol monomethyl ether acetate (PGMEA, manufactured by Daicel Chemical Industries, Ltd.) were added and stirred until it was homogenous.

1.5 parts by mass of tetramethylammonium bromide (TEAB, manufactured by Tokyo Chemical Industry Co., Ltd.) as an additive catalyst and 0.7 parts by mass of p-methoxyphenol were added to a reaction solution and a temperature was raised to 100° C. In addition, 61.9 parts by mass of glycidyl methacrylate (GMA, manufactured by FUJIFILM Wako Pure Chemical Corporation) was added and stirred at 100° C. for 9 hours to obtain an MFG/PGMEA mixed solution of the polymer P-10. The weight-average molecular weight of P-10 measured by GPC was 17,000 (in terms of polystyrene), and the number average molecular weight was 7,000. The concentration of solid contents was 36.3% by mass.

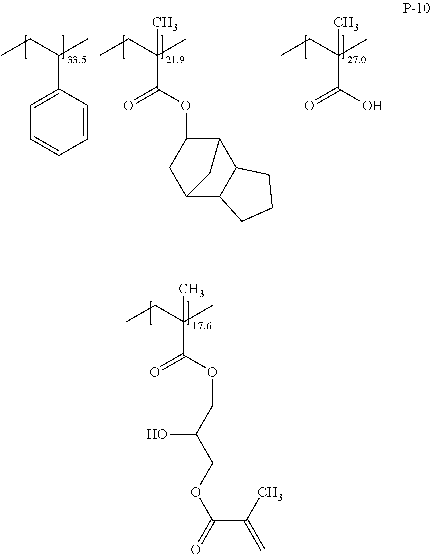

A numerical value written together with each constitutional unit in Compound P-10 is a content ratio (molar ratio) of the constitutional unit.

<Synthesis of Binder Polymers P-20>

P-20 was synthesized by the same method as the synthesis of the polymer P-10 except that the type and amount of the monomers were changed. A numerical value written together with each constitutional unit in P-20 is a content ratio (molar ratio) of the constitutional unit.

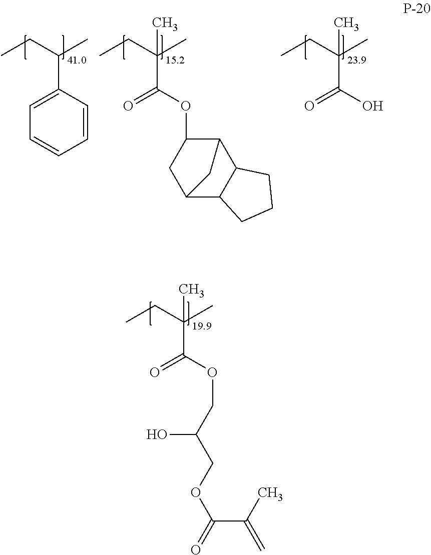

Karenz AOI-BM: 2-(O-[1′-methylpropylideneamino] carbonylamino) ethyl acrylate, manufactured by Showa Denko KK.

<Preparation of Coating Solution for Forming Second Transparent Layer>

Next, materials B-1 to B-15, which are coating solutions for forming the second transparent layer, were prepared with the compositions shown in Table 3 or Table 4.

TABLE 3

| | | Material | | | | | | | | |
|---|---|---|---|---|---|---|---|---|---|---|
| | | Material | Material | Material | Material | Material | Material | Material | Material | Material |
| | | B-1 | B-2 | B-3 | B-4 | B-5 | B-6 | B-7 | B-8 | B-9 |
| Titania Sol R: TiO₂ particles | | 1.90 | 2.71 | 3.26 | 3.80 | 4.34 | — | — | — | — |
| (containing tin oxide and | | | | | | | | | | |
| silicon dioxide) methanol dispersion | | | | | | | | | | |
| liquid (non-volatilized | | | | | | | | | | |
| amount: 30.5%) manufactured | | | | | | | | | | |
| by Nissan Chemical Corporation | | | | | | | | | | |
| TS-020: TiO₂ particles | | — | — | — | — | — | 5.05 | — | — | — |
| (containing tin oxide and silicon | | | | | | | | | | |
| dioxide) equeous dispersion liquid | | | | | | | | | | |
| (non-volatilized amount: 25.8%) | | | | | | | | | | |
| manufactured by Tayca Corporation | | | | | | | | | | |
| SRD-W: TiO₂ particles | | — | — | — | — | — | — | 6.62 | — | — |
| aqueous dispersion liquid | | | | | | | | | | |
| (non-volatilized amount: 15%) | | | | | | | | | | |
| manufactured by Sakai | | | | | | | | | | |
| Chemical Industry Co., Ltd. | | | | | | | | | | |
| NANOUSE OZS-30M: ZrO₂ particles | | — | — | — | — | — | — | — | 4.88 | — |
| (containing tin oxide) | | | | | | | | | | |
| methanol disperson liquid | | | | | | | | | | |
| (non-volatilized amount 30.5%) | | | | | | | | | | |
| manufactured by Nissan | | | | | | | | | | |
| Chemical Corporation | | | | | | | | | | |
| WT-01: TiO₂ particles | | — | — | — | — | — | — | — | — | 5.05 |
| (containing silicon dioxide) | | | | | | | | | | |
| aqueous dispersion liquid | | | | | | | | | | |
| (non-volatilized amount: 40%) | | | | | | | | | | |
| manufactured by Tayca Corporation | | | | | | | | | | |
| Ammonia water (25%) | | 7.84 | 7.84 | 7.84 | 7.84 | 7.84 | 7.84 | 7.84 | 7.84 | 7.84 |
| Binder | Copolymer resin of | 0.80 | 0.60 | 0.47 | 0.34 | 0.20 | 0.20 | 0.47 | 0.07 | 0.47 |
| polymer | methacrylic acid/ | | | | | | | | | |
| | allyl methacrylate | | | | | | | | | |
| | (Mw: 38,000, | | | | | | | | | |
| | composition ratio = 20/80, | | | | | | | | | |
| | non-volatilized | | | | | | | | | |
| | amount: 99.8%) | | | | | | | | | |
| | The following | 0.20 | 0.05 | 0.12 | 0.08 | 0.05 | 0.05 | 0.12 | 0.02 | 0.12 |
| | compound B | | | | | | | | | |

| | | | | | | | | | |
|---|---|---|---|---|---|---|---|---|---|
| Carboxy group-containing monomer | 0.04 | 0.03 | 0.03 | 0.03 | 0.03 | 0.03 | 0.03 | 0.03 | 0.03 |
| ARONIX TO-2349 | | | | | | | | | |
| (manufactured by TOAGOSEI | | | | | | | | | |
| CO., LTD.) | | | | | | | | | |
| Benzotriazole BT-LX | 0.04 | 0.03 | 0.03 | 0.03 | 0.03 | 0.03 | 0.03 | 0.03 | 0.03 |
| (manufactured by JOHOKU | | | | | | | | | |
| CHEMICAL CO., LTD) | | | | | | | | | |
| MEGAFACE F444 (manufactured | 0.01 | 0.01 | 0.01 | 0.01 | 0.01 | 0.01 | 0.01 | 0.01 | 0.01 |
| by DIC CORPORATION) | | | | | | | | | |
| Ion exchange water | 23.5 | 22.7 | 22.0 | 21.9 | 21.5 | 20.8 | 18.7 | 20.9 | 20.2 |
| Methanol | 65.7 | 66.0 | 66.2 | 66.0 | 66.0 | 66.0 | 66.2 | 66.2 | 66.2 |
| Total (parts by mass) | 100 | 100 | 100 | 100 | 100 | 100 | 100 | 100 | 100 |

TABLE 4

| | | Material | Material | Material | Material | Material | Material |
|---|---|---|---|---|---|---|---|
| Material | | B-10 | B-11 | B-12 | B-13 | B-14 | B-15 |
| Titania Sol R: TiO₂ particles (containing tin oxide and silicon | | — | — | — | — | — | — |
| dioxide) methanol dispersion liquid (non-volatilized amount: 30.5%) | | | | | | | |
| manufactured by Nissan Chemical Corporation | | | | | | | |
| TS-020: TiO₂ particles (containing tin oxide and silicon dioxide) | | 3.27 | 3.27 | 3.27 | 3.26 | 3.27 | 3.27 |
| aqueous dispersion liquid (non-volatilized amount: 25.8%) | | | | | | | |
| manufactured by Tayca Corporation | | | | | | | |
| SRD-W: TiO₂ particles aqueous dispersion liquid (non-volatilized | | — | — | — | — | — | — |
| amount: 15%) manufactured by Sakai Chemical Industry Co., Ltd. | | | | | | | |
| NANOUSE OZS-30M: ZrO₂ particles (containing tin oxide) | | — | — | — | — | — | — |
| methanol dispersion liquid (non-volatilized amount 30.5%) | | | | | | | |
| manufactured by Nissan Chemical Corporation | | | | | | | |
| WT-01: TiO₂ particles (containing silicon dioxide) aqueous | | — | — | — | — | — | — |
| dispersion liquid (non-volatilized amount: 40%) manufactured by | | | | | | | |
| Tayca Corporation | | | | | | | |
| Ammonia water (25%) | | 7.84 | 7.84 | 7.84 | 7.84 | 7.84 | 7.84 |
| Binder | Copolymer resin of methacrylic acid/allyl | — | — | — | — | — | — |
| polymer | methacrylate | | | | | | |
| | (Mw: 38,000, composition ratio = 20/80, | — | — | — | — | — | — |
| | non-volatilized amount: 99.8%) | | | | | | |
| | The following compound B | — | — | — | — | — | — |
| | P-3 (acid value: 156 mgKOH/g) | 0.46 | 0.46 | 0.46 | 0.46 | 0.46 | 0.46 |
| | ARUFON UC-3920 (manufactured by TOAGOSEI | 0.08 | 0.08 | 0.08 | 0.08 | 0.08 | 0.08 |
| | CO., LTD) | | | | | | |

| | | | | | | |
|---|---|---|---|---|---|---|
| Carboxy group-containing monomer | 0.03 | — | — | — | — | 0.03 |
| ARONIX TO-2349 (manufactured by TOAGOSEI CO., LTD.) | | | | | | |
| Benzotriazole BT-LX (manufactured by JOHOKU CHEMICAL CO., | — | — | — | — | — | — |
| LTD) | | | | | | |
| 1,2,4-triazole (manufactured by Otsuka Chemical Co., Ltd.) | 0.03 | 0.03 | 0.03 | 0.03 | 0.03 | 0.03 |
| MEGAFACE F444 (manufactured by DIC CORPORATION) | — | — | — | 0.01 | 0.01 | — |
| MEGAFACE F510 (manufactured by DIC CORPORATION) | 0.01 | 0.01 | 0.01 | — | — | 0.01 |
| MEGFACE F410 (manufactured by DIC CORPORATION) | — | — | — | 0.01 | — | — |
| 3-Methacryloxypropyltrimethoxysilane | 0.03 | — | — | 0.03 | 0.03 | — |
| KBM-503: Silane coupling agent | | | | | | |
| (manufactured by Shin-Etsu Chemical Co Ltd.) | | | | | | |
| 3-Acryloxypropyltrimethoxysilane | — | 0.03 | — | — | — | — |
| KBM-5103: Silane coupling agent | | | | | | |
| (manufactured by Shin-Etsu Chemical Co., Ltd.) | | | | | | |
| 3-Glycidoxypropyltrimethoxysilane | — | — | 0.03 | — | — | — |
| KBM-403: Silane coupling agent | | | | | | |
| (manufactured by Shin-Etsu Chemical Co., Ltd.) | | | | | | |
| Organtics TC-200: titanium coupling agent (manufactured by | — | — | — | — | — | 0.03 |
| Matsumoto Fine Chemicals Co.; Ltd.) | | | | | | |
| Ion exchange water | 19.2 | 19.3 | 19.3 | 19.3 | 19.3 | 19.3 |
| Methanol | 69.0 | 69.0 | 69.0 | 69.0 | 69.0 | 69.0 |
| Total (parts by mass) | 100 | 100 | 100 | 100 | 100 | 100 |

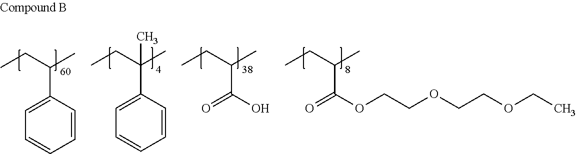

A weight-average molecular weight Mw of Compound B was 15,500. In addition, a numerical value written together on a lower right bracket with each constitutional unit in Compound B is a content ratio (molar ratio) of the constitutional unit.

<Synthesis of Binder Polymers P-3>

270.0 parts by mass of 1-methoxypropanol (manufactured by Tokyo Chemical Industry Co., Ltd.) was introduced into a three-neck flask, and a temperature was raised to 70° C. under a nitrogen stream while stirring. Meanwhile, 45.6 parts by mass of allyl methacrylate (manufactured by FUJIFILM Wako Pure Chemical Corporation) and 14.4 parts by mass of methacrylic acid (manufactured by FUJIFILM Wako Pure Chemical Corporation) are dissolved in 270.0 parts by mass of 1-methoxypropanol (manufactured by Tokyo Chemical Industry Co., Ltd.), 3.94 parts by mass of V-65 (manufactured by FUJIFILM Wako Pure Chemical Corporation) was dissolved to produce a dropwise addition liquid, and liquid was added dropwise to a flask for 2.5 hours. The reaction was carried out while keeping the stirred state for 2 hours. Then, the temperature was returned to room temperature (25° C., the same applies hereinafter), and the mixture was added dropwise to 2,700 parts by mass of stirred ion exchange water, and reprecipitation was carried out to obtain a turbid solution. The filtration was carried out by introducing a turbid solution in Nutche with a filter paper, and the filtered material was further cleaned with ion exchange water to obtain a wet powder. It was dried by blowing air at 45° C. to confirm that the amount became constant, and a binder polymer (methacrylic acid/allyl methacrylate copolymer resin) was obtained as a powder in a yield of 70%. The weight-average molecular weight of the binder polymer by GPC was 38,000 (in terms of polystyrene).

### Examples 1 to 21 and Comparative Examples 1 to 3: Production of Transfer Film

A coating amount on the temporary support of a polyethylene terephthalate film having a thickness of 16 μm (Lumirror 16KS40, manufactured by Toray Industries, Inc.) was adjusted to a coating amount so that a film thickness after drying is a thickness of Table 6 or Table 7 using a slit-shaped nozzle, and any one kind of the materials A-1 to A-8 for forming the first transparent layer shown in Table 6 or Table 7 was applied to form the first transparent layer.

After the solvent is volatilized in the drying zone at 100° C., the coating amount was adjusted to the amount so that the film thickness after drying is a film thickness shown in Table 6 or Table 7, to be applied to the first transparent layer, using at least one kind of the materials B-1 to B-15 for forming the second transparent layer shown in Table 6 or Table 7 in combination shown in Table 6 or Table 7 using the slit-shaped nozzle, and dried at a drying temperature at 80° C. to form the second transparent layer. A protective film (Lumirror 16KS40, manufactured by Toray Industries, Inc.) was pressure-bonded onto the second transparent layer to produce transfer films of Examples 1 to 21 and Comparative Examples 1 to 3.

In addition, in Example 11, the second transparent layer was not formed, and a protective film (Lumirror 16KS40, manufactured by Toray Industries, Inc.) was directly pressure-bonded onto the first transparent layer to produce a transfer film.

<Manufacturing of Transparent Electrode Pattern Film Used for Manufacturing Laminate>

—Formation of Transparent Film—

A cycloolefin resin film having a film thickness of 38 μm and a refractive index of 1.53 was subjected to a corona discharge treatment for 3 seconds under the conditions of an electrode length of 240 mm, a distance between work electrodes of 1.5 mm at an output voltage of 100% and an output of 250 W with a wire electrode having a diameter of 1.2 mm by using a high frequency oscillator, to perform the surface reforming. The obtained film was used as a transparent film substrate.

Next, a material of a material-C shown in Table 5 was applied onto a transparent film substrate using a slit-shaped nozzle, then irradiated with ultraviolet rays (integrated light amount of 300 mJ/cm²), and dried at approximately 110° C. to manufacture a transparent film having a refractive index of 1.60 and a film thickness of 80 nm.

TABLE 5

| Material | Material-C |
|---|---|
| ZrO₂: manufactured by Solar Co., Ltd., ZR-010 | 2.08 |
| DPHA solution (dipentaerythritol hexa-acrylate: 38%, dipentaerythritol penta-acrylate: 38%, | 0.29 |
| 1-methoxy-2-propyl acetate: 24%) | |
| Urethane monomer: UK oligo UA-32P manufactured by Shin-Nakamura Chemical Co., Ltd.: | 0.14 |
| non-volatilized amount 75%, 1-methoxy-2-propyl acetate: 25% | |
| Monomer mixture (polymerizable compound (b2-1) disclosed in paragraph [0111] of | 0.36 |
| JP2012-078528A, n = 1, tripentaerythritol octaacrylate content: 85%, total of n = 2 and n = 3 | |
| as impurities is 15%) | |
| Polymer solution 1 (structural formula P-25 disclosed in paragraph [0058] of | 1.89 |
| JP2008-146018A: weight-average molecular weight = 35,000, solid content: 45%, | |
| 1-methoxy-2-propyl acetate: 15%, 1-methoxy-2-propanol: 40%) | |
| Photo-radical polymerization initiator: | 0.03 |
| 2-benzyl-2-dimethylamino-1-(4-morpholinophenyl)-butanone (Irgacure (registered | |
| trademark) 379, manufachned by BASF Japan Ltd.) | |
| Photopolymerization initiator: KAYACURE-DETX-S (manufactured by Nippon Kayaku | 0.03 |
| Co., Ltd., alkyl thioxanthone) | |
| Polymer solution 2 (polymer of structural formula represented by Formula (3), solution | 0.01 |
| having weight-average molecular weight of 15,000, non-volatilized amount: 30% by mass, | |
| methyl ethyl ketone: 70% by mass) | |
| 1-methoxy-2-propyl acetate | 38.73 |
| Methyl ethyl ketone | 56.80 |
| Total (parts by mass) | 100 |

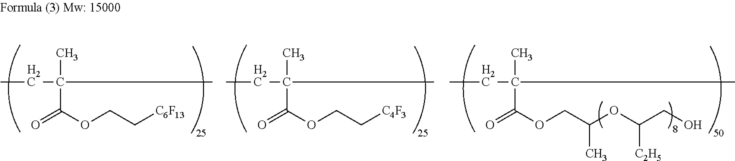

In addition, a numerical value written together on a lower right bracket with each constitutional unit in the polymer of a structural formula represented by Formula (3) is a content ratio (molar ratio) of the constitutional unit.

—Formation of Transparent Electrode Pattern—

A film in which a transparent film was laminated on the transparent film substrate obtained as described above was introduced into a vacuum chamber, and an ITO thin film having a thickness of 40 nm and a refractive index of 1.82 was formed using an ITO target (indium:tin=95:5 (molar ratio)) having a SnO₂ content of 10% by mass by a direct current (DC) magnetron sputtering (conditions: transparent film substrate temperature: 150° C., argon partial pressure: 0.13 Pa, oxygen partial pressure: 0.01 Pa), and a film in which a transparent film and a transparent electrode layer were formed on the transparent film substrate was obtained. A surface electrical resistance of the ITO thin film was 80Ω/□ (square per Ω).

—Preparation of Photosensitive Film E1 for Etching—

A coating solution for a thermoplastic resin layer consisting of the following formulation H1 was applied and dried on a polyethylene terephthalate film temporary support having a thickness of 75 μm using a slit-shaped nozzle. Next, a coating solution for an interlayer consisting of the following formulation P1 was applied and dried. In addition, a coating solution for photocurable resin layer for etching consisting of the following formulation E1 was applied and dried. By the method described above, a laminate formed of a thermoplastic resin layer having a dry film thickness of 15.1 μm, an interlayer having a dry film thickness of 1.6 μm, and a photocurable resin layer for etching having a film thickness of 2.0 μm on the temporary support was produced, and a protective film (polypropylene film having a thickness of 12 μm) was pressure-bonded finally. By doing so, a photosensitive film E1 for etching, which is a transfer material in which a temporary support, a thermoplastic resin layer, an interlayer (oxygen blocking film), and a photocurable resin layer for etching were integrated, was produced.

—Coating Solution for Photocurable Resin Layer for Etching: Formulation E1—
Methyl methacrylate/styrene/methacrylic acid copolymer (copolymer composition (% by mass): 31/40/29, weight-average molecular weight of 60,000, acid value of 163 mgKOH/g): 16 parts by mass
Monomer 1 (product name: BPE-500, manufactured by Shin-Nakamura Chemical Co., Ltd.): 5.6 parts by mass
Tetraethylene oxide monomethacrylate of hexamethylene diisocyanate 0.5 mol adduct: 7 parts by mass
Cyclohexanedimethanol monoacrylate as a compound having one polymerizable group in the molecule: 2.8 parts by mass
2-Chloro-N-butylacridone: 0.42 parts by mass
2,2-bis (o-chlorophenyl)-4,4′,5,5′-tetraphenylbiimidazole: 2.17 parts by mass
Malachite green oxalic acid: 0.02 parts by mass
Leuco crystal violet: 0.26 parts by mass
Phenothiazine: 0.013 parts by mass
Surfactant (product name: MEGAFACE F-780F, manufactured by DIC Corporation): 0.03 parts
Methyl ethyl ketone: 40 parts
1-Methenyl-2-propanol: 20 parts by mass

The viscosity of the coating solution E1 for the photocurable resin layer for etching at 100° C. after removing the solvent was 2,500 Pa·sec.

—Coating Solution for Thermoplastic resin layer: Formulation H1—
Methanol: 11.1 parts
Propylene glycol monomethyl ether acetate: 6.36 parts by mass
Methyl ethyl ketone: 52.4 parts by mass
Methyl methacrylate/2-ethylhexyl acrylate/benzyl methacrylate/methacrylic acid copolymer (copolymerization composition ratio (molar ratio)=55/11.7/4.5/28.8, molecular weight=100,000, Tg≈70° C.: 5.83 parts by mass
Styrene/acrylic acid copolymer (copolymerization composition ratio (molar ratio)=63/37, weight-average molecular weight=10,000, Tg≈100° C.): 13.6 parts by mass
Monomer 1 (product name: BPE-500, manufactured by Shin-Nakamura Chemical Co., Ltd.): 9.1 parts by mass
Fluorine-based polymer [components below]: 0.54 parts by mass
A copolymer of 40 parts by mass of fluoropolymer: C₆F₁₃CH₂CH₂OCOCH═CH₂, 55 parts by mass of (OCH(CH₃)CH₂)₇OCOCH═CH₂, and 5 parts by mass and H(OCHCH₂)₇OCOCH═CH₂ (weight-average molecular weight 30,000, methyl ethyl ketone 30% by mass solution, product name: MEGAFACE F780F, manufactured by DIC Corporation)

—Coating Solution for Interlayer: Formulation P1—
Polyvinyl alcohol (product name: PVA205, manufactured by Kuraray Co., Ltd., saponification degree=88%, polymerization degree 550): 32.2 parts by mass
Polyvinylpyrrolidone (product name: K-30, manufactured by Ashland Japan., Co., Ltd.): 14.9 parts by mass
Distilled water: 524 parts by mass
Methanol: 429 parts by mass

—Formation of Transparent Electrode Pattern—

A film in which a transparent film and a transparent electrode layer were formed on the transparent film substrate was washed, and the photosensitive film E1 for etching from which the protective film was removed was laminated. In the laminating conditions, a temperature of transparent film substrate was 130° C., a rubber roller temperature was 120° C., a linear pressure was 100 N/cm, and a transportation speed was 2.2 m/min.

After peeling off the temporary support, a distance between a surface of an exposure mask (quartz exposure mask having a transparent electrode pattern) and the photocurable resin layer for etching described above was set to 200 μm, and the patternwise exposure was performed with an exposure amount of 50 mJ/cm² (i ray).

Next, the treatment was performed at 25° C. for 100 seconds by using a triethanolamine-based developer (containing 30% by mass of triethanolamine, liquid obtained by diluting product name; T-PD2 (manufactured by FUJIFILM Corporation) 10-fold with pure water), and at 33° C. for 20 seconds by using a surfactant-containing cleaning solution (liquid obtained by diluting product name: T-SD3 (manufactured by FUJIFILM Corporation) 10-fold with pure water). Residues were removed with a rotating brush and an ultrahigh pressure cleaning nozzle. In addition, a post baking treatment at 130° C. for 30 minutes was performed to obtain a film in which a transparent film, a transparent electrode layer, and a photocurable resin layer pattern for etching were formed on a transparent film substrate.

The film in which the transparent film, the transparent electrode layer, and the photocurable resin layer pattern for etching were formed on the transparent film substrate was immersed in an etching tub containing an etching solution for ITO (hydrochloric acid, potassium chloride aqueous solution, liquid temperature of 30° C.), the treatment was performed for 100 seconds to dissolve and remove the transparent electrode layer in the exposed area that is not covered by the photocurable resin layer for etching, and a film with a transparent electrode pattern having a pattern of the photocurable resin layer for etching was obtained.

Next, the film with the transparent electrode pattern having a photocurable resin layer pattern for etching was immersed in a resist peeling tub containing a resist peeling solution (N-methyl-2-pyrrolidone, monoethanolamine, surfactant (product name: Surfinol 465, manufactured by Air Products Japan Inc.), liquid temperature 45° C.) and treated for 200 seconds to remove the photocurable resin layer for etching, and a film in which the transparent film and the transparent electrode pattern were formed on the transparent film substrate was obtained.

<Manufacturing of Transparent Laminate>

Using the transfer films of Examples and Comparative Examples from which the protective films were peeled off, the transparent film and the transparent electrode pattern of the film in which the transparent film and the transparent electrode pattern were formed on the transparent film substrate were transferred to a position so as to be covered by the transfer film. As a result, the third transparent layer, the second transparent layer, the first transparent layer, and the temporary support were transferred in this order by the transfer film on the transparent film and the transparent electrode pattern of the transparent film substrate. The transfer was performed in the conditions in which a temperature of transparent film substrate was 40° C., a rubber roller temperature was 100° C., a linear pressure was 3 N/cm, and a transportation speed was 2 m/min, by using a vacuum laminator manufactured by MCK Co., Ltd.

After that, a surface of an exposure mask (quartz exposure mask including a pattern for forming overcoat) and the temporary support were brought into contact with each other, and the patternwise exposure was performed with an exposure intensity of 10 m/cm² (i ray) through the temporary support, by using a proximity type exposure machine including an ultra-high pressure mercury lamp (manufactured by Hitachi High-Tech Corporation).

After peeling off the temporary support, the development treatment was carried out at 32° C. in a 1% sodium carbonate aqueous solution for 60 seconds. The residue was removed by spraying ultrapure water from an ultrahigh pressure cleaning nozzle onto the transparent film substrate after the development treatment. Subsequently, air was blown to remove moisture from the transparent film substrate, and post baking treatment was performed at 145° C. for 30 minutes to form a transparent laminate in which the transparent film, the transparent electrode pattern, the second transparent layer, and the first transparent layer were laminated in this order on the transparent film substrate.

[Evaluation of Transparent Laminate]

<Evaluation of Concealing Properties of Transparent Electrode Pattern>

A transparent laminate in which the transparent film, the transparent electrode pattern, the second transparent layer, and the first transparent layer were laminated in this order on the transparent film substrate was adhered to a black PET material through a transparent adhesive tape (manufactured by 3M Japan Ltd., product name, OCA tape 8171CL), and the entire substrate was shielded from light.

The concealing properties of the transparent electrode pattern were measured by irradiating the substrate manufactured as a fluorescent lamp (light source) with light from a glass surface side in a dark room and visually observing the reflected light from the glass surface diagonally. A. B, or C is preferable, A or B is more preferably, and A is particularly preferable.

(Evaluation Standards)

A: The transparent electrode pattern is completely invisible.

B: The transparent electrode pattern is slightly visible.

C: The transparent electrode pattern is more visible than the B, but not as visible as the D.

D: The transparent electrode pattern is more visible than the C, but it is not clearly visible and is practically acceptable.

E: The transparent electrode pattern is clearly visible and is not practically acceptable.

<HAZE Evaluation>

Using the obtained transparent laminate, a haze value (HAZE value) was measured using HAZE meter NDH4000 (manufactured by Nippon Denshoku Industries Co., Ltd.)

A measurement wavelength is 380 nm to 780 nm, and the measurement is based on JIS K7136 (2000).

The smaller the haze value, the higher the transparency, which is preferable.

<Surface Evaluation>

Using the obtained transparent laminate, the transparent laminate was observed from the first transparent layer side with an optical microscope at a magnification of 200 times. It was evaluated according to the following evaluation standard with the observed states. The levels of B or higher are preferably practically and A is more preferable.

A: No particular abnormality is seen on the entire surface.

B: There is a faint sea-island-like defect on the entire surface.

C: There is a clear sea-island-like defect on the entire surface.

<Adhesiveness Evaluation>

A cross-cut test of 100 squares was carried out with reference to the JIS standard (K5400-8.5). A square cut having a size of 1 mm was made on a transfer layer which is a test surface of the transparent laminate of each example and comparative example (first transparent layer, second transparent layer, and third transparent layer) using a cutter knife, the transparent adhesive tape #600 (manufactured by 3M Japan Ltd.) was strongly pressure-bonded and peeled off in a direction of 180° C., a state of the square was visually observed, and the adhesiveness according to the following evaluation standard was evaluated. A, B, or C is preferable, A or B is more preferably, and A is particularly preferable.

(Evaluation Standards)

A: 100% of the total area on the test surface is in close contact.

B: 95% or more and less than 100% of the total area on the test surface remains in close contact.

C: 65% or more and less than 95% of the total area on the test surface remains in close contact.

D: 35% or more and less than 65% of the total area on the test surface remains in close contact.

E: The percentage of the part closely attached and remaining is less than 35% of the entire area of the test surface.

The evaluation results are shown in Table 6 or 7.

TABLE 6

| | First transparent layer | | | | | | Second transparent layer | | | | | | | | | |
|---|---|---|---|---|---|---|---|---|---|---|---|---|---|---|---|---|
| | | | | Metal oxide particle | | | | | | Metal oxide particle | | | Evaluation result | | | |
| | | | | | Inorganic | | | | | | Inorganic | | | | | Concealing |
| | | | | | oxide | | | | | | oxide | | | | | properties |
| | | | | | component in | Average | | | | | component in | Average | | | | of |
| | | | | | metal oxide | primary | | | | | metal oxide | primary | | | | transparent |
| | | | Refractive | Content | particle and | particle | | | Refractive | Content | particle and | particle | Haze | | | electrode |
| | Material | Thickness | index | in layer | content thereof | diameter | Material | Thickness | index | in layer | content thereof | diameter | value | Surface | Adhesiveness | pattern |
| Example 1 | Material | 8 μm | 1.53 | — | — | — | Material | 70 nm | 1.60 | 35% by | Titanium oxide | 8 nm | 0.3% | A | A | C |
| | A-1 | | | | | | B-1 | | | mass | (79% by mass), | | | | | |
| | | | | | | | | | | | tin oxide | | | | | |
| | | | | | | | | | | | (12% by mass), | | | | | |
| | | | | | | | | | | | silicon dioxide | | | | | |
| | | | | | | | | | | | (9% by mass) | | | | | |
| Example 2 | Material | 8 μm | 1.53 | — | — | — | Material | 70 nm | 1.63 | 50% by | Titanium oxide | 8 nm | 0.4% | A | A | B |
| | A-1 | | | | | | B-2 | | | mass | (79% by mass), | | | | | |
| | | | | | | | | | | | tin oxide | | | | | |
| | | | | | | | | | | | (12% by mass), | | | | | |
| | | | | | | | | | | | silicon dioxide | | | | | |
| | | | | | | | | | | | (9% by mass) | | | | | |
| Example 3 | Material | 8 μm | 1.53 | — | — | — | Material | 70 nm | 1.70 | 60% by | Titanium oxide | 8 nm | 0.4% | A | A | A |
| | A-1 | | | | | | B-3 | | | mass | (79% by mass), | | | | | |
| | | | | | | | | | | | tin oxide | | | | | |
| | | | | | | | | | | | (12% by mass), | | | | | |
| | | | | | | | | | | | silicon dioxide | | | | | |
| | | | | | | | | | | | (9% by mass) | | | | | |
| Example 4 | Material | 8 μm | 1.53 | — | — | — | Material | 70 nm | 1.75 | 70% by | Titanium oxide | 8 nm | 0.4% | A | A | A |
| | A-1 | | | | | | B-4 | | | mass | (79% by mass), | | | | | |
| | | | | | | | | | | | tin oxide | | | | | |
| | | | | | | | | | | | (12% by mass), | | | | | |
| | | | | | | | | | | | silicon dioxide | | | | | |
| | | | | | | | | | | | (9% by mass) | | | | | |
| Example 5 | Material | 8 μm | 1.53 | — | — | — | Material | 70 nm | 1.80 | 80% by | Titanium oxide | 8 nm | 0.5% | A | A | B |
| | A-1 | | | | | | B-5 | | | mass | (79% by mass), | | | | | |
| | | | | | | | | | | | tin oxide | | | | | |
| | | | | | | | | | | | (12% by mass), | | | | | |
| | | | | | | | | | | | silicon dioxide | | | | | |
| | | | | | | | | | | | (9% by mass) | | | | | |
| Example 6 | Material | 8 μm | 1.53 | — | — | — | Material | 40 nm | 1.70 | 60% by | Titanium oxide | 8 nm | 0.4% | A | A | B |
| | A-1 | | | | | | B-3 | | | mass | (79% by mass), | | | | | |
| | | | | | | | | | | | tin oxide | | | | | |
| | | | | | | | | | | | (12% by mass), | | | | | |
| | | | | | | | | | | | silicon dioxide | | | | | |
| | | | | | | | | | | | (9% by mass) | | | | | |
| Example 7 | Material | 8 μm | 1.53 | — | — | — | Material | 100 nm | 1.70 | 60% by | Titanium oxide | 8 nm | 0.4% | A | A | B |
| | A-1 | | | | | | B-3 | | | mass | (79% by mass), | | | | | |
| | | | | | | | | | | | tin oxide | | | | | |
| | | | | | | | | | | | (12% by mass), | | | | | |
| | | | | | | | | | | | silicon dioxide | | | | | |
| | | | | | | | | | | | (9% by mass) | | | | | |
| Example 8 | Material | 8 μm | 1.53 | — | — | — | Material | 70 nm | 1.70 | 60% by | Titanium oxide | 8 nm | 0.4% | A | A | A |
| | A-2 | | | | | | B-3 | | | mass | (79% by mass), | | | | | |
| | | | | | | | | | | | tin oxide | | | | | |
| | | | | | | | | | | | (12% by mass), | | | | | |
| | | | | | | | | | | | silicon dioxide | | | | | |
| | | | | | | | | | | | (9% by mass) | | | | | |
| Example 9 | Material | 4 μm | 1.53 | — | — | — | Material | 70 nm | 1.70 | 60% by | Titanium oxide | 8 nm | 0.4% | A | A | A |
| | A-2 | | | | | | B-3 | | | mass | (79% by mass), | | | | | |
| | | | | | | | | | | | tin oxide | | | | | |
| | | | | | | | | | | | (12% by mass), | | | | | |
| | | | | | | | | | | | silicon dioxide | | | | | |
| | | | | | | | | | | | (9% by mass) | | | | | |
| Example 10 | Material | 8 μm | 1.53 | — | — | — | Material | 70 nm | 1.70 | 60% by | Titanium oxide | 5 nm to | 0.5% | A | A | A |
| | A-2 | | | | | | B-6 | | | mass | (33 to 99% by mass), | 10 nm | | | | |
| | | | | | | | | | | | tin oxide | | | | | |
| | | | | | | | | | | | (0.2 to 66% by mass), | | | | | |
| | | | | | | | | | | | silicon dioxide | | | | | |
| | | | | | | | | | | | (0.2 to 66% by mass) | | | | | |
| Example 11 | Material | 4 μm | 1.60 | 35% by | Titanium oxide | 8 nm | — | — | — | — | — | — | 0.6% | A | A | C |
| | A-3 | | | mass | (79% by mass), | | | | | | | | | | | |
| | | | | | tin oxide | | | | | | | | | | | |
| | | | | | (12% by mass), | | | | | | | | | | | |
| | | | | | silicon dioxide | | | | | | | | | | | |
| | | | | | (9% by mass) | | | | | | | | | | | |
| Comparative | Material | 8 μm | 1.53 | — | — | — | Material | 80 nm | 1.60 | 60% by | Titanium oxide | 4 nm | 2.0% | C | A | C |
| Example 1 | A-1 | | | | | | B-7 | | | mass | (100% by mass) | | | | | |
| Comparative | Material | 8 μm | 1.53 | — | — | — | Material | 80 nm | 1.60 | 90% by | Zirconium oxide | 12 nm | 0.4% | A | E | A |
| Example 2 | A-1 | | | | | | B-8 | | | mass | (90% by mass), | | | | | |
| | | | | | | | | | | | tin oxide | | | | | |
| | | | | | | | | | | | (10% by mass) | | | | | |
| Comparative | Material | 8 μm | 1.53 | — | — | — | Material | 80 nm | 1.64 | 60% by | Titanium oxide | — | 1.5% | C | A | B |
| Example 3 | A-1 | | | | | | B-9 | | | mass | (80% by mass), | | | | | |
| | | | | | | | | | | | silicon dioxide | | | | | |
| | | | | | | | | | | | (20% by mass) | | | | | |

TABLE 7

| | First transparent layer | | | | | | Second transparent layer | | | | | | | | | |
|---|---|---|---|---|---|---|---|---|---|---|---|---|---|---|---|---|
| | | | | Metal oxide particle | | | | | | Metal oxide particle | | | Evaluation result | | | |
| | | | | | Inorganic | | | | | | Inorganic | | | | | Concealing |
| | | | | | oxide | | | | | | oxide | | | | | properties |
| | | | | | component in | Average | | | | | component in | Average | | | | of |
| | | | | | metal oxide | primary | | | | | metal oxide | primary | | | | transparent |
| | | | Refractive | Content | particle and | particle | | | Refractive | Content | particle and | particle | Haze | | | electrode |
| | Material | Thickness | index | in layer | content thereof | diameter | Material | Thickness | index | in layer | content thereof | diameter | value | Surface | Adhesiveness | pattern |
| Example 12 | Material | 4 μm | 1.53 | — | — | — | | 70 nm | 1.68 | 58% by | Titanium oxide | 8 nm | 0.4% | A | A | A |
| | A-4 | | | | | | | | | mass | (33 to 99% by mass), | | | | | |
| | | | | | | | | | | | tin oxide | | | | | |
| | | | | | | | | | | | (0.2 to 66% by mass), | | | | | |
| | | | | | | | | | | | silicon dioxide | | | | | |
| | | | | | | | | | | | (0.2 to 66% by mass) | | | | | |
| Example 13 | Material | 4 μm | 1.53 | — | — | — | | 70 nm | 1.68 | 58% by | Titanium oxide | 8 nm | 0.4% | A | A | A |
| | A-5 | | | | | | | | | mass | (33 to 99% by mass), | | | | | |
| | | | | | | | | | | | tin oxide | | | | | |
| | | | | | | | | | | | (0.2 to 66% by mass), | | | | | |
| | | | | | | | | | | | silicon dioxide | | | | | |
| | | | | | | | | | | | (0.2 to 66% by mass) | | | | | |
| Example 14 | Material | 4 μm | 1.62 | 38% by | Titanium oxide | 8 nm | — | — | — | — | — | — | 0.4% | A | A | C |
| | A-6 | | | mass | (79% by mass), | | | | | | | | | | | |
| | | | | | tin oxide | | | | | | | | | | | |
| | | | | | (12% by mass), | | | | | | | | | | | |
| | | | | | silicon dioxide | | | | | | | | | | | |
| | | | | | (9% by mass) | | | | | | | | | | | |
| Example 15 | Material | 4 μm | 1.53 | — | — | — | | 70 nm | 1.68 | 58% by | Titanium oxide | 8 nm | 0.4% | A | A | A |
| | A-7 | | | | | | | | | mass | (33 to 99% by mass), | | | | | |
| | | | | | | | | | | | tin oxide | | | | | |
| | | | | | | | | | | | (0.2 to 66% by mass), | | | | | |
| | | | | | | | | | | | silicon dioxide | | | | | |
| | | | | | | | | | | | (0.2 to 66% by mass) | | | | | |
| Example 16 | Material | 4 μm | 1.53 | — | — | — | | 70 nm | 1.68 | 58% by | Titanium oxide | 8 nm | 0.4% | A | A | A |
| | A-8 | | | | | | | | | mass | (33 to 99% by mass), | | | | | |
| | | | | | | | | | | | tin oxide | | | | | |
| | | | | | | | | | | | (0.2 to 66% by mass), | | | | | |
| | | | | | | | | | | | silicon dioxide | | | | | |
| | | | | | | | | | | | (0.2 to 66% by mass) | | | | | |
| Example 17 | Material | 4 μm | 1.53 | — | — | — | | 70 nm | 1.68 | 58% by | Titanium oxide | 8 nm | 0.4% | A | A | A |
| | A-7 | | | | | | | | | mass | (33 to 99% by mass), | | | | | |
| | | | | | | | | | | | tin oxide | | | | | |
| | | | | | | | | | | | (0.2 to 66% by mass), | | | | | |
| | | | | | | | | | | | silicon dioxide | | | | | |
| | | | | | | | | | | | (0.2 to 66% by mass) | | | | | |
| Example 18 | Material | 4 μm | 1.53 | — | — | — | | 70 nm | 1.68 | 58% by | Titanium oxide | 8 nm | 0.4% | A | A | A |
| | A-7 | | | | | | | | | mass | (33 to 99% by mass), | | | | | |
| | | | | | | | | | | | tin oxide | | | | | |
| | | | | | | | | | | | (0.2 to 66% by mass), | | | | | |
| | | | | | | | | | | | silicon dioxide | | | | | |
| | | | | | | | | | | | (0.2 to 66% by mass) | | | | | |
| Example 19 | Material | 4 μm | 1.53 | — | — | — | | 70 nm | 1.68 | 58% by | Titanium oxide | 8 nm | 0.4% | A | A | A |
| | A-7 | | | | | | | | | mass | (33 to 99% by mass), | | | | | |
| | | | | | | | | | | | tin oxide | | | | | |
| | | | | | | | | | | | (0.2 to 66% by mass), | | | | | |
| | | | | | | | | | | | silicon dioxide | | | | | |
| | | | | | | | | | | | (0.2 to 66% by mass) | | | | | |
| Example 20 | Material | 4 μm | 1.53 | — | — | — | | 70 nm | 1.68 | 58% by | Titanium oxide | 8 nm | 0.4% | A | A | A |
| | A-7 | | | | | | | | | mass | (33 to 99% by mass), | | | | | |
| | | | | | | | | | | | tin oxide | | | | | |
| | | | | | | | | | | | (0.2 to 66% by mass), | | | | | |
| | | | | | | | | | | | silicon dioxide | | | | | |
| | | | | | | | | | | | (0.2 to 66% by mass) | | | | | |
| Example 21 | Material | 4 μm | 1.53 | — | — | — | | 70 nm | 1.68 | 58% by | Titanium oxide | 8 nm | 0.4% | A | A | A |
| | A-7 | | | | | | | | | mass | (33 to 99% by mass), | | | | | |
| | | | | | | | | | | | tin oxide | | | | | |
| | | | | | | | | | | | (0.2 to 66% by mass), | | | | | |
| | | | | | | | | | | | silicon dioxide | | | | | |
| | | | | | | | | | | | (0.2 to 66% by mass) | | | | | |

As the metal oxide particles used in Example 10, particles in which each metal oxide satisfies the amount within the range shown in Table 4 were used.

As shown in Table 4, by using the transfer films of Examples 1 to 21 containing the metal oxide particles containing tin oxide in addition to titanium oxide, a film having excellent adhesiveness and low haze was obtained, compared to the transfer films of Comparative Examples 1 to 3.

In addition, as a result of producing a transfer film and a transparent laminate using a polyethylene terephthalate film (Lumirror 12QS62, manufactured by Toray Industries, Inc.) having a thickness of 12 μm instead of the temporary support used in Example 1, it is confirmed that the evaluation result that is completely the same as in Example 1 was obtained.

In addition, using the transparent laminate of the embodiment, it was treated for 500 hours using a xenon light resistance tester having an output of 2.4 W/(m²·nm) at 420 nm, but it was confirmed that there was a problem in appearance and transparency and a material having strong light resistance is obtained.

Further, an ultrathin transparent layer (third transparent layer) having substantially no particles of approximately 1 nm to 15 nm was formed between the transparent base material of the transparent laminate of the embodiment and the second transparent layer.

### Examples 101 to 121

<Manufacturing of Touch Panel>

According to JP2013-214173A, a structure up to the first electrode portion 140 and the second electrode portion 145 shown in FIG. 5 was formed. In addition, the protective films 114 and 119 were formed on the first electrode portion 140 and the second electrode portion 145 using the transfer film according to any one of Examples 1 to 21, and a film sensor was formed. Further, the film sensor was attached to the cover panel 12 through the adhesive layer (not shown) and the display device 115 through the adhesive layer (not shown) to produce a touch panel. It was confirmed that the obtained touch panel operates normally.

In addition, according to JP2013-214173A, in the film sensor of the single-surface XY electrode shown in FIG. 6, the insulation film 149 was formed using the transfer film of any of Examples 1 to 21 which is the same as the transfer film used above to produce a touch panel. It was confirmed that the obtained touch panel operates normally.

### EXPLANATION OF REFERENCES

10: transfer film
12: temporary support
16: protective film
18, 18A: first transparent layer (electrode protective film for touch panel)
20, 20A: second transparent layer (first refractive index adjusting layer)
30: touch panel
32: substrate
34: transparent electrode pattern
36: second refractive index adjusting layer
40: first region where transparent electrode pattern is present
42: second region where transparent electrode pattern is not present
56: leading wiring
70: first transparent electrode pattern
72: second transparent electrode pattern
74: image display region
75: image non-display region
90: touch panel
105: Finger
110: Input/output device (touch panel)
112: Cover panel
114: Protective film
115: Display device
119: Protective film
120: Cover module
130: Film sensor
132: Base film
132a: Surface (surface of one side)
132b: Surface (surface of the other side)
136: leading wiring
140: First electrode portion
141: First conductor
142: Line portion
143: bulging portion
145: Second electrode portion
146: Second conductor
147: Line portion
148: bulging portion
149: Insulating layer
155: Bridge portion
A1: Display region
A2: Non-display region

What is claimed is:

1. A transfer film which satisfies at least one of the following (1) or (2),
wherein (1) the transfer film comprises a temporary support, and a first transparent layer including a polymerizable compound, a polymerization initiator, and a resin, and the first transparent layer further contains a metal oxide particle containing titanium oxide and tin oxide, and
(2) the transfer film comprises a temporary support, a first transparent layer including a polymerizable compound, a polymerization initiator, and a resin, and a second transparent layer, and the second transparent layer contains a metal oxide particle containing titanium oxide and tin oxide.

2. The transfer film according to claim 1,
wherein the transfer film satisfies the (2).

3. The transfer film according to claim 1,
wherein the titanium oxide in the metal oxide particle contains a rutile type titanium oxide.

4. The transfer film according to claim 1,
wherein an average primary particle diameter of the metal oxide particle is 10 nm or less.

5. The transfer film according to claim 1,
wherein a content of the tin oxide with respect to a content of the titanium oxide in the metal oxide particle is 5% by mass or more.

6. The transfer film according to claim 1,
wherein the metal oxide particle further contains an inorganic oxide other than the titanium oxide and the tin oxide.

7. The transfer film according to claim 1,
wherein the layer containing the metal oxide particle further contains a silane coupling agent or a titanium coupling agent.

8. The transfer film according to claim 1,
wherein the transfer film is a transfer film for forming a protective film of a touch panel.

9. A manufacturing method of a cured film, the method comprising:
transferring at least the first transparent layer of the transfer film according to claim 1 on a support; and
curing at least a part of the first transparent layer to form a cured film.

10. A manufacturing method of a laminate, the method comprising:
transferring at least the first transparent layer of the transfer film according to claim 1 on a substrate including an electrode; and
curing at least a part of the first transparent layer to form a cured layer.

11. The manufacturing method of a laminate according to claim 10,
wherein the electrode is an electrode of a capacitive input device.

12. A manufacturing method of a touch panel, comprising
preparing a substrate for a touch panel having a structure in which at least one of an electrode for a touch panel or a wiring for a touch panel is disposed on the substrate;
forming a photosensitive layer on a surface of the substrate for a touch panel, on a side where at least one of the electrode for a touch panel or the wiring for a touch panel is disposed, by using the transfer film according to claim 1;
performing patternwise exposing on the photosensitive layer formed on the substrate for a touch panel; and
developing the patternwise exposed photosensitive layer to obtain a protective film for a touch panel protecting at least a part of at least one of the electrode for a touch panel or the wiring for a touch panel.
